(19) United States
(12) Patent Application Publication
(10) Pub. No.: US 2022/0213293 A1
(43) Pub. Date: Jul. 7, 2022

(54) CURABLE COMPOSITION, CURED FILM, COLOR FILTER, SOLID-STATE IMAGING ELEMENT, AND IMAGE DISPLAY DEVICE

(71) Applicant: FUJIFILM Corporation, Tokyo (JP)

(72) Inventors: Yoshinori TAGUCHI, Shizuoka (JP); Takahiro OYA, Shizuoka (JP)

(73) Assignee: FUJIFILM Corporation, Tokyo (JP)

(21) Appl. No.: 17/700,448

(22) Filed: Mar. 21, 2022

Related U.S. Application Data
(63) Continuation of application No. PCT/JP2020/034104, filed on Sep. 9, 2020.

(30) Foreign Application Priority Data
Sep. 26, 2019 (JP) 2019-175048

(51) Int. Cl. C08K 3/36; G02B 5/20; G02B 1/04; H04N 9/04; C08K 9/02

(52) U.S. Cl. CPC C08K 3/36; G02B 5/208; C08K 9/02; H04N 9/0455; G02B 1/04

(57) ABSTRACT

An object of the present invention is to provide a curable composition with which a cured film having excellent color separation, pattern shape accuracy, and transmittance can be manufactured. Another object of the present invention is to provide a cured film formed of the curable composition, a color filter, a solid-state imaging element, and an image display device. The curable composition of the present invention contains, a coloring material, a resin, a polymerizable compound, a polymerization initiator, and silica particles, in which a content of the coloring material is 30 to 80 mass % with respect to a total solid content of the curable composition, and a content of the silica particles is 5 to 30 mass % with respect to the total solid content of the curable composition.

### CROSS-REFERENCE TO RELATED APPLICATIONS

This application is a Continuation of PCT International Application No. PCT/JP2020/034104 filed on Sep. 9, 2020, which claims priority under 35 U.S.C. § 119(a) to Japanese Patent Application No. 2019-175048 filed on Sep. 26, 2019. The above application is hereby expressly incorporated by reference, in its entirety, into the present application.

### BACKGROUND OF THE INVENTION

### 1. Field of the Invention

The present invention relates to a curable composition, a cured film, a color filter, a solid-state imaging element, and an image display device.

### 2. Description of the Related Art

In the related art, a color filter which is used for an image display device such as a liquid crystal display device and an organic electroluminescent display device, a solid-state imaging element, and the like has been known.

The color filter is manufactured by a photolithography method and the like using a curable composition which contains a coloring material such as a pigment and a dye, a resin, a polymerizable compound, a polymerization initiator, and the like.

For example, JP2013-195697A discloses that the color filter is manufactured using a photosensitive coloring composition (curable composition) which contains a dye, a polymerization initiator, a polymerizable compound, hollow silica particles, and the like.

### SUMMARY OF THE INVENTION

In a case where a cured film (color filter) formed of the curable composition disclosed in JP2013-195697A is studied, the present inventors have found that there is room for improvement in color separation and the like.

In addition, from the viewpoint of stable device manufacturing and device sensitivity improvement, the cured film constituting the color filter has been required to have excellent pattern shape accuracy (for example, in a case where the cured film has a patterned shape, there is little chipping or the like of a cross section of the pattern) and high transmittance. Therefore, an object of the present invention is to provide a curable composition with which a cured film having excellent color separation, pattern shape accuracy, and transmittance can be manufactured. Another object of the present invention is to provide a cured film formed of the curable composition, a color filter, a solid-state imaging element, and an image display device.

The present inventors have conducted intensive studies to achieve the above-described object, and as a result, found that, in a curable composition containing a coloring material, a resin, a polymerizable compound, a polymerization initiator, and silica particles, in a case where the content of the coloring material is 30 to 80 mass % with respect to the total solid content of the curable composition and the content of the silica particles is 5 to 30 mass % with respect to the total solid content of the curable composition, a cured film having excellent color density, pattern shape accuracy, and transmittance can be manufactured, and completed the present invention.

That is, the present inventors have found that the above-described objects can be achieved by the following configurations.

[1]

A curable composition comprising:

a coloring material;

a resin;

a polymerizable compound;

a polymerization initiator; and

silica particles,

in which a content of the coloring material is 30 to 80 mass % with respect to a total solid content of the curable composition, and

a content of the silica particles is 5 to 30 mass % with respect to the total solid content of the curable composition.

[2]

The curable composition according to [1],

in which the silica particles are modified silica particles containing silica and a coating layer coating the silica.

[3]

The curable composition according to [2],

in which the coating layer contains at least one group selected from the group consisting of a group including a silicon atom, a group including a fluorine atom, an alkyl group which may have a substituent, and an aryl group which may have a substituent.

[4]

The curable composition according to any one of [1] to [3],

in which the resin contains a resin having a repeating unit having a graft chain.

[5]

The curable composition according to any one of [1] to [4],

in which the resin contains a resin having an acid value of 10 to 100 mgKOH/g and having an ethylenically unsaturated bond equivalent of 0.4 to 2.5 mmol/g.

[6]

The curable composition according to any one of [1] to [5],

in which the content of the silica particles is 5 mass % or more and less than 20 mass % with respect to the total solid content of the curable composition.

[7]

The curable composition according to any one of [1] to [6],

in which the content of the coloring material is 40 mass % or more and less than 70 mass % with respect to the total solid content of the curable composition.

[8]

The curable composition according to any one of [1] to [7],

in which a mass ratio of the content of the coloring material to the content of the silica particles is 2 to 14.

[9]

The curable composition according to any one of [1] to [8],

in which the coloring material contains at least one selected from the group consisting of Color Index Pigment Red 122, Color Index Pigment Red 177, Color Index Pigment Red 179, Color Index Pigment Red 254, Color Index Pigment Red 264, Color Index Pigment Red 269, Color Index Pigment Red 272, Color Index Pigment Green 7, Color Index Pigment Green 36, Color Index Pigment Green 58, Color Index Pigment Green 59, Color Index Pigment Green 63, Color Index Pigment Blue 15:4, Color Index Pigment Blue 15:6, Color Index Pigment Blue 16, Color Index Pigment Yellow 138, Color Index Pigment Yellow 139, Color Index Pigment Yellow 150, Color Index Pigment Yellow 185, Color Index Pigment Violet 23, carbon black, titanium black, a squarylium compound, and a pyrrolopyrrole compound.

[10]

A cured film formed of the curable composition according to any one of [1] to [9].

[11]

The cured film according to [10],

in which a reflectivity is 5% or less.

[12]

The cured film according to [10] or [11],

in which the cured film has a patterned shape, and

a size of one side of the pattern is 3 μm or less.

[13]

A color filter comprising:

the cured film according to any one of [10] to [12].

[14]

A solid-state imaging element comprising:

the cured film according to any one of [10] to [12].

[15]

An image display device comprising:

the cured film according to any one of [10] to [12].

According to the present invention, it is possible to provide a curable composition with which a cured film having excellent color separation, pattern shape accuracy, and transmittance can be manufactured. In addition, according to the present invention, it is also possible to provide a cured film formed of the curable composition, a color filter, a solid-state imaging element, and an image display device.

### BRIEF DESCRIPTION OF THE DRAWINGS

FIG. 1 is a schematic cross-sectional view showing a configuration example of a solid-state imaging device.

FIG. 2 is a schematic cross-sectional view showing an enlarged imaging unit included in the solid-state imaging device of FIG. 1.

FIG. 3 is a schematic cross-sectional view showing a configuration example of an infrared sensor.

### DESCRIPTION OF THE PREFERRED EMBODIMENTS

Hereinafter, the present invention will be described in detail.

The description of the configuration requirements described below is made on the basis of representative embodiments of the present invention, but it should not be construed that the present invention is limited to those embodiments.

In the present specification, a numerical range represented using “to” means a range containing numerical values described before and after the preposition “to” as a lower limit value and an upper limit value.

In addition, in a notation for a group (atomic group) in the present specification, in a case where the group is denoted without specifying whether it is substituted or unsubstituted, the group includes both a group having no substituent and a group having a substituent. For example, an “alkyl group” includes not only an alkyl group having no substituent (unsubstituted alkyl group), but also an alkyl group having a substituent (substituted alkyl group).

In addition, “actinic ray” or “radiation” in the present disclosure means, for example, far ultraviolet ray, extreme ultraviolet ray (EUV), X-ray, electron beam, and the like. In addition, in the present specification, light means actinic ray and radiation. In the present specification, unless specified otherwise, “exposure” denotes not only exposure with far ultraviolet ray, X-ray, EUV light, and the like, but also drawing with corpuscular beams such as electron beam and ion beam.

In addition, in the present specification, “(meth)acrylate” refers to acrylate and methacrylate. In the present specification, “(meth)acrylic” refers to acrylic and methacrylic. In the present specification, “(meth)acryloyl” refers to acryloyl and methacryloyl. In the present specification, “(meth)acrylamide” refers to acrylamide and methacrylamide. In the present specification, “monomeric substance” and “monomer” are synonymous.

In the present specification, “ppm” means “parts per million (10⁻⁶)”, “ppb” means “parts per billion (10⁻⁹)”, “ppt” means “parts per trillion (10⁻¹²)”.

In addition, in the present specification, a weight-average molecular weight (Mw) is a value by a gel permeation chromatography (GPC) method in terms of polystyrene.

In the present specification, the GPC method is based on a method using HLC-8020 GPC (manufactured by Tosoh Corporation), using TSKgel SuperHZM-H, TSKgel SuperHZ4000, and TSKgel SuperHZ2000 (all manufactured by Tosoh Corporation, 4.6 mmID X 15 cm) as a column, and using tetrahydrofuran (THF) as an eluent.

The bonding direction of a divalent group (for example, —COO—) denoted in the present specification is not limited unless otherwise specified. For example, in a case where Y in a compound represented by a general formula “X—Y—Z” is —COO—, the compound may be “X—O—CO—Z” or “X—CO—O—Z”.

In the present specification, a “total solid content” of a curable composition means components forming a cured film, and in a case where the curable composition contains a solvent (organic solvent, water, or the like), the “total solid content” means all components except the solvent. In addition, in a case where a component forms the cured film, the component which is a liquid component is also regarded as a solid content.

[Curable Composition]

A curable composition according to an embodiment of the present invention contains a coloring material, a resin, a polymerizable compound, a polymerization initiator, and silica particles, in which a content of the coloring material is 30 to 80 mass % with respect to a total solid content of the curable composition, and a content of the silica particles is 5 to 30 mass % with respect to the total solid content of the curable composition.

With the curable composition according to the embodiment of the present invention, a cured film having excellent color separation, pattern shape accuracy, and transmittance can be manufactured. The details of the reason are not clear, but are presumed as follows.

That is, in a case where the curable composition contains a predetermined amount or more of silica particles, it is considered that the silica particles are unevenly distributed on a surface of the cured film, and a pseudo layer having a low refractive index due to the silica particles is formed on the surface of the cured film. As a result, it is presumed that the transmittance of the cured film is improved as a result of reduced reflection of the cured film.

In addition, it is presumed that permeability of a developer during pattern formation can be suppressed and the pattern shape accuracy is improved.

In addition, in a case where the curable composition contains a predetermined amount or more of the coloring material, it is presumed that a cured film having a desired tint with excellent color separation can be formed.

In addition, in a case where the content of the silica particles and the content of the coloring material in the curable composition are not more than a predetermined amount, it is presumed that lithography performance of the curable composition is improved and chipping or the like of the pattern shape of the cured film is suppressed.

Hereinafter, the fact that the cured film formed from the curable composition has excellent color separation, that the cured film formed from the curable composition has excellent pattern shape accuracy, and/or that the cured film formed from the curable composition has excellent transmittance are also referred to as that the effects of the present invention are excellent.

Hereinafter, components which are contained in the curable composition according to the embodiment of the present invention and components which may be contained in the curable composition according to the embodiment of the curable composition will be described.

[Silica Particles]

The curable composition according to the embodiment of the present invention contains silica particles (particles of silicon dioxide). Different materials are used for the silica particles and a coloring material described later.

The content of the silica particles is 5 to 30 mass % with respect to the total solid content of the curable composition, and from the viewpoint that transmittance and the like of the cured film are more excellent, it is preferable to be 5 mass % or more, more preferable to be 7 mass % or more, and still more preferable to be 9 mass % or more, and from the viewpoint that pattern shape accuracy and the like are more excellent, it is preferable to be less than 20 mass %, more preferable to be 18 mass % or less, and still more preferable to be 16 mass % or less.

The curable composition according to the embodiment of the present invention may include only one kind of the silica particle or two or more kinds thereof. In a case of including two or more kinds thereof, the total amount thereof is preferably within the above-described range.

From the viewpoint that the effects of the present invention are more excellent, the particle size of the silica particles is preferably 1 to 200 nm, more preferably 10 to 100 nm, and still more preferably 15 to 78 nm.

In the present specification, the particle size of the silica particles means an average primary particle diameter of particles measured by the following method. The average primary particle diameter can be measured using a scanning electron microscope (SEM).

A maximum length (Dmax: maximum length between two points on a contour of a particle image) and a maximum perpendicular length (DV-max: shortest length connecting perpendicularly between two straight lines in a case where the image is interposed between the two straight lines parallel with the maximum length) of a particle image obtained by using the SEM are measured, and the geometric mean value (Dmax×DV-max)^{1/2} thereof is defined as a particle diameter. By measuring particle diameters of 100 particles by the method, the arithmetic average value thereof is defined as the average primary particle diameter of the particles.

The refractive index of the silica particles is not particularly limited, but from the viewpoint that low reflection properties of the cured film are more excellent, the refractive index is preferably 1.10 to 1.60 and more preferably 1.15 to 1.45.

In addition, the silica particles may be hollow particles or solid particles.

The hollow particles refer to particles in which cavities exist inside the particles.

The hollow particles may have a structure in which the particles consist of an inner cavity and an outer shell surrounding the cavity. In addition, the hollow particles may have a structure in which a plurality of cavities exist inside the particles.

The solid particles refer to particles in which no cavity substantially exists inside the particles.

The hollow particles preferably have a void ratio of 3% or more, and the solid particles preferably have a void ratio of less than 3%.

From the viewpoint that the effects of the present invention are more excellent, the silica particles are preferably the hollow particles.

Since the hollow particles have cavities inside so as to have a lower specific density than particles having no hollow structure, it is considered that the hollow particles float on a surface of a coating film formed of the curable composition, and the effect of uneven distribution on the surface of the cured film is further enhanced.

In addition, the hollow particles have a lower refractive index of the particles themselves than the particles having no hollow structure. For example, in a case where the hollow particles are composed of silica, since the hollow silica particles hold air having a low refractive index (refractive index=1.0), the refractive index of the particles themselves is 1.2 to 1.4, which is significantly lower than that of ordinary silica (refractive index=1.6). Therefore, by forming a cured film using a composition containing the hollow particles, it is considered that the hollow particles having a low refractive index are unevenly distributed on the surface of the cured film, so that an anti-reflection (AR) type low reflection effect is obtained and low reflection properties of the cured film are improved.

Examples of the hollow silica particles include hollow silica particles described in JP2001-233611A and JP3272111B.

As the hollow silica particles, for example, THRULYA 4110 (trade name, manufactured by JGC C&C) can also be used.

As a preferred aspect of the solid silica particles, IPA-ST, IPA-ST-L, IPA-ST-ZL, MIBK-ST, MIBK-ST-L, CHO-ST-M, PGM-AC-2140Y, PGM-AC-4130Y, and the like (all trade names manufactured by Nissan Chemical Corporation) can be used.

As the silica particles, beaded silica particles which are particle aggregates in which a plurality of silica particles are connected in a chain may be used. As the beaded silica particles, silica particles in which a plurality of spherical colloidal silica particles having a particle size of 5 to 50 nm are bonded with metal oxide-containing silica are preferable.

Examples of the beaded colloidal silica particles include silica sol described in JP4328935B and JP2013-253145A.

The silica particles may contain a component other than silicon dioxide as desired. The content of silicon dioxide in the silica particles is preferably 75 to 100 mass %, more preferably 90 to 100 mass %, and still more preferably 99 to 100 mass % with respect to the total mass of the silica particles.

From the viewpoint that transmittance of the cured film is more excellent, the silica particles are preferably modified silica particles containing silica and a coating layer coating the silica.

<Coating Layer>

The coating layer is a layer which coats silica constituting the above-described silica particles. The coating with the coating layer may be performed on the entire surface of the silica, or may be performed only a part of the silica. It is preferable that 10% or more of the silica particles is coated with the coating layer, more preferable that 30% or more thereof is coated with the coating layer, and still more preferable that 50% or more thereof is coated with the coating layer.

The coating layer may be disposed directly on the surface of the silica, or may be disposed on the silica through another layer.

The coating layer preferably contains at least one group selected from the group consisting of a group including a silicon atom, a group including a fluorine atom, an alkyl group which may have a substituent, an aryl group which may have a substituent, a (meth)acryloyl group, a glycidoxy group, and an amino group. Among these, from the viewpoint that the effects of the present invention are more excellent and/or generation of residue in a case of forming a patterned cured film can be further suppressed, it is more preferable to contain at least one group selected from the group consisting of a group including a silicon atom, a group including a fluorine atom, an alkyl group which may have a substituent, and an aryl group which may have a substituent, and it is still more preferable to contain at least one group selected from the group consisting of a group including a silicon atom and a group including a fluorine atom.

However, the silicon atom in the group including a silicon atom referred to here does not include the silicon atom bonded to the silica through an oxygen atom. For example, in a case where a silane coupling agent is used to prepare the modified silica particles, a silicon atom derived from the hydrolyzable silyl group bonded to the silica through an oxygen atom does not correspond to the silicon atom in the group including a silicon atom, and in a case where a silylating agent is used to prepare the modified silica particles, a silicon atom derived from the silylating agent bonded to the silica through an oxygen atom does not correspond to the silicon atom in the group including a silicon atom.

As a more detailed specific example, even in a case where modified silica particles having a methacryloyl group are prepared by reacting silica with a trimethoxysilyl group of 3-methacryloxypropyltrimethoxysilane, a silicon atom derived from the trimethoxysilyl group which has reacted with the silica does not correspond to the silicon atom in the group including a silicon atom of the coating layer. Similarly, even in a case where modified silica particles having an alkyl group (methyl group) are prepared by reacting silica with hexamethyldisilazane, a silicon atom derived from hexamethyldisilazane which has reacted with the silica does not correspond to the silicon atom in the group including a silicon atom of the coating layer.

The group including a silicon atom and the group including a fluorine atom are preferably a group including a repeating unit represented by General Formula (1) described below (preferably, a group represented by S^{S1} in General Formula (1)). In other words, the coating layer preferably contains a polymer containing a repeating unit represented by General Formula (1).

The coating layer may contain the above-described polymer as a part thereof, or the coating layer may be the polymer itself. The content of the above-described polymer is preferably 10 to 100 mass %, more preferably 70 to 100 mass %, and still more preferably 95 to 100 mass % with respect to the total mass of the coating layer.

The repeating unit represented by General Formula (1), which is contained in the above-described polymer, is shown below.

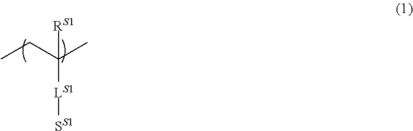

In General Formula (1), R^{S1} represents an alkyl group which may contain a substituent, or a hydrogen atom.

The above-described alkyl group may be linear or branched. In addition, the above-described alkyl group may have a cyclic structure as a whole or may partially contain a cyclic structure.

The number of carbon atoms in the above-described alkyl group is preferably 1 to 10 and more preferably 1 to 3. In a case where the alkyl group contains a substituent, the preferred number of carbon atoms here is intended to be the number of carbon atoms including the number of carbon atoms which may be present in the substituent.

Among these, R^{S1} is preferably a hydrogen atom or a methyl group.

In General Formula (1), L^{S1} represents a single bond or a divalent linking group.

Examples of the above-described divalent linking group include —O—, —CO—, —C(O)O—, —S—, —SO₂—, —NR^{N}— (R^{N} represents a hydrogen atom or an alkyl group), a divalent hydrocarbon group (an alkylene group, an alkenylene group (for example, —CH═CH—), an alkynylene group (for example, —C≡C— and the like), and an arylene group), —SiR^{SX}₂—(R^{SX} represents a hydrogen atom or a substituent), and a group of a combination of one or more groups selected from the group consisting of these groups.

The above-described divalent linking group may have a substituent if possible, and the substituent in the above-described divalent linking group may be a group represented by S^{S1} described later, or may be a group partially containing the group represented by S^{S1} described later.

Among these, the above-described divalent linking group is preferably a group of a combination of groups selected from the group consisting of an ester group and an alkylene group (preferably, an alkylene group having 1 to 10 carbon atoms).

Among these, the above-described divalent linking group is preferably a group represented by*A—CO—O—*B or*A—CO—O—alkylene group—*B.

*B represents a bonding position with S^{S1} in General Formula (1), and*A represents a bonding position on the opposite side of*13.

The above-described alkylene group may be linear or branched. In addition, the above-described alkylene group may have a cyclic structure as a whole or may partially contain a cyclic structure. The above-described alkylene group is preferably linear.

The number of carbon atoms in the above-described alkylene group is preferably 1 to 10 and more preferably 1 to 3. In a case where the alkylene group contains a substituent, the preferred number of carbon atoms here is intended to be the number of carbon atoms including the number of carbon atoms which may be present in the substituent. The above-described alkylene group is preferably unsubstituted.

In General Formula (1), S^{S1} represents a substituent.

The above-described substituent preferably contains a silicon atom or a fluorine atom. That is, the substituent is preferably a group including a silicon atom or a group including a fluorine atom.

As the above-described substituent, an unsubstituted alkyl group, a fluoroalkyl group, or a group represented by General Formula (SS1) described later is preferable, and a fluoroalkyl group or a group represented by General Formula (SS1) described later is more preferable.

The above-described unsubstituted alkyl group as the substituent represented by S^{S1} may be linear or branched. In addition, the above-described unsubstituted alkyl group may have a cyclic structure as a whole or may partially contain a cyclic structure.

The number of carbon atoms in the above-described unsubstituted alkyl group is preferably 1 to 10 and more preferably 1 to 5.

An alkyl group moiety of the above-described fluoroalkyl group as the substituent represented by S^{S1} may be linear or branched. In addition, the above-described alkyl group moiety may have a cyclic structure as a whole or may partially contain a cyclic structure.

The number of carbon atoms in the above-described alkyl group moiety is preferably 1 to 15 and more preferably 1 to 10.

It is also preferable that the alkyl group moiety does not contain a substituent other than a fluorine atom.

The number of fluorine atoms contained in the above-described fluoroalkyl group is preferably 1 to 30 and more preferably 5 to 20.

It is also preferable that the above-described fluoroalkyl group is a perfluoroalkyl group in whole or in part.

The group represented by General Formula (SS1) as the substituent represented by S^{S1} is as follows.

*—L^{S2}—O—SiR^{s2}₃ (SS1)

In General Formula (SS1),*represents a bonding position.

In General Formula (SS1), R^{S2} represents a hydrocarbon group having 1 to 20 carbon atoms, which may contain a substituent.

The number of carbon atoms in the above-described hydrocarbon group is 1 to 20, preferably 1 to 10 and more preferably 1 to 5. In a case where the hydrocarbon group contains a substituent, the number of carbon atoms here is intended to be the number of carbon atoms including the number of carbon atoms which may be present in the substituent.

The above-described hydrocarbon group is preferably an alkyl group.

The above-described alkyl group may be linear or branched. In addition, the above-described alkyl group may have a cyclic structure as a whole or may partially contain a cyclic structure.

A plurality of R^{s2}'s may be the same or different from each other.

In General Formula (SS1), L^{S2} represents a single bond or a divalent linking group.

Examples of the divalent linking group in L^{S2} of General Formula (SS1) include the same group mentioned as examples of the divalent linking group in L^{S1} of General Formula (1).

In addition, the divalent linking group in L^{S2} may contain one or more (for example, 1 to 1000) —SiR^{S2}₂—O—, R^{S2} in —SiR^{S2}₂—O— is the same as R^{S2} described above.

From the viewpoint that the effects of the present invention are more excellent, S^{S1} is more preferably a group represented by General Formula (2).

The group represented by General Formula (2) is shown below.

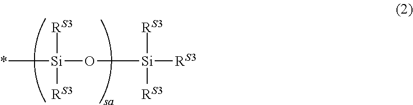

In General Formula (2),*represents a bonding position.

In General Formula (2), sa represents an integer of 1 to 1000.

In General Formula (2), R^{S3} represents a hydrocarbon group having 1 to 20 carbon atoms, which may contain a substituent, or a group represented by General Formula (3) described later.

In General Formula (2), a plurality of R^{s3}'s may be the same or different from each other.

Examples of the above-described hydrocarbon group which can be represented by R^{s3} include the above-described hydrocarbon group which can be represented by R^{S2} and may have a substituent.

Among these, it is preferable that R^{s3}'s bonded to the rightmost Si in General Formula (2) are each independently the above-described hydrocarbon group.

In a case where sa in General Formula (2) is 1, R^{s3}'s in “—(—SiR^{s3}₂—O—)ₛₐ—” are each independently preferably the group represented by General Formula (3) described later.

Among “2× sa” pieces R^{s3}'s present in “—(—SiR^{s3}₂—O—)ₛₐ-”, the number of R^{s3}'s as a group represented by General Formula (3) is preferably 0 to 1000, more preferably 0 to 10, and still more preferably 0 to 2.

The group represented by General Formula (3), which can be represented by R^{S3}, is shown below.

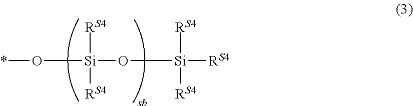

In General Formula (3),*represents a bonding position.

In General Formula (3), sb represents an integer of 0 to 300.

In General Formula (3), R^{S4} represents a hydrocarbon group having 1 to 20 carbon atoms, which may contain a substituent.

In General Formula (3), a plurality of R^{s4}'s may be the same or different from each other.

Examples of the above-described hydrocarbon group which can be represented by R^{s4} include the above-described hydrocarbon group which can be represented by R^{S2} and may have a substituent.

The polymer contained in the coating layer may contain a repeating unit other than the repeating unit represented by General Formula (1).

The above-described repeating unit other than the repeating unit represented by General Formula (1) is preferably a (meth)acrylic repeating unit.

The molecular weight of the above-described repeating unit other than the repeating unit represented by General Formula (1) is preferably 86 to 1000 and more preferably 100 to 500.

From the viewpoint that the effects of the present invention are more excellent, the content of the repeating unit represented by General Formula (1) in the polymer contained in the coating layer is preferably 10 to 100 mass %, more preferably 60 to 100 mass %, and still more preferably 90 to 100 mass % with respect to the total repeating units.

It is preferable that the polymer contained in the coating layer does not substantially contain a repeating unit having an ethylenically unsaturated group and/or a repeating unit having a hydrolyzable silyl group.

The fact “does not substantially contain the above-described repeating unit” means that, in the polymer contained in the coating layer, the content of the repeating unit having an ethylenically unsaturated group and the content of the repeating unit having a hydrolyzable silyl group are each independently 1.0 mass % or less (preferably, 0.1 mass % or less) with respect to the total repeating units.

The coating layer containing the polymer having the repeating unit represented by General Formula (1) can be formed, for example, by the following method.

First, silica is reacted with a silane coupling agent (3-methacryloxypropyltrimethoxysilane and the like) containing an ethylenically unsaturated group (for example, a (meth)acryloyl group, a vinyl group, a styryl group, and the like) to form a polymer precursor layer containing an ethylenically unsaturated group on a surface of the silica. Next, the coating layer containing the polymer having the repeating unit represented by General Formula (1) can be formed by polymerizing the ethylenically unsaturated group in the polymer precursor layer, the ethylenically unsaturated group in the monomer corresponding to the repeating unit represented by General Formula (1), and an ethylenically unsaturated group in other ethylenically unsaturated group-containing monomers added as desired.

In addition, the group including a fluorine atom may be a group contained in a coating layer having no polymer, and examples thereof include a layer formed by using a silane coupling agent. In this case, specific examples of the group including a fluorine atom include a fluoroalkyl group, and a perfluoroalkyl is preferable.

From the viewpoint that defects of the cured film can be further suppressed, the fluoroalkyl group preferably has 1 to 10 carbon atoms, more preferably has 1 to 5 carbon atoms, and still more preferably has 1 to 3 carbon atoms.

The coating layer having the group including a fluorine atom and no polymer can be formed, for example, by reacting silica with a silane coupling agent (trifluoropropyltrimethoxysilane and the like) containing a fluoroalkyl group. That is, the coating layer may be a layer formed by using a silane coupling agent containing a fluoroalkyl group.

The coating layer having the alkyl group which may have a substituent may be a coating layer having no polymer, and examples thereof include a layer formed by using a silylating agent.

In the alkyl group which may have a substituent, the alkyl group preferably has 1 to 20 carbon atoms, and from the viewpoint that transmittance of the cured film is more excellent, more preferably has 2 or more carbon atoms and still more preferably has 3 or more carbon atoms, and from the viewpoint that uniformity of the cured film is more excellent, more preferably has 10 or less carbon atoms and still more preferably has 8 or less carbon atoms.

The alkyl group may have any linear, branched, or cyclic structure, but from the viewpoint that the effects of the present invention are more excellent, the alkyl group is preferably linear.

Specific examples of the alkyl group include a methyl group, an ethyl group, an isopropyl group, an n-butyl group, a tert-butyl group, an n-octyl group, an n-decyl group, an n-hexadecyl group, a cyclopropyl group, a cyclopentyl group, and a cyclohexyl group.

In the alkyl group which may have a substituent, examples of the substituent include a halogen atom, and a fluorine atom is preferable.

The coating layer having the alkyl group which may have a substituent can be formed, for example, by reacting silica with a silylating agent (hexamethyldisilazane and the like) containing an alkyl group. That is, the coating layer may be a layer formed by using a silylating agent containing an alkyl group.

The coating layer having the aryl group which may have a substituent may be a coating layer having no polymer, and examples thereof include a layer formed by using a silane coupling agent.

In the aryl group which may have a substituent in the coating layer, the aryl group preferably has 6 to 30 carbon atoms, and from the viewpoint that uniformity of the cured film is more excellent, more preferably has 20 or less carbon atoms and still more preferably has 12 or less carbon atoms.

The aryl group may be a monocyclic ring or may have a fused-ring structure of two or more rings, but from the viewpoint that the effects of the present invention are more excellent, a monocyclic ring is preferable.

Specific examples of the aryl group include a phenyl group, a 2,6-diethylphenyl group, a 3,5-ditrifluoromethylphenyl group, a naphthyl group, and a biphenyl group.

In the aryl group which may have a substituent, examples of the substituent include a vinyl group.

The coating layer having the aryl group which may have a substituent can be formed, for example, by reacting silica with a silane coupling agent containing an aryl group. That is, the coating layer may be a layer formed by using a silane coupling agent containing an aryl group.

The coating layer having the (meth)acryloyl group may be a coating layer having no polymer, and can be formed, for example, by reacting silica with a silane coupling agent (3-methacryloxypropyltrimethoxysilane and the like). That is, the coating layer may be a layer formed by using a silane coupling agent containing a (meth)acryloyl group.

In addition, the coating layer having the epoxy group may be a coating layer having no polymer, and can be formed, for example, by reacting silica with a silane coupling agent (3-glycidoxypropyltrimethoxysilane and the like). That is, the coating layer may be a layer formed by using a silane coupling agent containing an epoxy group.

In addition, the coating layer having the amino group may be a coating layer having no polymer, and can be formed, for example, by reacting silica with a silane coupling agent (3-aminopropyltrimethoxysilane and the like). That is, the coating layer may be a layer formed by using a silane coupling agent containing an amino group.

In the modified silica particles, from the viewpoint that the effects of the present invention are more excellent, the content of the coating layer is preferably 2 mass % or more, more preferably 6 mass % or more, and still more preferably 8 mass % or more with respect to the total mass of the modified silica particles. The upper limit is preferably 30 mass % or less, more preferably 20 mass % or less, and still more preferably 15 mass % or less.

[Coloring Material]

The composition according to the embodiment of the present invention contains a coloring material. Different materials are used for the above-described silica particles and the coloring material. The coloring material may be used alone, or in combination of two or more kinds thereof.

Examples of the coloring material include a chromatic colorant, an achromatic colorant, and an infrared absorber. In the present invention, the chromatic colorant denotes a colorant other than a white colorant and a black colorant. It is preferable that the chromatic colorant is a colorant having an absorption in a wavelength range of 400 nm or more and less than 650 nm.

The content of the coloring material is 30 to 80 mass % with respect to the total solid content of the curable composition, and from the viewpoint that color separation is more excellent, it is preferable to be 40 mass % or more, more preferable to be 44 mass % or more, and still more preferable to be 48 mass % or more, and from the viewpoint that pattern shape accuracy is further improved, it is preferable to be less than 70 mass %, more preferable to be 65 mass % or less, and still more preferable to be 60 mass % or less.

The curable composition according to the embodiment of the present invention may include only one kind of the coloring material or two or more kinds thereof. In a case of including two or more kinds thereof, the total amount thereof is preferably within the above-described range.

In the curable composition, from the viewpoint that color separation is more excellent, the lower limit value of the mass ratio of the content of the coloring material to the content of the silica particles (content of coloring material/content of silica particles) is preferably 1 or more, more preferably 2 or more, still more preferably 3 or more, and particularly preferably 5 or more, and from the viewpoint that transmittance is more excellent, it is preferable to be 16 or less, more preferable to be 14 or less, still more preferable to be 12 or less, and particularly preferable to be 10 or less. In particular, in a case where the above-described mass ratio is within the range of 2 to 14, occurrence of peeling after a humidity test can be further suppressed.

<Chromatic Colorant>

Examples of the chromatic colorant include red colorants, green colorants, blue colorants, yellow colorants, violet colorants, and orange colorants. The chromatic colorant may be a pigment or a dye. The pigment and the dye may be used in combination. In addition, the pigment may be either an inorganic pigment or an organic pigment. In addition, as the pigment, a material in which a part of an inorganic pigment or an organic-inorganic pigment is replaced with an organic chromophore can also be used. By substituting an inorganic pigment or an organic-inorganic pigment with an organic chromophore, hue design can be easily performed.

The average primary particle diameter of the pigment is preferably 1 to 200 nm. The lower limit is preferably 5 nm or more and more preferably 10 nm or more. The upper limit is preferably 180 nm or less, more preferably 150 nm or less, and still more preferably 100 nm or less. In a case where the average primary particle diameter of the pigment is within the above-described range, dispersion stability of the pigment in the curable composition is good. In the present invention, the primary particle diameter of the pigment can be determined from a captured image obtained by observing primary particles of the pigment using a transmission electron microscope. Specifically, a projected area of the primary particles of the pigment is determined, and the corresponding equivalent circle diameter is calculated as the primary particle diameter of the pigment. In addition, the average primary particle diameter in the present invention is the arithmetic average of the primary particle diameters with respect to 400 primary particles of the pigment. In addition, the primary particle of the pigment refers to a particle which is independent without aggregation.

It is preferable that the chromatic colorant includes a pigment. The content of the pigment in the chromatic colorant is preferably 50 mass % or more, more preferably 70 mass % or more, still more preferably 80 mass % or more, and particularly preferably 90 mass % or more. Examples of the pigment include the following pigments:

Color Index (C. I.) Pigment Yellow 1, 2, 3, 4, 5, 6, 10, 11, 12, 13, 14, 15, 16, 17, 18, 20, 24, 31, 32, 34, 35, 35:1, 36, 36:1, 37, 37:1, 40, 42, 43, 53, 55, 60, 61, 62, 63, 65, 73, 74, 77, 81, 83, 86, 93, 94, 95, 97, 98, 100, 101, 104, 106, 108, 109, 110, 113, 114, 115, 116, 117, 118, 119, 120, 123, 125, 126, 127, 128, 129, 137, 138, 139, 147, 148, 150, 151, 152, 153, 154, 155, 156, 161, 162, 164, 166, 167, 168, 169, 170, 171, 172, 173, 174, 175, 176, 177, 179, 180, 181, 182, 185, 187, 188, 193, 194, 199, 213, 214, 215, 228, 231, 232 (methine-based), 233 (quinoline-based), 234 (aminoketone-based), 235 (aminoketone-based), 236 (aminoketone-based), and the like (all of which are yellow pigments);

C. I. Pigment Orange 2, 5, 13, 16, 17:1, 31, 34, 36, 38, 43, 46, 48, 49, 51, 52, 55, 59, 60, 61, 62, 64, 71, and 73 (all of which are orange pigments);

C. I. Pigment Red 1, 2, 3, 4, 5, 6, 7, 9, 10, 14, 17, 22, 23, 31, 38, 41, 48:1, 48:2, 48:3, 48:4, 49, 49:1, 49:2, 52:1, 52:2, 53:1, 57:1, 60:1, 63:1, 66, 67, 81:1, 81:2, 81:3, 83, 88, 90, 105, 112, 119, 122, 123, 144, 146, 149, 150, 155, 166, 168, 169, 170, 171, 172, 175, 176, 177, 178, 179, 184, 185, 187, 188, 190, 200, 202, 206, 207, 208, 209, 210, 216, 220, 224, 226, 242, 246, 254, 255, 264, 269, 270, 272, 279, 294 (xanthene-based, Organo Ultramarine, Bluish Red), 295 (azo-based), 296 (azo-based), 297 (aminoketone-based), and the like (all of which are red pigments);

C. I. Pigment Green 7, 10, 36, 37, 58, 59, 62, 63, 64 (phthalocyanine-based), 65 (phthalocyanine-based), 66 (phthalocyanine-based), and the like (all of which are green pigments);

C. I. Pigment Violet 1, 19, 23, 27, 32, 37, 42, 60 (triarylmethane-based), 61 (xanthene-based), and the like (all of which are violet pigments); and

C. I. Pigment Blue 1, 2, 15, 15:1, 15:2, 15:3, 15:4, 15:6, 16, 22, 29, 60, 64, 66, 79, 80, 87 (monoazo-based), 88 (methine-based), and the like (all of which are blue pigments).

In addition, a halogenated zinc phthalocyanine pigment having an average number of halogen atoms in one molecule of 10 to 14, an average number of bromine atoms in one molecule of 8 to 12, and an average number of chlorine atoms in one molecule of 2 to 5 can also be used as the green pigment. Specific examples thereof include the compounds described in WO2015/118720A. In addition, as the green pigment, compounds described in CN2010-6909027A, phthalocyanine compounds described in WO2012/102395A, which have a phosphoric acid ester as a ligand, or the like can also be used.

In addition, an aluminum phthalocyanine compound having a phosphorus atom can also be used as the blue pigment. Specific examples thereof include the compounds described in paragraph Nos. 0022 to 0030 of JP2012-247591A and paragraph No. 0047 of JP2011-157478A.

In addition, as the yellow pigment, pigments described in JP2008-074985A, compounds described in JP2008-074987A, quinophthalone compounds described in JP2013-061622A, quinophthalone compounds described in JP2013-181015A, colorants described in JP2014-085565A, pigments described in JP2016-145282A, pigments described in JP2017-201003A, pigments described in 2017-197719A, pigments described in paragraph Nos. 0011 to 0062 and 0137 to 0276 of JP2017-171912A, pigments described in paragraph Nos. 0010 to 0062 and 0138 to 0295 of JP2017-171913A, pigments described in paragraph Nos. 0011 to 0062 and 0139 to 0190 of JP2017-171914A, pigments described in paragraph Nos. 0010 to 0065 and 0142 to 0222 of JP2017-171915A, quinophthalone compounds described in JP2017-197640A, quinophthalone-based pigments described in JP2018-040835A, pigments described in JP2018-203798A, pigments described in JP2018-062578A, quinophthalone-based yellow pigments described in JP2018-155881A, compounds described in JP2018-062644A, quinophthalone compounds described in JP6432077B, or pigments described in JP6443711B can also be used.

In addition, as the yellow pigment, compounds described in JP2018-062644A can also be used. These compounds can also be used as a pigment derivative.

As the red pigment, diketopyrrolopyrrole compounds described in JP2017-201384A, in which the structure has at least one substituted bromine atom, diketopyrrolopyrrole compounds described in paragraph Nos. 0016 to 0022 of JP6248838B, diketopyrrolopyrrole compounds described in WO2012/102399A, diketopyrrolopyrrole compounds described in WO2012/117965A, naphtholazo compounds described in JP2012-229344, and the like can also be used. In addition, as the red pigment, a compound having a structure that an aromatic ring group in which a group bonded with an oxygen atom, a sulfur atom, or a nitrogen atom is introduced to an aromatic ring is bonded to a diketopyrrolopyrrole skeleton can be used.

In addition, as the red pigment, compounds described in JP6516119B and JP6525101B can also be used. These compounds can also be used as a pigment derivative.

In the present invention, a dye can also be used as the chromatic colorant. The dye is not particularly limited and a known dye can be used. Examples thereof include a pyrazoleazo-based dye, an anilinoazo-based dye, a triarylmethane-based dye, an anthraquinone-based dye, an anthrapyridone-based dye, a benzylidene-based dye, an oxonol-based dye, a pyrazolotriazoleazo-based dye, a pyridoneazo-based dye, a cyanine-based dye, a phenothiazine-based dye, a pyrrolopyrazoleazomethine-based dye, a xanthene-based dye, a phthalocyanine-based dye, a benzopyran-based dye, an indigo-based dye, and a pyrromethene-based dye. In addition, thiazole compounds described in JP2012-158649A, azo compounds described in JP2011-184493A, or azo compounds described in JP2011-145540A can also be preferably used. In addition, as yellow dyes, the quinophthalone compounds described in paragraph Nos. 0011 to 0034 of JP2013-054339A, or the quinophthalone compounds described in paragraph Nos. 0013 to 0058 of JP2014-026228A can be used.

<Achromatic Colorant>

Examples of the achromatic colorant include a black colorant and a white colorant.

(Black Colorant)

Examples of the black colorant include one or more selected from the group consisting of black pigments and black dyes.

In addition, a black colorant which is adjusted so as to be black as a whole by combining a plurality of colorants which cannot be used alone as the black colorant may be used.

For example, a plurality of pigments having a color other than black alone may be combined and used as the black pigment. Similarly, a plurality of dyes having a color other than black alone may be combined and used as the black dye, and a pigment having a color other than black alone and a dye having a color other than black alone may be combined and used as the black dye.

In the present specification, the black colorant means a coloring material which absorbs over the entire wavelength range of 400 to 700 nm.

More specifically, for example, a black colorant which meets an evaluation standard Z described below is preferable.

First, a composition containing a coloring material, a transparent resin matrix (acrylic resin or the like), and a solvent, in which the content of the coloring material is 60 mass % with respect to the total solid content, is prepared. The obtained composition is applied to a glass substrate so that the film thickness of a coating film after drying is 1 mm to form a coating film. Light shielding properties of the coating film after drying are evaluated using a spectrophotometer (UV-3600 manufactured by Hitachi High-Tech Corporation., or the like). In a case where the maximum value of transmittance of the coating film after drying in a wavelength of 400 to 700 nm is less than 10%, it can be determined that the above-described coloring material is a black colorant which meets the evaluation standard Z. In the evaluation standard Z, as the black colorant, the maximum value of transmittance of the coating film after drying in a wavelength of 400 to 700 nm is more preferably less than 8%, and still more preferably less than 5%.

Black Pigment

As the black pigment, various known black pigments can be used. The black pigment may be an inorganic pigment or an organic pigment.

From the viewpoint that light resistance of a light shielding film is more excellent, the black colorant is preferably a black pigment.

As the black pigment, a pigment which expresses black color by itself is preferable, and a pigment which expresses black color by itself and absorbs infrared ray is more preferable.

Here, the black pigment which absorbs infrared ray has absorption, for example, in a wavelength region in the infrared region (preferably, a wavelength of 650 to 1300 nm). A black pigment having a maximal absorption wavelength in a wavelength region of 675 to 900 nm is also preferable.

The particle size of the black pigment is not particularly limited, but from the viewpoint that balance between handleability and temporal stability (black pigment does not settle) of the curable composition is more excellent, the particle size is preferably 5 to 100 nm, more preferably 5 to 50 nm, and still more preferably 5 to 30 nm.

In the present specification, the particle size of the black pigment means an average primary particle diameter of particles measured by the following method. The average primary particle diameter can be measured using a transmission electron microscope (TEM). As the transmission electron microscope, for example, a transmission microscope HT7700 manufactured by Hitachi High-Tech Corporation. can be used.

A maximum length (Dmax: maximum length between two points on a contour of a particle image) and a maximum perpendicular length (DV-max: shortest length connecting perpendicularly between two straight lines in a case where the image is interposed between the two straight lines parallel with the maximum length) of a particle image obtained by using the transmission electron microscope are measured, and the geometric mean value (Dmax×DV-max)^{1/2} thereof is defined as a particle diameter. By measuring particle diameters of 100 particles by the method, the arithmetic average value thereof is defined as the average primary particle diameter of the particles.

Inorganic Pigment Used as Black Colorant

The inorganic pigment used as the black colorant is not particularly limited as long as particles have light shielding properties and contain an inorganic compound, and a known inorganic pigment can be used.

From the viewpoint that low reflection properties and light shielding properties of the light shielding film are more excellent, the black colorant is preferably an inorganic pigment.

Examples of the inorganic pigment include Group 4 metal elements such as titanium (Ti) and zirconium (Zr), Group 5 metal elements such as vanadium (V) and niobium (Nb), and metal oxides, metal nitrides, and metal oxynitrides containing one or two or more metal elements selected from the group consisting of cobalt (Co), chromium (Cr), copper (Cu), manganese (Mn), ruthenium (Ru), iron (Fe), nickel (Ni), tin (Sn), and silver (Ag).

As the above-described metal oxides, metal nitrides, and metal oxynitrides, particles in which other atoms are mixed may be used. For example, metal nitride-containing particles further containing an atom selected from Group 13 to 17 elements of the periodic table (preferably, an oxygen atom and/or a sulfur atom) can be used.

A method for producing the above-described metal oxides, metal nitrides, or metal oxynitrides is not particularly limited as long as a black pigment having desired physical properties can be obtained, and a known production method such as a gas phase reaction method can be used. Examples of the gas phase reaction method include an electric furnace method and a thermal plasma method, and from the viewpoint that there are few impurities mixed in, the particle size is easy to match, and productivity is high, a thermal plasma method is preferable.

The above-described metal oxides, metal nitrides, or metal oxynitrides may be subjected to a surface modification treatment. For example, a surface modification treatment may be performed with a surface treatment agent having both a silicone group and an alkyl group. Examples of such inorganic particles include “KTP-09” series (manufactured by Shin-Etsu Chemical Co., Ltd.).

Among these, from the viewpoint that occurrence of undercut in a case of forming the light shielding film can be suppressed, nitrides or oxynitrides of one or more metals selected from the group consisting of titanium, vanadium, zirconium, and niobium are more preferable. In addition, from the viewpoint that moisture resistance of the light shielding film is more excellent, oxynitrides of one or more metals selected from the group consisting of titanium, vanadium, zirconium, and niobium are still more preferable, and titanium oxynitride (titanium black) is particularly preferable.

Titanium black is black particles containing titanium oxynitride. The surface of the titanium black can be modified, as necessary, according to the purpose of improving dispersibility, suppressing aggregating properties, and the like. The titanium black can be coated with silicon oxide, titanium oxide, germanium oxide, aluminum oxide, magnesium oxide, or zirconium oxide, and can be subjected to a treatment with a water repellent substance as shown in JP2007-302836A.

As a method for producing the titanium black, a method of heating and reducing a mixture of titanium dioxide and metallic titanium in a reducing atmosphere (JP1974-5432A (JP-S49-5432A)), a method of reducing ultrafine titanium dioxide obtained by high-temperature hydrolysis of titanium tetrachloride in a hydrogen-containing reducing atmosphere (JP1982-205322A (JP-S57-205322A)), a method of high temperature reduction of titanium dioxide or titanium hydroxide in the presence of ammonia (JP1985-65069A (JP-S60-65069A) and JP1986-201610A (JP-S61-201610A)), a method of adhering a vanadium compound to titanium dioxide or titanium hydroxide and reducing at high-temperature in the presence of ammonia (JP1986-201610A (JP-S61-201610A)), and the like can be used, but the method for producing the titanium black is not particularly limited thereto.

The particle size of the titanium black is not particularly limited, but is preferably 10 to 45 nm and more preferably 12 to 20 nm. The specific surface area of the titanium black is not particularly limited, but in order to set water repellency after the surface treatment with a water repellent agent to be specified performance, a value measured by Brunauer, Emmett, Teller (BET) method is preferably 5 to 150 m²/g and more preferably 20 to 100 m²/g.

Examples of a commercially available product of the titanium black include Titanium black 10S, 12S, 13R, 13M, 13M-C, 13R, 13R—N, and 13M-T (trade name, manufactured by Mitsubishi Materials Corporation), Tilack D (trade name, manufactured by Akokasei Co., Ltd.), and MT-150A (trade name, manufactured by TAYCA Co., Ltd.).

The curable composition also preferably contains the titanium black as a dispersoid containing titanium black and an Si atom. In this aspect, the titanium black is contained as a dispersoid in the curable composition. The content ratio (Si/Ti) of Si atoms to Ti atoms in the dispersoid is preferably 0.05 to 0.5, more preferably 0.07 to 0.4 in terms of mass. Here, the above-described dispersoid includes both those in which the titanium black is in a state of primary particle and those in which the titanium black is in a state of aggregate (secondary particle).

In addition, in a case where Si/Ti of the dispersoid is a predetermined value or more, a residue is less likely to remain in a removed portion in a case where a coating film using the dispersoid is patterned by optical lithography or the like, and in a case where Si/Ti of the dispersoid is a predetermined value or less, light shielding performance tends to be good.

In order to change Si/Ti of the dispersoid (for example, to make it 0.05 or more), the following method can be used. First, a dispersion is obtained by dispersing titanium oxide and silica particles using a disperser, and by reducing the mixture at a high temperature (for example, 850° C. to 1000° C.), a dispersoid containing titanium black particles as a main component and containing Si and Ti can be obtained. Titanium black in which Si/Ti has been adjusted can be produced, for example, by a method described in paragraph Nos. 0005 and 0016 to 0021 of JP2008-266045A.

The content ratio (Si/Ti) of Si atoms to Ti atoms in the dispersoid is measured, for example, using a method (2-1) or method (2-3) described in paragraphs 0054 to 0056 of WO2011/049090A.

In the dispersoid containing titanium black and Si atom, the above-described titanium black can be used. In addition, in the dispersoid, for the purpose of adjusting dispersibility, colorability, and the like, in addition to the titanium black, one or two or more black pigments consisting of composite oxides of a plurality of metals selected from Cu, Fe, Mn, V, Ni, and the like, cobalt oxide, iron oxide, carbon black, and aniline black may be used in combination as the dispersoid. In this case, it is preferable that the dispersoid consisting of titanium black occupies 50 mass % or more of the total dispersoid.

Examples of the inorganic pigment include carbon black.

Examples of the carbon black include furnace black, channel black, thermal black, acetylene black, and lamp black.

As the carbon black, carbon black produced by a known method such as an oil furnace method may be used, or a commercially available product may be used. Specific examples of the commercially available product of the carbon black include organic pigments such as C. I. Pigment Black 1 and inorganic pigments such as C. I. Pigment Black 7.

As the carbon black, surface-treated carbon black is preferable. By the surface treatment, a particle surface state of the carbon black can be reformed, and dispersion stability in the curable composition can be improved. Examples of the surface treatment include a coating treatment with a resin, a surface treatment for introducing an acidic group, and a surface treatment with a silane coupling agent.

As the carbon black, carbon black coated with a resin is preferable. By coating the surface of the carbon black particles with an insulating resin, light shielding properties and insulating properties of the light shielding film can be improved. In addition, reliability of the image display device can be improved by reducing leakage current and the like. Therefore, it is suitable for applications in which the light shielding film is required to have insulating properties.

Examples of the coating resin include an epoxy resin, polyamide, polyamidoimide, a novolac resin, a phenol resin, a urea resin, a melamine resin, polyurethane, a diallyl phthalate resin, an alkylbenzene resin, polystyrene, polycarbonate, polybutylene terephthalate, and modified polyphenylene oxide.

From the viewpoint that light shielding properties and insulating properties of the light shielding film are more excellent, the content of the coating resin is preferably 0.1 to 40 mass % and more preferably 0.5 to 30 mass % with respect to the total of the carbon black and the coating resin.

In addition, zirconium nitride described in JP2017-222559A, WO2019/130772A, and the like can also be preferably used.

Organic Pigment Used as Black Colorant

The organic pigment used as the black colorant is not particularly limited as long as particles have light shielding properties and contain an organic compound, and a known organic pigment can be used.

In the present invention, examples of the organic pigment include a bisbenzofuranone compound, an azomethine compound, a perylene compound, and an azo compound. Among these, a bisbenzofuranone compound or a perylene compound is preferable.

Examples of the bisbenzofuranone compound include the compounds described in JP2010-534726A, JP2012-515233A, and JP2012-515234A, and the like. The bisbenzofuranone compound is available, for example, as “Irgaphor Black” (trade name) manufactured by BASF.

Examples of the perylene compound include the compounds described in JP1987-1753A (JP-S62-1753A) and JP1988-26784B (JP-S63-26784B). The perylene compound is available as C. I. Pigment Black 21, 30, 31, 32, 33, and 34.

Black Dye

As the black dye, a dye which expresses black color by itself can be used, and for example, a pyrazoleazo compound, a pyrromethene compound, an anilinoazo compound, a triphenylmethane compound, an anthraquinone compound, a benzylidene compound, an oxonol compound, a pyrazolotriazoleazo compound, a pyridoneazo compound, a cyanine compound, a phenothiazine compound, a pyrrolopyrazoleazomethine compound, and the like can be used.

In addition, as the black dye, compounds described in JP1989-90403A (JP-S64-90403A), JP1989-91102A (JP-S64-91102A), JP1989-94301A (JP-H1-94301A), JP1994-11614A (JP-H6-11614A), JP2592207B, U.S. Pat. Nos. 4,808,501A, 5,667,920A, U.S. Pat. Nos. 5,059,500A, 5,667,920A, JP1993-333207A (JP-H5-333207A), JP1994-35183A (JP-H6-35183A), JP1994-51115A (JP-H6-51115A), JP1994-194828A (JP-H6-194828A), and the like can be referred to, the contents of which are incorporated herein by reference.

Specific examples of these black dyes include dyes defined by Color Index (C. I.) of solvent black 27 to 47, and a dye defined by C. I. of solvent black 27, 29, or 34 is preferable.

In addition, examples of a commercially available product of these black dyes include dyes such as Spiron Black MH and Black BH (both manufactured by Hodogaya Chemical Co., Ltd.), VALIFAST Black 3804, 3810, 3820, and 3830 (all manufactured by ORIENT CHEMICAL INDUSTRIES CO., LTD.), Savinyl Black RLSN (manufactured by Clariant), and KAYASET Black K-R and K-BL (both manufactured by Nippon Kayaku Co., Ltd.).

In addition, as the black dye, a coloring agent multimer may be used. Examples of the coloring agent multimer include compounds described in JP2011-213925A and JP2013-041097A. In addition, a polymerizable dye having a polymerizable property in the molecule may be used, and examples of a commercially available product thereof include RDW series manufactured by Wako Pure Chemical Corporation.

Further, as described above, a plurality of dyes having a color other than black alone may be combined and used as the black dye. As such coloring dye, for example, in addition to dyes of chromatic colors such as R (red), G (green), and B (blue) (chromatic dyes), dyes described in paragraphs 0027 to 0200 of JP2014-42375A can also be used.

(White Colorant)

Examples of the white colorant include one or more selected from the group consisting of white pigments and white dyes, and from the viewpoint of weather fastness and the like, a white pigment is preferable.

Examples of the white pigment include titanium oxide, strontium titanate, barium titanate, zinc oxide, magnesium oxide, zirconium oxide, aluminum oxide, barium sulfate, silica, talc, mica, aluminum hydroxide, calcium silicate, aluminum silicate, hollow resin particles, and zinc sulfide. The white pigment is preferably particles having a titanium atom, more preferably titanium oxide. As the titanium oxide, titanium oxide described in “Titanium Oxide—Physical Properties and Applied Technology, written by Manabu Kiyono, Jun. 25, 1991, published by Gihodo Shuppan Co., Ltd.” can also be suitably used.

In addition, as the white pigment, C. I. Pigment White 1, 3, 6, 16, 18, and 21 can be used.

<Infrared Absorber>

The infrared absorber means a compound having absorption in a wavelength region in the infrared region (preferably, a wavelength of 650 to 1300 nm). As the infrared absorber, a compound having a maximal absorption wavelength in a wavelength region of 675 to 900 nm is preferable.

Examples of the colorant having such spectral characteristics include a pyrrolopyrrole compound, a copper compound, a cyanine compound, a phthalocyanine compound, an iminium compound, a thiol complex compound, a transition metal oxide compound, a squarylium compound, a naphthalocyanine compound, a quaterrylene compound, a dithiol metal complex compound, and a croconium compound.

As the phthalocyanine compound, naphthalocyanine compound, iminium compound, cyanine compound, squarylium compound, and croconium compound, compounds described in paragraphs 0010 to 0081 of JP2010-111750A may also be used, the contents of which are incorporated herein by reference. The cyanine compound can be found in, for example, “Functional Colorants by Makoto Okawara, Masaru Matsuoka, Teijiro Kitao, and Tsuneoka Hirashima, published by Kodansha Scientific Ltd.”, the content of which is incorporated herein by reference.

As the colorant having the above-described spectral characteristics, compounds described in paragraphs 0004 to 0016 of JP1995-164729A (JP-H07-164729A) and/or compounds described in paragraphs 0027 to 0062 of JP2002-146254A, or near-infrared absorbing particles consisting of crystallites of oxides containing Cu and/or P described in paragraphs 0034 to 0067 of JP2011-164583A and having a number average aggregated particle diameter of 5 to 200 nm can also be used.

As the compound having a maximal absorption wavelength in a wavelength region of 675 to 900 nm, at least one selected from the group consisting of a cyanine compound, a pyrrolopyrrole compound, a squarylium compound, a phthalocyanine compound, and a naphthalocyanine compound is preferable.

In addition, the infrared absorber is preferably a compound which dissolves in water at 25° C. in an amount of 1 mass % or more, and more preferably a compound which dissolves in water at 25° C. in an amount of 10 mass % or more. By using such a compound, solvent resistance is improved.

As the pyrrolopyrrole compound, paragraphs 0049 to 0062 of JP2010-222557A can be referred to, the content of which is incorporated herein by reference. As the cyanine compound and the squarylium compound, paragraphs 0022 to 0063 of WO2014/088063A, paragraphs 0053 to 0118 of WO2014/030628A, paragraphs 0028 to 0074 of JP2014-59550A, paragraphs 0013 to 0091 of WO2012/169447A, paragraphs 0019 to 0033 of JP2015-176046A, paragraphs 0053 to 0099 of JP2014-63144A, paragraphs 0085 to 0150 of JP2014-52431, paragraphs 0076 to 0124 of JP2014-44301A, paragraphs 0045 to 0078 of JP2012-8532A, paragraphs 0027 to 0067 of JP2015-172102A, paragraphs 0029 to 0067 of JP2015-172004A, paragraphs 0029 to 0085 of JP2015-40895A, paragraphs 0022 to 0036 of JP2014-126642A, paragraphs 0011 to 0017 of JP2014-148567A, paragraphs 0010 to 0025 of JP2015-157893A, paragraphs 0013 to 0026 of JP2014-095007A, paragraphs 0013 to 0047 of JP2014-80487A, paragraphs 0007 to 0028 of JP2013-227403A, and the like can be referred to, the contents of which are incorporated herein by reference.

[Resin]

The curable composition according to the embodiment of the present invention contains a resin. The resin is blended in, for example, an application for dispersing particles such as a pigment in the curable composition or an application as a binder. Mainly, a resin which is used for dispersing particles such as a pigment is also referred to as a dispersant. However, such applications of the resin are only exemplary, and the resin can also be used for other purposes in addition to such applications.

The weight-average molecular weight (Mw) of the resin is preferably 2000 to 2000000. The upper limit is preferably 1000000 or less and more preferably 500000 or less. The lower limit is preferably 3000 or more and more preferably 5000 or more.

Examples of the resin include a (meth)acrylic resin, an epoxy resin, an ene-thiol resin, a polycarbonate resin, a polyether resin, a polyarylate resin, a polysulfone resin, a polyethersulfone resin, a polyphenylene resin, a polyarylene ether phosphine oxide resin, a polyimide resin, a polyamidoimide resin, a polyolefin resin, a cyclic olefin resin, a polyester resin, and a styrene resin. These resins may be used singly or as a mixture of two or more kinds thereof. From the viewpoint of improving heat resistance, as the cyclic olefin resin, a norbornene resin is preferable. Examples of a commercially available product of the norbornene resin include ARTON series (for example, ARTON F4520) manufactured by JSR Corporation. Examples of the epoxy resin include an epoxy resin which is a glycidyl etherified product of a phenol compound, an epoxy resin which is a glycidyl etherified product of various novolac resins, an alicyclic epoxy resin, an aliphatic epoxy resin, a heterocyclic epoxy resin, a glycidyl ester-based epoxy resin, a glycidyl amine-based epoxy resin, an epoxy resin obtained by glycidylating halogenated phenols, a condensate of a silicon compound having an epoxy group and another silicon compound, and a copolymer of a polymerizable unsaturated compound having an epoxy group and another polymerizable unsaturated compound. In addition, as the epoxy resin, MARPROOF G-0150M, G-0105SA, G-0130SP, G-0250SP, G-1005S, G-1005SA, G-1010S, G-2050M, G-01100, or G-01758 (manufactured by NOF Corporation, an epoxy group-containing polymer) can also be used. In addition, as the resin, resins described in Examples of WO2016/088645A can be used. In addition, in a case where the resin has an ethylenically unsaturated group, particularly a (meth)acryloyl group in the side chain, in the resin, it is also preferable that the main chain and the ethylenically unsaturated group are bonded through a divalent linking group having an alicyclic structure.

The curable composition according to the embodiment of the present invention preferably includes an alkali-soluble resin. In a case where the curable composition according to the embodiment of the present invention includes an alkali-soluble resin, developability of the curable composition is improved, and in a case where a pattern is formed by a photolithography method using the curable composition according to the embodiment of the present invention, the generation of development residue and the like can be effectively suppressed. Examples of the alkali-soluble resin include resins having an acid group. Examples of the acid group include a carboxy group, a phosphoric acid group, a sulfo group, and a phenolic hydroxy group, and a carboxy group is preferable. The acid group included in the alkali-soluble resin may be used singly or in combination of two or more kinds thereof. The alkali-soluble resin can also be used as a dispersant.

The alkali-soluble resin preferably includes a repeating unit having an acid group in the side chain, and more preferably includes 5 to 70 mol % of repeating units having an acid group in the side chain with respect to the total repeating units of the resin. The upper limit of the content of the repeating unit having an acid group in the side chain is preferably 50 mol % or less and more preferably 30 mol % or less. The lower limit of the content of the repeating unit having an acid group in the side chain is preferably 10 mol % or more and more preferably 20 mol % or more.

The alkali-soluble resin is also preferably an alkali-soluble resin having a polymerizable group. Examples of the polymerizable group include a (meth)allyl group (meaning both an allyl group and a methallyl group) and a (meth)acryloyl group. The alkali-soluble resin having a polymerizable group is preferably a resin including a repeating unit having a polymerizable group in the side chain and a repeating unit having an acid group in the side chain.

It is also preferable that the alkali-soluble resin includes a repeating unit derived from a monomer component including a compound represented by Formula (ED1) and/or a compound represented by Formula (ED2) (hereinafter, these compounds may be referred to as an “ether dimer”).

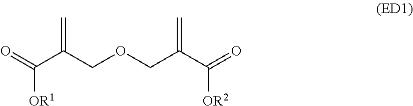

In Formula (ED1), R¹ and R² each independently represent a hydrogen atom or a hydrocarbon group having 1 to 25 carbon atoms, which may have a substituent.

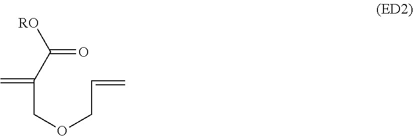

In Formula (ED2), R represents a hydrogen atom or an organic group having 1 to 30 carbon atoms. With regard to details of Formula (ED2), reference can be made to the description in JP2010-168539A, the contents of which are incorporated herein by reference.

With regard to the specific examples of the ether dimer, reference can be made to the description in paragraph No. 0317 of JP2013-029760A, the contents of which are incorporated herein by reference.

It is also preferable that the alkali-soluble resin includes a repeating unit derived from a compound represented by Formula (X).

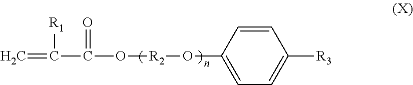

In Formula (X), R₁ represents a hydrogen atom or a methyl group, R₂ represents an alkylene group having 2 to 10 carbon atoms, and R₃ represents a hydrogen atom or an alkyl group having 1 to 20 carbon atoms which may include a benzene ring. n represents an integer of 1 to 15.

With regard to the alkali-soluble resin, reference can be made to the description in paragraph Nos. 0558 to 0571 of JP2012-208494A (paragraph Nos. 0685 to 0700 of the corresponding US2012/0235099A) and the description in paragraph Nos. 0076 to 0099 of JP2012-198408A, the contents of which are incorporated herein by reference.

The acid value of the resin (particularly, the alkali-soluble resin) is preferably 10 to 500 mgKOH/g. The lower limit is preferably 30 mgKOH/g or more, more preferably 50 mgKOH/g or more, and still more preferably 70 mgKOH/g or more. The upper limit is preferably 400 mgKOH/g or less, more preferably 300 mgKOH/g or less, still more preferably 200 mgKOH/g or less, and particularly preferably 100 mgKOH/g or less.

The ethylenically unsaturated bond equivalent (meaning a value obtained by dividing the number of ethylenically unsaturated groups in the polymerizable compound by the molecular weight (g/mol) of the polymerizable compound) of the resin (particularly, the alkali-soluble resin) is preferably 0.4 to 2.5 mmol/g. The lower limit is preferably 1.0 mmol/g or more and more preferably 1.2 mmol/g or more. The upper limit is preferably 2.3 mmol/g or less and more preferably 2.0 mmol/g or less.

In particular, in a case where the curable composition according to the embodiment of the present invention includes a resin having an acid value of 10 to 100 mgKOH/g and an ethylenically unsaturated bond equivalent of 1.0 to 2.0 mmol/g, occurrence of peeling after a humidity test can be further suppressed.

Specific examples of the alkali-soluble resin include resins having the following structures. In the following structural formulae, Me represents a methyl group.

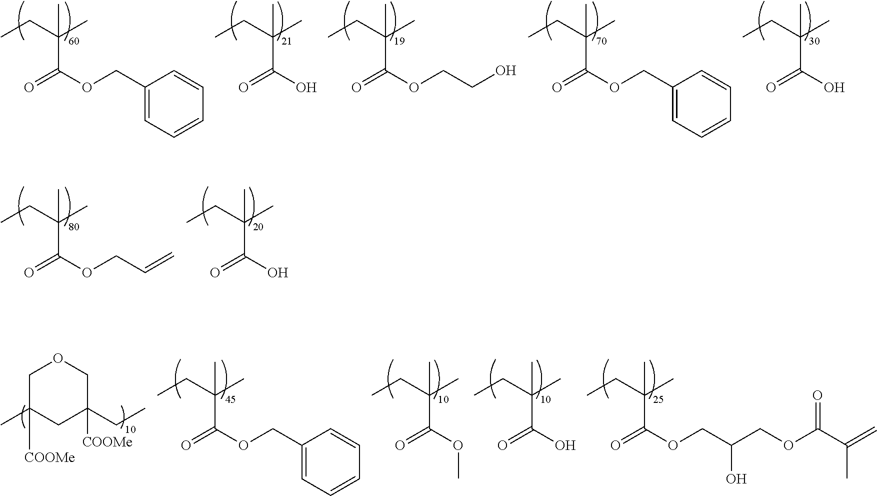

The curable composition according to the embodiment of the present invention preferably includes a resin having a basic group. Examples of the basic group include an amino group and an ammonium salt group. The resin having a basic group may further have an acid group in addition to the basic group. In a case where the resin having a basic group further has an acid group, such a resin is also an alkali-soluble resin.

Examples of the resin having a basic group include a resin having a tertiary amino group or a quaternary ammonium salt group. The resin having a tertiary amino group and a quaternary ammonium salt group is preferably a resin which has a repeating unit having a tertiary amino group and a repeating unit having a quaternary ammonium salt group. In addition, the resin having a tertiary amino group and a quaternary ammonium salt group may further have a repeating unit having an acid group. The resin having a tertiary amino group and a quaternary ammonium salt group also preferably has a block structure. In the resin having a tertiary amino group and a quaternary ammonium salt group, it is preferable that the amine value is 10 to 250 mgKOH/g and the quaternary ammonium salt value is 10 to 90 mgKOH/g, and it is more preferable that the amine value is 50 to 200 mgKOH/g and the quaternary ammonium salt value is 10 to 50 mgKOH/g. The weight-average molecular weight (Mw) of the resin having a tertiary amino group and a quaternary ammonium salt group is preferably 3000 to 300000 and more preferably 5000 to 30000. The resin having a tertiary amino group and a quaternary ammonium salt group can be produced by copolymerizing an ethylenically unsaturated monomer having a tertiary amino group, an ethylenically unsaturated monomer having a quaternary ammonium salt group, and other ethylenically unsaturated monomers as necessary. Examples of the ethylenically unsaturated monomer having a tertiary amino group and the ethylenically unsaturated monomer having a quaternary ammonium salt group include those described in paragraph Nos. 0150 to 0170 of WO2018/230486A, the contents of which are incorporated herein by reference. In addition, a resin having an acidic group, which is described in paragraph Nos. 0079 to 0160 of JP2018-87939A, may be used in combination.

In addition, the resin having a basic group is also preferably a resin including a nitrogen atom in the main chain. The resin including a nitrogen atom in the main chain (hereinafter, also referred to as an oligoimine-based resin) preferably includes at least one repeating unit having a nitrogen atom, selected from a poly(lower alkyleneimine)-based repeating unit, a polyallylamine-based repeating unit, a polydiallylamine-based repeating unit, a metaxylene diamine-epichlorohydrin polycondensate-based repeating unit, and a polyvinylamine-based repeating unit. In addition, as the oligoimine-based resin, a resin which has a repeating unit having a partial structure X having a functional group of pKa 14 or less, and a repeating unit having a side chain including an oligomer chain or a polymer chain Y having 40 to 10000 atoms is preferable. The oligoimine-based resin may further have a repeating unit having an acid group. With regard to the oligoimine-based resin, reference can be made to the description in paragraph Nos. 0102 to 0166 of JP2012-255128A, the contents of which are incorporated herein by reference.

The curable composition according to the embodiment of the present invention may also include a resin as a dispersant, and preferably includes a resin as a dispersant. Examples of the dispersant include an acidic dispersant (acidic resin) and a basic dispersant (basic resin). Here, the acidic dispersant (acidic resin) represents a resin in which the amount of the acid group is larger than the amount of the basic group. The acidic dispersant (acidic resin) is preferably a resin in which the amount of the acid group occupies 70 mol % or more in a case where the total amount of the acid group and the basic group is 100 mol %, and more preferably a resin substantially consisting of only an acid group. The acid group included in the acidic dispersant (acidic resin) is preferably a carboxy group. In addition, the basic dispersant (basic resin) represents a resin in which the amount of the basic group is larger than the amount of the acid group. The basic dispersant (basic resin) is preferably a resin in which the amount of the basic group is more than 50 mol % in a case where the total amount of the acid group and the basic group is 100 mol %. The dispersant is preferably a resin having a basic group, and more preferably a basic dispersant.

Examples of the resin used as a dispersant include the above-described resin having a tertiary amino group and a quaternary ammonium salt group and the above-described oligoimine-based resin. In addition, it is also preferable that the resin used as a dispersant is a graft resin. Examples of the graft resin include a resin which has a repeating unit having a graft chain. The graft resin may further have a repeating unit having an acid group. With regard to details of the graft resin, reference can be made to the description in paragraph Nos. 0025 to 0094 of JP2012-255128A, the contents of which are incorporated herein by reference.

In order to improve interaction between the graft chain and the solvent, thereby improving dispersibility of the coloring material and the like, the graft chain is preferably a graft chain containing at least one selected from the group consisting of a polyester structure, a polyether structure, and a poly(meth) acrylate structure, and more preferably a graft chain containing at least one of a polyester structure or a polyether structure.

In addition, the resin used as a dispersant is also preferably a resin which includes a repeating unit having an acid group. In addition, it is also preferable that the resin used as a dispersant is a resin having a structure in which a plurality of polymer chains are bonded to a core portion. Examples of such a resin include dendrimers (including star polymers). In addition, specific examples of the dendrimer include polymer compounds C-1 to C-31 described in paragraph Nos. 0196 to 0209 of JP2013-043962A. In addition, the above-described alkali-soluble resin can also be used as a dispersant.

The dispersant is available as a commercially available product, and specific examples thereof include Disperbyk-111 (manufactured by BYK Chemie) and SOLSPERSE 76500 (manufactured by Lubrizol Corporation). The dispersants described in paragraph Nos. 0041 to 0130 of JP2014-130338A can also be used, the contents of which are incorporated herein by reference.

It is also preferable to use the dispersant described in JP2019-078878A.

The content of the resin in the total solid content of the curable composition is preferably 1 to 50 mass %. The lower limit is preferably 5 mass % or more and more preferably 7 mass % or more. The upper limit is preferably 40 mass % or less and more preferably 30 mass % or less.

In addition, in a case where the curable composition according to the embodiment of the present invention contains an alkali-soluble resin, the content of the alkali-soluble resin in the total solid content of the curable composition is preferably 1 to 50 mass %. The lower limit is preferably 5 mass % or more and more preferably 7 mass % or more. The upper limit is preferably 40 mass % or less and more preferably 30 mass % or less. In addition, the content of the alkali-soluble resin in the resin included in the curable composition is preferably 50 to 100 mass %, more preferably 75 to 100 mass %, and still more preferably 90 to 100 mass %.

In addition, in a case where the curable composition according to the embodiment of the present invention contains a resin as a dispersant, the content of the resin as a dispersant in the total solid content of the curable composition is preferably 0.1 to 40 mass %. The upper limit is preferably 20 mass % or less and still more preferably 10 mass % or less. The lower limit is preferably 0.5 mass % or more and still more preferably 1 mass % or more.

The curable composition according to the embodiment of the present invention may include only one kind of the resin or two or more kinds thereof. In a case of including two or more kinds thereof, the total amount thereof is preferably within the above-described range.

[Polymerizable Compound]

The curable composition according to the embodiment of the present invention contains a polymerizable compound.

The content of the polymerizable compound is not particularly limited, but is preferably 5 to 60 mass %, more preferably 7 to 35 mass %, and still more preferably 9 to 20 mass % with respect to the total solid content of the curable composition.

The polymerizable compound may be used alone or in combination of two or more kinds thereof. In a case where two or more kinds of polymerizable compounds are used, it is preferable that the total content thereof is within the above-described range.

The molecular weight (or weight-average molecular weight) of the polymerizable compound is not particularly limited, but is preferably 2500 or less.

The polymerizable compound is preferably a compound containing an ethylenically unsaturated group (a group containing an ethylenically unsaturated bond).

That is, the curable composition according to the embodiment of the present invention preferably contains a low-molecular-weight compound containing an ethylenically unsaturated group as a polymerizable compound.

The polymerizable compound is preferably a compound containing one or more ethylenically unsaturated bonds, more preferably a compound containing two or more ethylenically unsaturated bonds, still more preferably a compound containing three or more ethylenically unsaturated bonds, and particularly preferably a compound containing four or more ethylenically unsaturated bonds. The upper limit is, for example, 15 or less. Examples of the ethylenically unsaturated group include a vinyl group, a (meth)allyl group, and a (meth)acryloyl group.

As the polymerizable compound, for example, compounds described in paragraph 0050 of JP2008-260927A and paragraph 0040 of JP2015-68893A can be used, the contents of which are incorporated herein by reference.

The polymerizable compound may be in any chemical form such as, for example, a monomer, a prepolymer, an oligomer, a mixture thereof, and a multimer thereof.

As the polymerizable compound, a (meth)acrylate compound having 3 to 15 functional groups is preferable, a (meth)acrylate compound having 3 to 6 functional groups is more preferable, and a (meth)acrylate compound having 5 or 6 functional groups is still more preferable.

The polymerizable compound is also preferably a compound containing one or more ethylenically unsaturated groups and having a boiling point of 100° C. or higher under normal pressure. For example, compounds described in paragraph 0227 of JP2013-29760A and paragraphs 0254 to 0257 of JP2008-292970A can be referred to, the contents of which are incorporated herein by reference.

As the polymerizable compound, dipentaerythritol triacrylate (as a commercially available product, for example, KAYARAD D-330 manufactured by Nippon Kayaku Co., Ltd.), dipentaerythritol tetraacrylate (as a commercially available product, for example, KAYARAD D-320 manufactured by Nippon Kayaku Co., Ltd.), dipentaerythritol penta(meth)acrylate (as a commercially available product, for example, KAYARAD D-310 manufactured by Nippon Kayaku Co., Ltd.), dipentaerythritol hexa(meth)acrylate (as a commercially available product, for example, KAYARAD DPHA manufactured by Nippon Kayaku Co., Ltd., and A-DPH-12E manufactured by Shin-Nakamura Chemical Co., Ltd.), or a structure in which these (meth)acryloyl groups are bonded through an ethylene glycol residue or a propylene glycol residue (for example, SR454 and SR499 which are commercially available products from Sartomer) is preferable. An oligomer type of these compounds can be used. In addition, NK ESTER A-TMMT (pentaerythritol tetraacrylate, manufactured by Shin-Nakamura Chemical Co., Ltd.) KAYARAD RP-1040, KAYARAD DPEA-12LT, KAYARAD DPHA LT, KAYARAD RP-3060, and KAYARAD DPEA-12 (all trade names, manufactured by Nippon Kayaku Co., Ltd.), and the like may be used. In addition, as the polymerizable compound, urethane (meth)acrylate-based compound having both (meth)acryloyl group and urethane bond in the compound may be used, and for example, KAYARAD DPHA-40H (trade name, manufactured by Nippon Kayaku Co., Ltd.) may be used.

Preferred aspects of the polymerizable compound are shown below.

The polymerizable compound may have an acid group such as a carboxylic acid group, a sulfonic acid group, and a phosphoric acid group. The polymerizable compound containing an acid group is preferably an ester of an aliphatic polyhydroxy compound and an unsaturated carboxylic acid, more preferably a polymerizable compound having an acid group by reacting an unreacted hydroxy group of an aliphatic polyhydroxy compound with a non-aromatic carboxylic acid anhydride, and in this ester, it is still more preferable that the aliphatic polyhydroxy compound is pentaerythritol and/or dipentaerythritol. Examples of a commercially available product include ARONIX TO-2349, M-305, M-510, and M-520 manufactured by Toagosei Co., Ltd.

The acid value of the polymerizable compound containing an acid group is preferably 0.1 to 40 mgKOH/g and more preferably 5 to 30 mgKOH/g. In a case where the acid value of the polymerizable compound is 0.1 mgKOH/g or more, developing and dissolving characteristics are good, and in a case where the acid value of the polymerizable compound is 40 mgKOH/g or less, it is advantageous in production and/or handling. Furthermore, photopolymerization performance is good and curing properties are excellent.

The polymerizable compound is also preferably a compound containing a caprolactone structure.

The compound containing a caprolactone structure is not particularly limited as long as, for example, the compound contains a caprolactone structure in the molecule, and examples thereof include a c-caprolactone-modified polyfunctional (meth)acrylate obtained by esterifying (meth)acrylic acid and c-caprolactone with a polyhydric alcohol such as trimethylolethane, ditrimethylolethane, trimethylolpropane, ditrimethylolpropane, pentaerythritol, dipentaerythritol, tripentaerythritol, glycerin, diglycerol, and trimethylolmelamine. Among these, a compound containing a caprolactone structure represented by Formula (Z-1) is preferable.

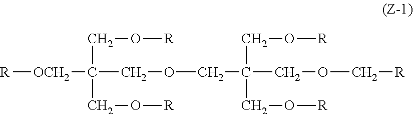

In Formula (Z-1), all of six R's represent a group represented by Formula (Z-2), or one to five R's among the six R's represent a group represented by Formula (Z-2) and the remaining R's represent a group represented by Formula (Z-3).

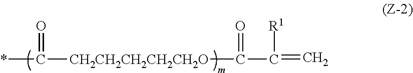

In Formula (Z-2), R¹ represents a hydrogen atom or a methyl group, m represents the number of 1 or 2, and “*” represents a bonding site.

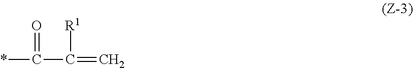

In Formula (Z-3), R¹ represents a hydrogen atom or a methyl group and “*” represents a bonding position.

The polymerizable compound containing a caprolactone structure is commercially available, for example, from Nippon Kayaku Co., Ltd. as KAYARAD DPCA series, and examples thereof include DPCA-20 (compound in which m is 1 in Formulae (Z-1) to (Z-3), the number of groups represented by Formula (Z-2) is 2, and R¹'s are all hydrogen atoms), DPCA-30 (compound in which m is 1 in Formulae (Z-1) to (Z-3), the number of groups represented by Formula (Z-2) is 3, and R¹'s are all hydrogen atoms), DPCA-60 (compound in which m is 1 in Formulae (Z-1) to (Z-3), the number of groups represented by Formula (Z-2) is 6, and R¹'s are all hydrogen atoms), and DPCA-120 (m is 2 in Formulae (Z-1) to (Z-3), the number of groups represented by Formula (Z-2) is 6, and R¹'s are all hydrogen atoms). In addition, examples of a commercially available product of the polymerizable compound containing a caprolactone structure also include M-350 (trade name) (trimethylolpropane triacrylate) manufactured by Toagosei Co., Ltd.

As the polymerizable compound, a compound represented by Formula (Z-4) or (Z-5) can also be used.

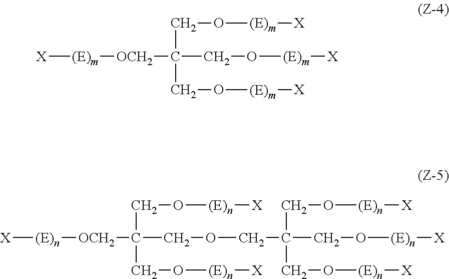

In Formulae (Z-4) and (Z-5), E represents—((CH₂)_{y}CH₂O)— or —((CH₂)_{y}CH(CH₃)O)—, y represents an integer of 0 to 10, and X represents a (meth)acryloyl group, a hydrogen atom, or a carboxylic acid group.

In Formula (Z-4), the total number of (meth)acryloyl groups is 3 or 4, m represents an integer of 0 to 10, and the sum of m's is an integer of 0 to 40.

In Formula (Z-5), the total number of (meth)acryloyl groups is 5 or 6, n represents an integer of 0 to 10, and the sum of n's is an integer of 0 to 60.

In Formula (Z-4), m represents preferably an integer of 0 to 6 and more preferably an integer of 0 to 4.

In addition, the sum of m's is preferably an integer of 2 to 40, more preferably an integer of 2 to 16, and still more preferably an integer of 4 to 8.

In Formula (Z-5), n represents preferably an integer of 0 to 6 and more preferably an integer of 0 to 4.

In addition, the sum of n's is preferably an integer of 3 to 60, more preferably an integer of 3 to 24, and still more preferably an integer of 6 to 12.

In addition, in —((CH₂)_{y}CH₂O)— or —((CH₂)_{y}CH(CH₃)O)— in Formula (Z-4) or (Z-5), it is preferable that the terminal on the oxygen atom side is bonded to X.

The compound represented by Formula (Z-4) or (Z-5) may be used alone or in combination of two or more thereof. In particular, in Formula (Z-5), an aspect in which all six X's are acryloyl groups is preferable, and in Formula (Z-6), an aspect in which a compound that all six X's are acryloyl groups and a compound that at least one of the six X's has a hydrogen atom are mixed is preferable. With such an aspect, developability can be further improved.

In addition, the total content of the compound represented by Formula (Z-4) or (Z-5) in the polymerizable compound is preferably 20 mass % or more, and more preferably 50 mass % or more.

Among the compounds represented by Formula (Z-4) or (Z-5), a pentaerythritol derivative and/or a dipentaerythritol derivative are more preferable.

In addition, the polymerizable compound may contain a cardo skeleton.

The polymerizable compound containing a cardo skeleton is preferably a polymerizable compound containing a 9,9-bisarylfluorene skeleton.

Examples of the polymerizable compound containing a cardo skeleton include Oncoat EX series (manufactured by NAGASE & CO., LTD.) and OGSOL (manufactured by Osaka Gas Chemicals Co., Ltd.).

The polymerizable compound is also preferably a compound containing an isocyanuric acid skeleton as a central core. Examples of such a polymerizable compound include NK ESTER A-9300 (manufactured by Shin-Nakamura Chemical Co., Ltd.).

The ethylenically unsaturated bond equivalent (meaning a value obtained by dividing the number of ethylenically unsaturated groups in the polymerizable compound by the molecular weight (g/mol) of the polymerizable compound) of the polymerizable compound is preferably 5.0 mmol/g or more. The upper limit is not particularly limited, but is generally 20.0 mmol/g or less.

[Polymerization Initiator]

The curable composition according to the embodiment of the present invention contains a polymerization initiator.

As the polymerization initiator, for example, a known polymerization initiator can be used. Examples of the polymerization initiator include a photopolymerization initiator and a thermal polymerization initiator, and a photopolymerization initiator is preferable.

The content of the polymerization initiator is preferably 0.5 to 20 mass %, more preferably 1.0 to 10 mass %, and still more preferably 1.5 to 8 mass % with respect to the total solid content of the curable composition.

The polymerization initiator may be used singly or in combination of two or more kinds thereof. In a case where two or more kinds of polymerization initiators are used in combination, it is preferable that the total content thereof is within the above-described range.

<Thermal Polymerization Initiator>

Examples of the thermal polymerization initiator include azo compounds such as 2,2′-azobisisobutyronitrile (AIBN), 3-carboxypropionitrile, azobismalenonitrile, and dimethyl-(2,2′)-azobis(2-methylpropionate) [V-601], and organic peroxides such as benzoyl peroxide, lauroyl peroxide, and potassium persulfate.

Specific examples of the thermal polymerization initiator include polymerization initiators described on pages 65 to 148 of “Shigaisen Koka Shisutemu (Ultraviolet Ray-Curing System)” written by Kiyoshi KATO (published by Sogo Gijutsu Center K. K. (1989)).

<Photopolymerization Initiator>

The photopolymerization initiator is not particularly limited, and can be appropriately selected from known photopolymerization initiators. For example, a compound having photosensitivity to light in a range from an ultraviolet range to a visible range is preferable. The photopolymerization initiator is preferably a photoradical polymerization initiator.

Examples of the photopolymerization initiator include a halogenated hydrocarbon derivative (for example, a compound having a triazine skeleton or a compound having an oxadiazole skeleton), an acylphosphine compound, a hexaarylbiimidazole, an oxime compound, an organic peroxide, a thio compound, a ketone compound, an aromatic onium salt, an α-hydroxyketone compound, and an α-aminoketone compound. From the viewpoint of exposure sensitivity, as the photopolymerization initiator, a trihalomethyltriazine compound, a benzyldimethylketal compound, an α-hydroxyketone compound, an α-aminoketone compound, an acylphosphine compound, a phosphine oxide compound, a metallocene compound, an oxime compound, a triarylimidazole dimer, an onium compound, a benzothiazole compound, a benzophenone compound, an acetophenone compound, a cyclopentadiene-benzene-iron complex, a halomethyl oxadiazole compound, or a 3-aryl-substituted coumarin compound is preferable, a compound selected from an oxime compound, an α-hydroxyketone compound, an α-aminoketone compound, or an acylphosphine compound is more preferable, and an oxime compound is still more preferable. Examples of the photopolymerization initiator include compounds described in paragraphs 0065 to 0111 of JP2014-130173A, and JP6301489B, the contents of which are incorporated herein by reference.

Examples of a commercially available product of the α-hydroxyketone compound include Omnirad 184, Omnirad 1173, Omnirad 2959, and Omnirad 127 (all of which are manufactured by IGM Resins B. V.) (in order, Irgacure 184, Irgacure 1173, Irgacure 2959, and Irgacure 127, manufactured by former BASF). Examples of a commercially available product of the α-aminoketone compound include Omnirad 907, Omnirad 369, Omnirad 369E, and Omnirad 379EG (all of which are manufactured by IGM Resins B. V.) (in order, Irgacure 907, Irgacure 369, Irgacure 369E, and Irgacure 379EG, manufactured by former BASF). Examples of a commercially available product of the acylphosphine compound include Omnirad 819 and Omnirad TPO (both of which are manufactured by IGM Resins B. V.) (in order, Irgacure 819 and Irgacure TPO, manufactured by former BASF).

Examples of the oxime compound include the compounds described in JP2001-233842A, the compounds described in JP2000-080068A, the compounds described in JP2006-342166A, the compounds described in J. C. S. Perkin II (1979, pp. 1653-1660), the compounds described in J. C. S. Perkin II (1979, pp. 156-162), the compounds described in Journal of Photopolymer Science and Technology (1995, pp. 202-232), the compounds described in JP2000-066385A, the compounds described in JP2004-534797A, the compounds described in JP2006-342166A, the compounds described in JP2017-019766A, the compounds described in JP6065596B, the compounds described in WO2015/152153A, the compounds described in WO2017/051680A, the compounds described in JP2017-198865A, the compounds described in paragraph Nos. 0025 to 0038 of WO2017/164127A, the compounds described in WO2013/167515A, and the compounds described in WO2019/088055A. Specific examples of the oxime compound include 3-benzoyloxyiminobutane-2-one, 3-acetoxyiminobutane-2-one, 3-propionyloxyiminobutane-2-one, 2-acetoxyiminopentane-3-one, 2-acetoxyimino-1-phenylpropane-1-one, 2-benzoyloxyimino-1-phenylpropane-1-one, 3-(4-toluene sulfonyloxy)iminobutane-2-one, and 2-ethoxycarbonyloxyimino-1-phenylpropane-1-one. Examples of a commercially available product include IRGACURE-OXE01, IRGACURE-OXE02, IRGACURE-OXE03, and IRGACURE-OXE04 (all of which are manufactured by BASF), TR-PBG-304 (manufactured by TRONLY), and ADEKA OPTOMER N-1919 (manufactured by ADEKA Corporation; photopolymerization initiator 2 described in JP2012-014052A). In addition, as the oxime compound, it is also preferable to use a compound having no colorability or a compound having high transparency and being resistant to discoloration. Examples of a commercially available product include ADEKA ARKLS NCI-730, NCI-831, and NCI-930 (all of which are manufactured by ADEKA Corporation).

In the present invention, an oxime compound having a fluorene ring can also be used as the photopolymerization initiator. Specific examples of the oxime compound having a fluorene ring include the compounds described in JP2014-137466A.

In addition, as the photopolymerization initiator, an oxime compound having a skeleton in which at least one benzene ring of a carbazole ring is a naphthalene ring can also be used. Specific examples of such an oxime compound include the compounds described in WO2013/083505A.

In the present invention, an oxime compound having a fluorine atom can also be used as the photopolymerization initiator. Specific examples of the oxime compound having a fluorine atom include the compounds described in JP2010-262028A, the compounds 24, and 36 to 40 described in JP2014-500852A, and the compound (C-3) described in JP2013-164471A.

In the present invention, an oxime compound having a nitro group can be used as the photopolymerization initiator. The oxime compound having a nitro group is also preferably used in the form of a dimer. Specific examples of the oxime compound having a nitro group include the compounds described in paragraph Nos. 0031 to 0047 of JP2013-114249A and paragraph Nos. 0008 to 0012 and 0070 to 0079 of JP2014-137466A, the compounds described in paragraph Nos. 0007 to 0025 of JP4223071B, and ADEKA ARKLS NCI-831 (manufactured by ADEKA Corporation).

In the present invention, an oxime compound having a benzofuran skeleton can also be used as the photopolymerization initiator. Specific examples thereof include OE-01 to OE-75 described in WO2015/036910A.

Specific examples of the oxime compound which are preferably used in the present invention are shown below, but the present invention is not limited thereto.

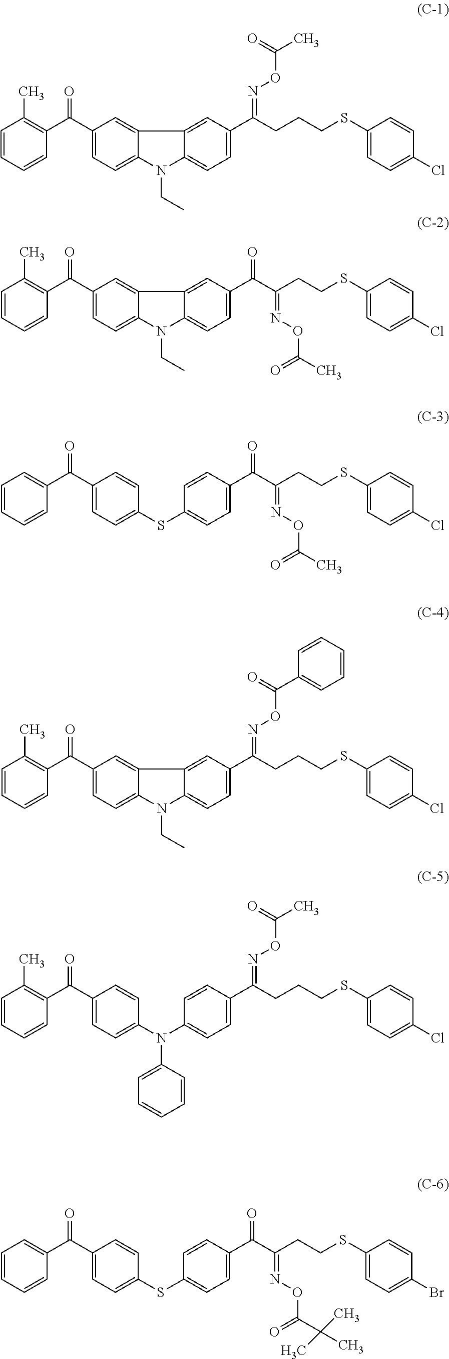 [SMILES: CCn1c2ccc(C(=O)c3ccccc3C)cc2c2cc(/C(CCCSc3ccc(Cl)cc3)=N/OC(C)=O)ccc21 ; CCn1c2ccc(C(=O)/C(CCSc3ccc(Cl)cc3)=N/OC(C)=O)cc2c2cc(C(=O)c3ccccc3C)ccc21 ; CC(=O)O/N=C(\CCSc1ccc(Cl)cc1)C(=O)c1ccc(Sc2ccc(C(=O)c3ccccc3)cc2)cc1 ; CCn1c2ccc(C(=O)c3ccccc3C)cc2c2cc(/C(CCCSc3ccc(Cl)cc3)=N/OC(=O)c3ccccc3)ccc21 ; CC(=O)O/N=C(\CCCSc1ccc(Cl)cc1)c1ccc(N(c2ccccc2)c2ccc(C(=O)c3ccccc3C)cc2)cc1 ; CC(C)(C)C(=O)O/N=C(\CCSc1ccc(Br)cc1)C(=O)c1ccc(Sc2ccc(C(=O)c3ccccc3)cc2)cc1]

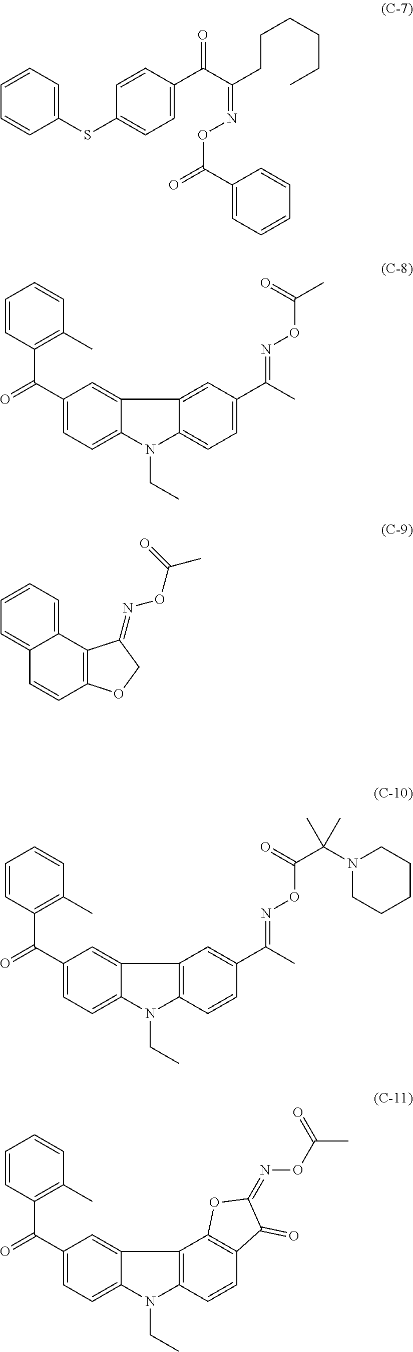 [SMILES: CCCCCC/C(=N/OC(=O)c1ccccc1)C(=O)c1ccc(Sc2ccccc2)cc1 ; CCn1c2ccc(C(=O)c3ccccc3C)cc2c2cc(/C(C)=N/OC(C)=O)ccc21 ; CC(=O)O/N=C1\COc2ccc3ccccc3c21 ; CCn1c2ccc(C(=O)c3ccccc3C)cc2c2cc(/C(C)=N/OC(=O)C(C)(C)N3CCCCC3)ccc21 ; CCn1c2ccc(C(=O)c3ccccc3C)cc2c2c3c(ccc21)C(=O)/C(=N\OC(C)=O)O3]

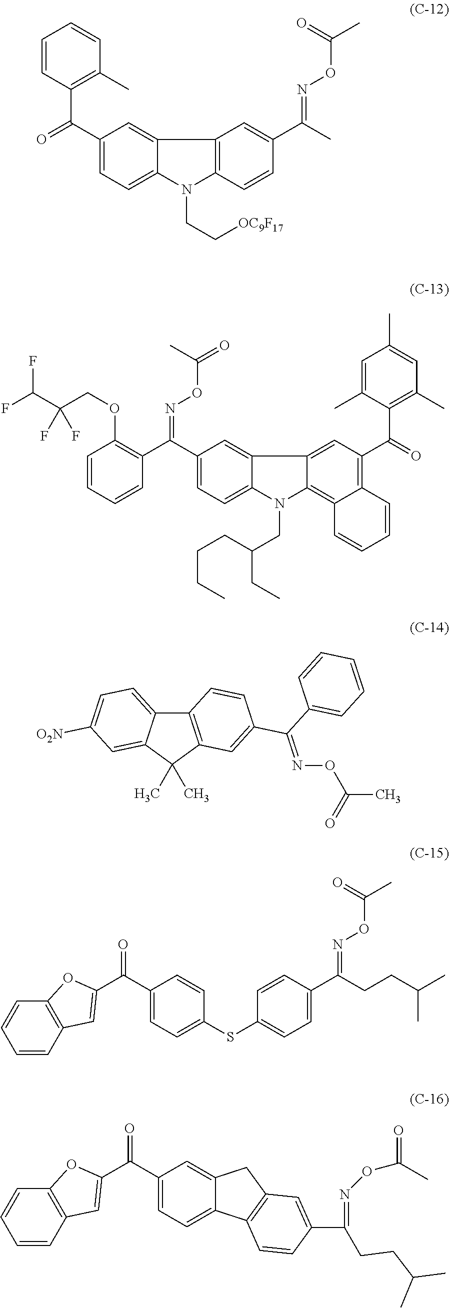

The oxime compound is preferably a compound having a maximal absorption wavelength in a wavelength range of 350 to 500 nm and more preferably a compound having a maximal absorption wavelength in a wavelength range of 360 to 480 nm. In addition, from the viewpoint of sensitivity, the molar absorption coefficient of the oxime compound at a wavelength of 365 nm or 405 nm is preferably high, more preferably 1000 to 300000, still more preferably 2000 to 300000, and particularly preferably 5000 to 200000. The molar absorption coefficient of a compound can be measured using a well-known method. For example, the molar absorption coefficient is preferably measured by a spectrophotometer (Cary-5 spectrophotometer, manufactured by Varian) using an ethyl acetate solvent at a concentration of 0.01 g/L.

As the photopolymerization initiator, a bifunctional or tri- or higher functional photoradical polymerization initiator may be used. By using such a photoradical polymerization initiator, two or more radicals are generated from one molecule of the photoradical polymerization initiator, and as a result, good sensitivity is obtained. In addition, in a case of using a compound having an asymmetric structure, crystallinity is reduced so that solubility in a solvent or the like is improved, precipitation is to be difficult over time, and temporal stability of the curable composition can be improved. Specific examples of the bifunctional or tri- or higher functional photoradical polymerization initiator include dimers of the oxime compounds described in JP2010-527339A, JP2011-524436A, WO2015/004565A, paragraph Nos. 0407 to 0412 of JP2016-532675A, and paragraph Nos. 0039 to 0055 of WO2017/033680A; the compound (E) and compound (G) described in JP2013-522445A; Cmpd 1 to 7 described in WO2016/034963A; the oxime ester photoinitiators described in paragraph No. 0007 of JP2017-523465A; the photoinitiators described in paragraph Nos. 0020 to 0033 of JP2017-167399A; and the photopolymerization initiator (A) described in paragraph Nos. 0017 to 0026 of JP2017-151342A.

It is also preferable that the photopolymerization initiator includes an oxime compound and an α-aminoketone compound. By using the oxime compound and the α-aminoketone compound in combination, developability is improved, and a pattern having excellent rectangularity is likely to be formed. In a case where an oxime compound and an α-aminoketone compound are used in combination, the content of the α-aminoketone compound is preferably 50 to 600 parts by mass and more preferably 150 to 400 parts by mass with respect to 100 parts by mass of the oxime compound.

The content of the photopolymerization initiator in the total solid content of the curable composition is preferably 0.1 to 40 mass %, more preferably 0.5 to 30 mass %, and still more preferably 1 to 20 mass %. The curable composition may include only one kind of the photopolymerization initiator or two or more kinds thereof. In a case of including two or more kinds thereof, the total amount thereof is preferably within the above-described range.

[Polymerization Inhibitor]

The curable composition may contain a polymerization inhibitor.

As the polymerization inhibitor, for example, a known polymerization inhibitor can be used. Examples of the polymerization inhibitor include phenol-based polymerization inhibitors (for example, p-methoxyphenol, 2,5-di-tert-butyl-4-methylphenol, 2,6-di-tert-butyl-4-methylphenol, 4,4′-thiobis (3-methyl-6-t-butylphenol), 2,2′-methylenebis(4-methyl-6-t-butylphenol), 4-methoxynaphthol, and the like); hydroquinone-based polymerization inhibitor (for example, hydroquinone, 2,6-di-tert-butylhyrodroquinone, and the like); quinone-based polymerization inhibitors (for example, benzoquinone and the like); free radical polymerization inhibitors (for example, 2,2,6,6-tetramethylpiperidine 1-oxyl free radical, 4-hydroxy-2,2,6,6-tetramethylpiperidine 1-oxyl free radical, and the like); nitrobenzene-based polymerization inhibitors (for example, nitrobenzene, 4-nitrotoluene, and the like); and phenothiazine-based polymerization inhibitors (for example, phenothiazine, 2-methoxyphenothiazine, and the like).

Among these, from the viewpoint that the curable composition has more excellent effects, a phenol-based polymerization inhibitor or a free radical-based polymerization inhibitor is preferable.

The content of the polymerization inhibitor is preferably 0.0001 to 0.5 mass %, more preferably 0.001 to 0.2 mass %, and still more preferably 0.008 to 0.05 mass % with respect to the total solid content of the curable composition. The polymerization inhibitor may be used singly or in combination of two or more kinds thereof. In a case where two or more kinds of polymerization inhibitors are used in combination, it is preferable that the total content thereof is within the above-described range.

In addition, a ratio (content of polymerization inhibitor/content of polymerizable compound (mass ratio)) of the content of the polymerization inhibitor to the content of the polymerizable compound in the curable composition is preferably 0.00005 to 0.02 and more preferably 0.0001 to 0.005.

[Solvent]

The curable composition according to the embodiment of the present invention preferably contains a solvent. As the solvent, an organic solvent is preferable. Examples of the organic solvent include an ester-based solvent, a ketone-based solvent, an alcohol-based solvent, an amide-based solvent, an ether-based solvent, and a hydrocarbon-based solvent. The details of the organic solvent can be found in paragraph No. 0223 of WO2015/166779A, the content of which is incorporated herein by reference. In addition, an ester solvent in which a cyclic alkyl group is substituted or a ketone solvent in which a cyclic alkyl group is substituted can also be preferably used. Specific examples of the organic solvent include polyethylene glycol monomethyl ether, dichloromethane, methyl 3-ethoxypropionate, ethyl 3-ethoxypropionate, ethyl cellosolve acetate, ethyl lactate, diethylene glycol dimethyl ether, butyl acetate, methyl 3-methoxypropionate, 2-heptanone, cyclohexanone, cyclohexyl acetate, cyclopentanone, ethyl carbitol acetate, butyl carbitol acetate, propylene glycol monomethyl ether, and propylene glycol monomethyl ether acetate. In this case, it may be preferable that the content of aromatic hydrocarbons (such as benzene, toluene, xylene, and ethylbenzene) as the organic solvent is low (for example, 50 parts per million (ppm) by mass or less, 10 ppm by mass or less, or 1 ppm by mass or less with respect to the total amount of the organic solvent) in consideration of environmental aspects and the like.

In the present invention, an organic solvent having a low metal content is preferably used. For example, the metal content in the organic solvent is preferably 10 mass parts per billion (ppb) or less. Optionally, an organic solvent having a metal content at a mass parts per trillion (ppt) level may be used. For example, such an organic solvent is available from Toyo Gosei Co., Ltd. (The Chemical Daily, Nov. 13, 2015).

Examples of a method for removing impurities such as a metal from the organic solvent include distillation (such as molecular distillation and thin-film distillation) and filtration using a filter. The filter pore size of the filter used for the filtration is preferably 10 μm or less, more preferably 5 μm or less, and still more preferably 3 μm or less. As a material of the filter, polytetrafluoroethylene, polyethylene, or nylon is preferable.

The organic solvent may include an isomer (a compound having the same number of atoms and a different structure). In addition, only one kind of isomers may be included, or a plurality of isomers may be included.

The organic solvent preferably has the content of peroxides of 0.8 mmol/L or less, and more preferably, the organic solvent does not substantially include peroxides.

The content of the solvent is preferably 10 to 97 mass % with respect to the total amount of the curable composition. The lower limit is preferably 30 mass % or more, more preferably 40 mass % or more, still more preferably 50 mass % or more, even more preferably 60 mass % or more, and particularly preferably 70 mass % or more. The upper limit is preferably 96 mass % or less and more preferably 95 mass % or less. The curable composition may include only one kind of the solvent or two or more kinds thereof. In a case of including two or more kinds thereof, the total amount thereof is preferably within the above-described range.

[Other Optional Components]

The composition may further contain any component other than the above-described components. Examples thereof include a particulate component other than those described above, an ultraviolet absorber, a silane coupling agent, a surfactant, a sensitizer, a co-sensitizer, a crosslinking agent, a curing accelerator, a thermosetting accelerator, a plasticizer, a diluent, and a sensitization agent, and further, a known additive such as an adhesion promoter to the surface of the substrate and other auxiliary agents (for example, conductive particles, a filler, a defoamer, a flame retardant, a leveling agent, a peeling accelerator, an antioxidant, a fragrance, a surface tension adjuster, a chain transfer agent, and the like) may be added as necessary.

The details of the components can be found in, for example, paragraphs 0183 to 0228 of JP2012-003225A (corresponding to paragraphs 0237 to 0309 of US2013/0034812A), paragraphs 0101 and 0102, 0103 and 0104, and 0107 to 0109 of JP2008-250074A, paragraphs 0159 to 0184 of JP2013-195480A, and the like, the contents of which are incorporated herein by reference.

[Method for Producing Curable Composition]

As the curable composition, it is preferable to first produce a silica particle dispersion liquid in which silica particles are dispersed and a coloring material dispersion liquid in which a coloring material is dispersed, and further mix these with other components to obtain a composition.

The coloring material dispersion liquid is preferably prepared by mixing a coloring material, a resin (preferably a dispersant), and a solvent. In addition, it is also preferable to contain a polymerization inhibitor in the coloring material dispersion liquid.

The above-described coloring material dispersion liquid can be prepared by mixing each of the above-described components by a known mixing method (for example, a mixing method using a stirrer, a homogenizer, a high-pressure emulsifier, a wet crusher, a wet disperser, or the like).

In the preparation of the curable composition, each component may be blended together, or each component may be dissolved or dispersed in a solvent and then sequentially blended. In addition, adding sequence and working conditions for blending are not particularly limited.

For the purpose of removing foreign matters, reducing defects, and the like, the curable composition is preferably filtered through a filter. As the filter, for example, any filters which have been used in the related art for filtration use and the like may be used without particular limitation. Examples thereof include filters formed of a fluororesin such as polytetrafluoroethylene (PTFE), a polyamide-based resin such as nylon, or a polyolefin-based resin (including a high-density polypropylene and ultrahigh molecular weight polypropylene) such as polyethylene and polypropylene (PP). Among these materials, polypropylene (including a high-density polypropylene) or nylon is preferable.

The pore size of the filter is preferably 0.1 to 7.0 μm, more preferably 0.2 to 2.5 μm, still more preferably 0.2 to 1.5 μm, and particularly preferably 0.3 to 0.7 μm. Within this range, fine foreign matters such as impurities and aggregates included in the pigment can be reliably removed while suppressing filtration clogging of the pigment.

In a case of using a filter, different filters may be combined. In this case, the filtering with a first filter may be performed once or may be performed twice or more times. In a case where filtering is performed twice or more by combining different filters, it is preferable that the pore size of the second and subsequent filters are the same or larger than the pore size of the first filtering. In addition, first filters having different pore sizes within the above-described range may be combined. With regard to the pore size of the filter herein, reference can be made to nominal values of filter manufacturers. A commercially available filter can be selected from, for example, various filters provided by Nihon Pall Corporation, Toyo Roshi Kaisha., Ltd., Nihon Entegris K. K. (formerly Nippon Microlith Co., Ltd.), and Kitz Micro Filter Corporation.

As the second filter, a filter formed of the same material as that of the first filter described above, or the like can be used. The pore size of the second filter is preferably 0.2 to 10.0 μm, more preferably 0.2 to 7.0 μm, and still more preferably 0.3 to 6.0 μm.

It is preferable that the curable composition does not include impurities such as metals, metal salts containing halogens, acids, and alkalis. The content of impurities included in these materials is preferably 1 ppm by mass or less, more preferably 1 ppb by mass or less, still more preferably 100 ppt by mass or less, particularly preferably 10 ppt by mass or less, and it is most preferable that the impurities are not substantially included (below the detection limit of a measuring device).

The above-described impurities can be measured by an inductively coupled plasma mass spectrometer (Agilent 7500cs type, manufactured by Yokogawa Analytical Systems, Inc.).

[Cured Film]

The cured film according to an embodiment of the present invention is a film formed of the above-described curable composition according to the embodiment of the present invention. Specifically, the cured film according to the embodiment of the present invention is formed by curing a composition layer formed of the curable composition according to the embodiment of the present invention to obtain a cured film (including a patterned cured film)

A method for manufacturing the cured film is not particularly limited, but preferably includes the following steps.
Composition layer forming step
Exposing step
Developing step

Hereinafter, the respective steps will be described.

[Composition layer forming step]

In the composition layer forming step, the curable composition is applied to a support or the like to form a layer (composition layer) of the curable composition prior to exposure. As the support, for example, a substrate for a solid-state imaging element, which is provided with an imaging element (light receiving element) such as a charge coupled device (CCD) and a complementary metal-oxide semiconductor (CMOS) on a substrate (for example, a silicon substrate), can be used. In addition, optionally, an undercoat layer (base layer) may be provided on the support to improve adhesiveness with a layer above the support, to prevent diffusion of materials, to planarize the surface of the substrate, and the like.

As a method for applying the composition to the support, various coating methods such as a slit coating method, an ink jet method, a spin coating method, a cast coating method, a roll coating method, and a screen printing method can be applied. The film thickness of the composition layer is preferably 0.1 to 10 μm, more preferably 0.2 to 5 μm, and still more preferably 0.2 to 3 μm. The composition layer applied on the support can be dried (pre-baked), for example, in a hot plate, an oven, or the like at a temperature of 50° C. to 140° C. in 10 to 300 seconds.

Examples of the undercoat layer include a film including a resin such as a (meth)acrylic resin. Specific examples of a method for forming the undercoat layer include a method in which a composition containing (meth)acrylate, a crosslinking agent, a surfactant, a solvent, and the like is applied to a support by a coating method such as a spin coating method to obtain a coating film, and then the coating film is dried.

The undercoat layer preferably has a contact angle of 20 to 70 degrees measured with diiodomethane, and preferably has a contact angle of 30 to 80 degrees measured with water. In a case where the contact angle is the lower limit or more of the above-described range, wettability of the color filter is good, and in a case of being the upper limit or less, surface energy of the film is controlled so that application properties of the undercoat layer are good. Examples of a method for adjusting the contact angle to the above-described range include addition of a surfactant and a method of controlling drying speed, spin coating, rotation speed, and the like. The contact angle of the undercoat layer is measured using a contact angle meter based on a liquid droplet method.

As the undercoat layer, a commercially available product may be used, and examples thereof include CT-4000L manufactured by Fujifilm Electronic Materials Co., Ltd.

[Exposing Step]

In the exposing step, the composition layer formed in the composition layer forming step is exposed by irradiating the composition layer with actinic ray or radiation to cure the light-irradiated composition layer.

As a method of light irradiation, it is preferable to irradiate light through a photomask having a patterned opening portion.

The exposure is preferably performed by irradiation with radiation. The radiation which can be used for the exposure is preferably ultraviolet rays such as g-ray, h-ray, and i-ray, and a light source is preferably a high-pressure mercury lamp. The irradiation intensity is preferably 5 to 1500 mJ/cm² and more preferably 10 to 1000 mJ/cm².

In a case where the composition contains a thermal polymerization initiator, the composition layer may be heated in the above-described exposing step. The heating temperature is not particularly limited, but is preferably 80° C. to 250° C. The heating time is preferably 30 to 300 seconds.

In the exposing step, in a case where the composition layer is heated, a post-heating step described later may be performed in combination. In other words, in the exposing step, in a case where the composition layer is heated, the method for manufacturing the cured film does not have to include a post-heating step.

[Developing Step]

The developing step is a step of developing the above-described composition layer after exposure to form a cured film. By this step, the composition layer of a light-unirradiated portion in the exposing step is eluted, only the photocured portion remains, and a patterned cured film can be obtained.

The type of a developer used in the developing step is not particularly limited, but an alkali developer which does not damage the underlying imaging element, circuit, and the like is desirable.

The developing temperature is, for example, 20° C. to 30° C.

The developing time is, for example, 20 to 90 seconds. In recent years, in order to remove the residue better, the development may be performed for 120 to 180 seconds. Further, in order to further improve residue removing properties, a step of removing the developer by shaking off per 60 seconds and supplying a fresh developer may be repeated multiple times.

As the alkali developer, an alkaline solution prepared by dissolving an alkaline compound in water so that the concentration is 0.001 to 10 mass % (preferably, 0.01 to 5 mass %) is preferable.

Examples of the alkaline compound include sodium hydroxide, potassium hydroxide, sodium carbonate, sodium silicate, sodium metasilicate, ammonia water, ethylamine, diethylamine, dimethylethanolamine, tetramethylammonium hydroxide, tetraethylammonium hydroxide, tetrapropylammonium hydroxide, tetrabutylammonium hydroxide, benzyltrimethylammonium hydroxide, choline, pyrrole, piperidine, and 1,8-diazabicyclo[5.4.0]-7-undecene (among these, an organic alkali is preferable).

In a case of using an alkali developer, a washing treatment with water is generally performed after the development.

[Post-Baking]

After the exposing step, it is preferable to perform a heating treatment (post-baking). Post-baking is a heating treatment which is performed after the development to complete the cure. The heating temperature is preferably 240° C. or lower and more preferably 220° C. or lower. There is no particular lower limit, but considering efficient and effective treatment, is preferably 50° C. or higher and more preferably 100° C. or higher.

The post-baking can be performed continuously or batchwise by using a heating unit such as a hot plate, a convection oven (hot-air circulation dryer), and a high-frequency heater.

The above-described post-baking is preferably performed in an atmosphere with a low oxygen concentration. The oxygen concentration is preferably 19 volume % or less, more preferably 15 volume % or less, still more preferably 10 volume % or less, particularly preferably 7 volume % or less, and most preferably 3 volume % or less. There is no particular lower limit, but 10 ppm by volume or more is practical.

In addition, the curing may be completed by ultraviolet (UV) irradiation instead of the post-baking by heating described above.

In this case, the above-described composition preferably further contains a UV curing agent. The UV curing agent is preferably a UV curing agent which can be cured at a wavelength shorter than 365 nm, which is an exposure wavelength of the polymerization initiator added for a lithography step by ordinary i-ray exposure. Examples of the UV curing agent include CIBA IRGACURE 2959 (trade name). In a case where the UV irradiation is performed, it is preferable that the composition layer is a material which cures at a wavelength of 340 nm or less. There is no particular lower limit value of the wavelength, but 220 nm or more is common. In addition, the exposure amount of the UV irradiation is preferably 100 to 5000 mJ, more preferably 300 to 4000 mJ, and still more preferably 800 to 3500 mJ. In order to perform low temperature curing more effectively, it is preferable that the UV curing step is performed after the exposing step. It is preferable to use an ozoneless mercury lamp as an exposure light source.

[Physical Properties, Shape, Use, and the Like of Cured Film]

The film thickness of the cured film is, for example, preferably 0.1 to 4.0 μm and more preferably 1.0 to 2.5 μm. In addition, the cured film may be a thinner film or a thicker film than the range, depending on the intended use.

The reflectivity of the cured film is preferably 10% or less, more preferably 5% or less, and still more preferably 3% or less. The lower limit is 0% or more.

The reflectivity referred to here is determined from a reflectivity spectrum obtained by injecting light having a wavelength of 400 to 1100 nm at an incidence angle of 5° using a spectroscope V7200 (trade name) VAR unit manufactured by JASCO Corporation. Specifically, the reflectivity of light having a wavelength showing the maximum reflectivity in the wavelength range of 400 to 1100 nm is defined as the reflectivity of the cured film.

In a case where the cured film has a patterned shape, a size of one side of the pattern of the cured film is preferably 3 μm or less, more preferably 2 μm or less, and still more preferably 1.4 μm or less. The lower limit value of the size of one side of the pattern of the cured film is not particularly limited, but is preferably 0.5 μm.

The patterned shape of the cured film is not particularly limited, but in a case where the cured film is a color filter used for a solid-state imaging element or the like, the patterned shape of the cured film is usually rectangular.

In addition, the above-described cured film is suitable for an optical filter (for example, a color filter), a light shielding member and a light shielding film of a module, and an antireflection member and an antireflection film, which are used in a product such as portable devices such as a personal computer, a tablet, a mobile phone, a smartphone, and a digital camera; office automation (OA) equipments such as a printer multifunction device and a scanner; industrial equipments such as a surveillance camera, a bar code reader, an automated teller machine (ATM), a high-speed camera, and an equipment with personal authentication functions using face image authentication or biometric authentication; in-vehicle camera equipments; medical camera equipments such as an endoscope, a capsule endoscope, and a catheter; and space equipments such as a biosensor, a military reconnaissance camera, a stereoscopic map camera, a meteorological and oceanographic observation camera, a land resource exploration camera, and an exploration camera for space astronomical and deep space targets.

The above-described cured film can also be used for applications such as micro light emitting diode (LED) and micro organic light emitting diode (OLED). The above-described cured film is suitable for a member which imparts a light shielding function or an antireflection function, in addition to an optical filter and an optical film (for example, a color filter) used in the micro LED and micro OLED.

Examples of the micro LED and micro OLED include examples described in JP2015-500562B and JP2014-533890B.

The above-described cured film is also suitable as an optical filter and an optical film (for example, a color filter) used in a quantum dot sensor and a quantum dot solid-state imaging element. In addition, the above-described cured film is also suitable as a member for imparting a light shielding function and an antireflection function. Examples of the quantum dot sensor and the quantum dot solid-state imaging element include examples described in US2012/37789A and WO2008/131313A.

[Light Shielding Film, Color Filter, Optical Element, Solid-State Imaging Element, and Solid-State Imaging Device]

In a case where the cured film according to the embodiment of the present invention is formed of the curable composition according to the embodiment of the present invention using the black colorant as the coloring material, it is also preferable to use the cured film according to the embodiment of the present invention as a so-called light shielding film. It is also preferable to such a light shielding film for a solid-state imaging element.

The light shielding film is one of the preferred uses in the cured film according to the embodiment of the present invention, and the light shielding film of the present invention can be similarly produced by a method described as the method for manufacturing the cured film.

In a case where the cured film according to the embodiment of the present invention is formed of the curable composition according to the embodiment of the present invention using the chromatic colorant as the coloring material, it is also preferable to use the cured film according to the embodiment of the present invention as a so-called color filter. It is also preferable to such a color filter for a solid-state imaging element.

The color filter is one of the preferred uses in the cured film according to the embodiment of the present invention, and the color filter of the present invention can be similarly produced by a method described as the method for manufacturing the cured film.

The present invention also includes an invention of an optical element. The optical element of the present invention is an optical element having the above-described cured film. Examples of the optical element include an optical element used in an optical instrument such as a camera, a binocle, a microscope, and a semiconductor exposure device.

Among these, as the above-described optical element, for example, a solid-state imaging element mounted on a camera or the like is preferable.

In addition, the solid-state imaging element according to an embodiment of the present invention is a solid-state imaging element containing the above-described cured film according to the embodiment of the present invention.

Examples of an aspect in which the solid-state imaging element according to the embodiment of the present invention contains the cured film include an aspect in which, on a substrate, a solid-state imaging element (CCD image sensor, CMOS image sensor, or the like) has light receiving elements which consist of a plurality of photodiodes and polysilicon or the like and constitute a light receiving area of the solid-state imaging element, and the cured film is provided on forming surface of the light receiving elements in the support (for example, a portion other than a light receiving section and/or a pixel for color adjustment, or the like) or on the opposite side of the forming surface.

In addition, in a case where the cured film is used as a light attenuation film, for example, in a case where the light attenuation film is disposed so that a part of light passes through the light attenuation film and then is incident on the light receiving elements, a dynamic range of the solid-state imaging element can be improved.

The solid-state imaging device includes the above-described solid-state imaging element.

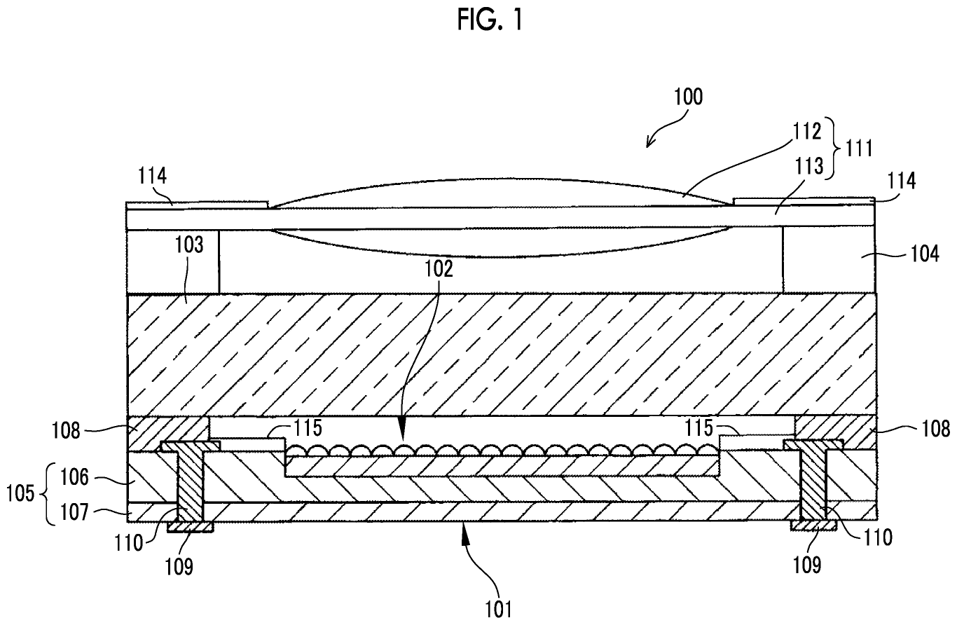

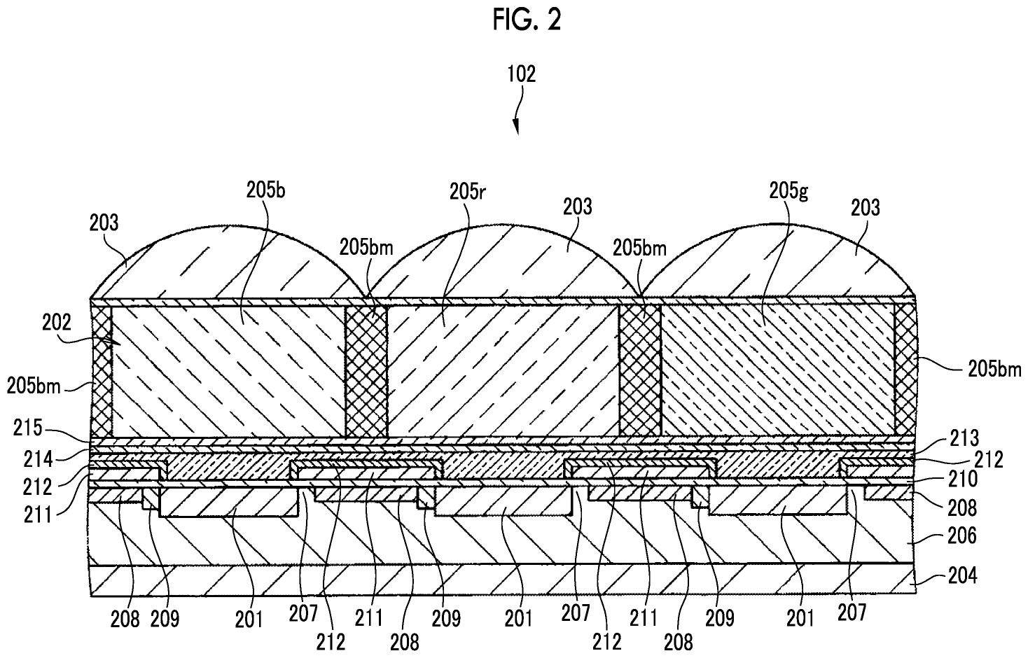

Configuration examples of the solid-state imaging device and the solid-state imaging element will be described with reference to FIGS. 1 and 2. In FIGS. 1 and 2, in order to clarify each part, the ratio of the mutual thickness and/or the width is ignored and a part is exaggerated.

FIG. 1 is a schematic cross-sectional view showing a configuration example of a solid-state imaging device containing the solid-state imaging element according to the embodiment of the present invention.

As shown in FIG. 1, a solid-state imaging device 100 includes a rectangular solid-state imaging element 101, a transparent cover glass 103 which is held above the solid-state imaging element 101 and seals the solid-state imaging element 101. Further, a lens layer 111 is provided on the cover glass 103 so as to be overlapped with a spacer 104. The lens layer 111 is composed of a support 113 and a lens material 112. The lens layer 111 may be composed of a support 113 and a lens material 112, in which both are integrally molded. In a case where stray light is incident on a peripheral region of the lens layer 111, due to diffusion of light, an effect of light collection on the lens material 112 is weakened, and light reaching an imaging unit 102 is reduced. In addition, noise is also generated due to the stray light. Therefore, the peripheral region of the lens layer 111 is provided with a light shielding film 114 to shield light. The cured film according to the embodiment of the present invention can also be used as the light shielding film 114.

The solid-state imaging element 101 photoelectrically converts an optical image imaged by the imaging unit 102 which is a light receiving surface thereof, and outputs the optical image as an image signal. The solid-state imaging element 101 includes a laminated substrate 105 in which two substrates are laminated. The laminated substrate 105 is composed of a rectangular chip board 106 and a circuit board 107 of the same size, and the circuit board 107 is laminated on a back surface of the chip board 106.

As a material of the substrate used as the chip board 106, for example, a known material can be used.

The imaging unit 102 is provided at the center of a surface of the chip board 106. In addition, a peripheral region of the imaging unit 102 is provided with a light shielding film 115. By shielding stray light incident on the peripheral region by the light shielding film 115, it is possible to prevent the generation of dark current (noise) from the circuit in the peripheral region. The cured film according to the embodiment of the present invention can also be used as the light shielding film 115.

A plurality of electrode pads 108 are provided on a surface edge of the chip board 106. The electrode pads 108 are electrically connected to the imaging unit 102 through a signal line (may be a bonding wire) provided on the surface of the chip board 106, which is not shown.

On a back surface of the circuit board 107, external connection terminals 109 are provided at positions substantially below each electrode pad 108. Each external connection terminal 109 is connected to the electrode pad 108 through a through-electrode 110 which vertically penetrates the laminated substrate 105. In addition, through wiring not shown, each external connection terminal 109 is connected to a control circuit which controls drive of the solid-state imaging element 101, an image processing circuit which performs image processing on the imaging signal output from the solid-state imaging element 101, and the like.

FIG. 2 shows a schematic cross-sectional view showing the imaging unit 102. As shown in FIG. 2, the imaging unit 102 is composed of each unit provided on a substrate 204, such as a light receiving element 201, a color filter 202, and a microlens 203. The color filter 202 has a blue pixel 205b, a red pixel 205r, a green pixel 205g, and a black matrix 205bm. The cured film according to the embodiment of the present invention may be used as the blue pixel 205b, the red pixel 205r, the green pixel 205g, and the black matrix 205bm.

As a material for the substrate 204, for example, the same material as the above-described chip board 106 can be used. A p-well layer 206 is formed on a surface layer of the substrate 204. In the p-well layer 206, light receiving elements 201, which are composed of n-type layers, and generate and accumulate signal charges by photoelectric conversion, are arranged in a square grid pattern.

A vertical electric charge transfer path 208 composed of an n-type layer is formed on one side of the light receiving element 201 through a readout gate portion 207 on a surface layer of the p-well layer 206. In addition, a vertical electric charge transfer path 208 belonging to an adjacent pixel is formed on the other side of the light receiving element 201 through an element separation region 209 composed of a p-type layer. The readout gate portion 207 is a channel region for reading the signal charge accumulated in the light receiving elements 201 to the vertical electric charge transfer path 208.

A gate insulating film 210 composed of an oxide-nitride-oxide (ONO) film is formed on a surface of the substrate 204. A vertical electric charge transfer electrode 211 composed of polysilicon or amorphous silicon is formed on the gate insulating film 210 so as to cover substantially directly above the vertical electric charge transfer path 208, the readout gate portion 207, and the element separation region 209. The vertical electric charge transfer electrode 211 functions as a driving electrode which drives the vertical electric charge transfer path 208 to perform charge transfer, and as a reading electrode which drives the readout gate portion 207 to read out the signal charge. The signal charge is sequentially transferred from the vertical electric charge transfer path 208 to a horizontal transfer path and an output unit (floating diffusion amplifier), which are not shown, and then outputs as a voltage signal.

A light shielding film 212 is formed on the vertical electric charge transfer electrode 211 so as to cover the surface thereof. The light shielding film 212 has an opening portion at a position directly above the light receiving elements 201, and shields the other regions from light. The cured film according to the embodiment of the present invention may be used the light shielding film 212.

On the light shielding film 212, an insulating film 213 composed of borophosphosilicate glass (BPSG), an insulating film (passivation film) 214 composed of P—SiN, and a transparent interlayer composed of a planarizing film 215 consisting of a transparent resin or the like are provided. The color filter 202 is formed on the interlayer.

[Image Display Device]

The image display device according to an embodiment of the present invention includes the cured film according to the embodiment of the present invention.

Examples of an aspect in which the image display device has the cured film include an aspect in which a color filter formed by the cured film according to the embodiment of the present invention is used in the image display device. The color filter may contain a black matrix.

Next, a black matrix and a color filter containing the black matrix will be described, and further, as a specific example of the image display device, a liquid crystal display device containing such a color filter will be described.

<Black Matrix>

It is also preferable that the cured film according to the embodiment of the present invention is contained in the black matrix. The black matrix may be contained in an image display device such as a color filter, a solid-state imaging element, and a liquid crystal display device.

Examples of the black matrix include those described above; a black edge provided on a peripheral edge of an image display device such as a liquid crystal display device; a lattice-formed and/or striped black part between red, blue, and green pixels; and a dot-shaped and/or linear black pattern for shielding thin film transistor (TFT). With regard to the definition of the black matrix, for example, the description of “Dictionary of Liquid Crystal Display Manufacturing Apparatus Terms” by Taihei Kanno, 2nd edition, published by Nikkan Kogyo Shimbun, 1996, p. 64. can be referred to.

In order to improve display contrast and to prevent deterioration of image quality due to light current leakage in a case of an active matrix drive-type liquid crystal display device using a thin film transistor (TFT), the black matrix preferably has high light shielding properties (optical density (OD) of 3 or more).

As a method for manufacturing the black matrix, for example, the black matrix can be produced by the same method as the above-described method for manufacturing the cured film. Specifically, the patterned cured film (black matrix) can be manufactured by applying a composition to a substrate to form a composition layer, and performing exposure and development. The film thickness of the cured film used as the black matrix is preferably 0.1 to 4.0 μm.

A material of the substrate preferably has a transmittance of 80% or more with respect to visible light (wavelength of 400 to 800 nm). Examples of such a material include glass such as soda lime glass, non-alkali glass, quartz glass, and borosilicate glass; and plastics such as a polyester-based resin and a polyolefin-based resin, and from the viewpoint of chemical resistance and heat resistance, non-alkali glass, quartz glass, or the like is preferable.

<Color Filter>

It is also preferable that the cured film according to the embodiment of the present invention is contained in the color filter.

Examples of an aspect in which the color filter contains the cured film include a color filter including a substrate and red, green, and blue colored pixels (cured films) formed on the substrate. In addition, the color filter may be a color filter including a substrate, the above-described black matrix, and red, green, and blue colored pixels formed in an opening portion of the above-described black matrix formed on the substrate.

The color filter containing the black matrix can be manufactured, for example, by the following method.

First, a coating film (composition layer) of a curable composition containing a coloring material corresponding to each colored pixel of the color filter is formed in an opening portion of a patterned black matrix formed on a substrate.

Next, the composition layer is exposed through a photomask having a pattern corresponding to the opening portion of the black matrix. Next, a non-exposed portion is removed by a development treatment, and the product is baked to form colored pixels in the opening portion of the black matrix. By performing the series of operations using, for example, a curable composition containing red, green, and blue pigments, a color filter having red, green, and blue pixels can be manufactured.

[Liquid Crystal Display Device]

It is also preferable that the cured film according to the embodiment of the present invention is contained in the liquid crystal display device. Examples of an aspect in which the liquid crystal display device contains the cured film include an aspect containing the color filter described above.

Examples of the liquid crystal display device according to the present embodiment include an aspect of including a pair of substrates arranged to face each other and a liquid crystal compound sealed between the substrates. The above-described substrate is as described above, for example, as a substrate for the black matrix.

Examples of a specific aspect of the above-described liquid crystal display device include a laminate containing, from the user side, polarizing plate/substrate/color filter/transparent electrode layer/alignment film/liquid crystal layer/transparent electrode layer/thin film transistor (TFT) element/substrate/polarizing plate/backlight unit in this order.

Examples of the liquid crystal display device include liquid crystal display devices described in “Electronic Display Device (Akio Sasaki, Kogyo Chosakai Publishing Co., Ltd., published in 1990)”, “Display Device (Sumiaki Ibuki, Sangyo Tosyo Co., Ltd., published in 1989)”, and the like. In addition, examples thereof include liquid crystal display devices described in “Liquid Crystal Display Technology for Next Generation (edited by Tatsuo Uchida, Kogyo Chosakai Publishing Co., Ltd., published in 1994)”.

[Infrared Sensor]

It is also preferable that the cured film according to the embodiment of the present invention is contained in an infrared sensor.

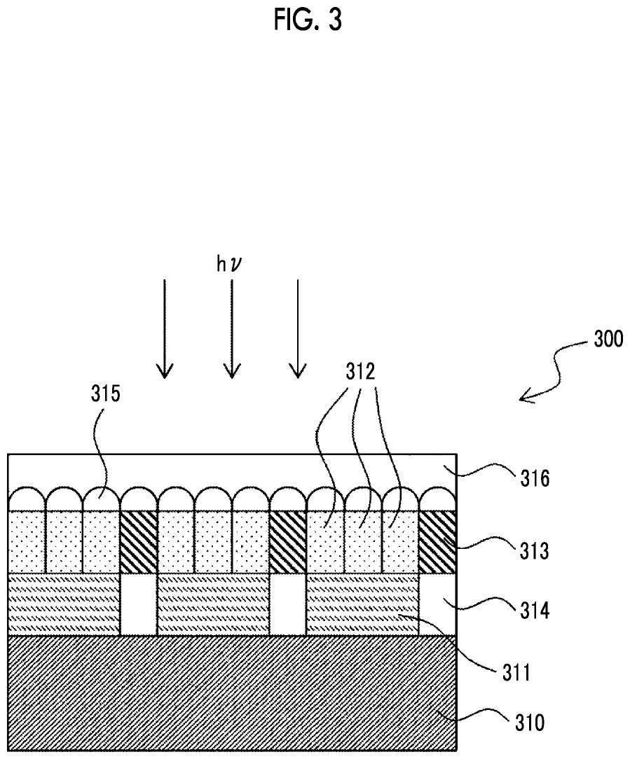

The infrared sensor according to the above-described embodiment will be described with reference to FIG. 3. FIG. 3 is a schematic cross-sectional view showing a configuration example of an infrared sensor including the cured film according to the embodiment of the present invention. An infrared sensor 300 shown in FIG. 3 includes a solid-state imaging element 310.

An imaging region provided on the solid-state imaging element 310 is configured by combining an infrared absorbing filter 311 and a color filter 312 according to the embodiment of the present invention.

The infrared absorbing filter 311 is a film which transmits light in the visible light region (for example, light having a wavelength of 400 to 700 nm) and cuts light in the infrared region (for example, light having a wavelength of 800 to 1300 mu, preferably light having a wavelength of 900 to 1200 nm and more preferably light having a wavelength of 900 to 1000 nm), and a cured film containing, as a coloring material, an infrared absorber (aspect of the infrared absorber is as described above) can be used.

The color filter 312 is a color filter having pixels which transmit and absorb light of a specific wavelength in the visible light region, and for example, a color filter or the like in which red (R), green (G), and blue (B) pixels are formed is used, and the aspect thereof is as described above.

A resin film 314 (for example, a transparent resin film or the like) capable of transmitting light having a wavelength transmitted through the infrared transmitting filter 313 is disposed between the infrared transmitting filter 313 and the solid-state imaging element 310.

The infrared transmitting filter 313 is a filter which has visible light shielding properties and transmits infrared rays of a specific wavelength, and the cured film according to the embodiment of the present invention, which contains a colorant (for example, a perylene compound and/or a bisbenzofuranone compound, and the like) absorbing light in the visible light region and an infrared absorber (for example, a pyrrolopyrrole compound, a phthalocyanine compound, a naphthalocyanine compound, a polymethine compound, and the like), can be used. For example, the infrared transmitting filter 313 preferably shields light having a wavelength of 400 to 830 nm and transmits light having a wavelength of 900 to 1300 nm.

A microlens 315 is disposed on an incidence ray hv side of the color filter 312 and the infrared transmitting filter 313, A planarizing film 316 is formed so as to cover the microlenses 315.

In the aspect shown in FIG. 3, the resin film 314 is disposed, but the infrared transmitting filter 313 may be formed instead of the resin filter 314. That is, the infrared transmitting filter 313 may be formed on the solid-state imaging element 310.

In addition, in the aspect shown in FIG. 3, the film thickness of the color filter 312 and the film thickness of the infrared transmitting filter 313 are the same, but the film thicknesses of both may be different from each other.

In addition, in the aspect shown in FIG. 3, the color filter 312 is provided closer to the incidence ray hv side than the infrared absorbing filter 311, but the order of the infrared absorbing filter 311 and the color filter 312 may be changed so that the infrared absorbing filter 311 is provided closer to the incidence ray hv side than the color filter 312.

In addition, in the aspect shown in FIG. 3, the infrared absorbing filter 311 and the color filter 312 are laminated adjacent to each other, but both filters are not necessarily adjacent to each other, and another layer may be provided therebetween. The cured film according to the embodiment of the present invention can be used as a light shielding film for the edges and/or side surfaces of the surface of the infrared absorbing filter 311. In addition, in a case where the cured film according to the embodiment of the present invention is used on an interior wall of a device of the infrared sensor, it is possible to prevent internal reflection and/or incident of meaningless light on the light receiving section and improve sensitivity.

Since this infrared sensor can capture image information at the same time, it is possible to perform motion sensing or the like which recognizes an object for detecting motion. In addition, since this infrared sensor can acquire distance information, it is possible to take an image including 3D information. Furthermore, this infrared sensor can also be used as a biometric authentication sensor.

Next, a solid-state imaging device to which the infrared sensor is applied will be described.

The above-described solid-state imaging device contains a lens optical system, a solid-state imaging element, an infrared light emitting diode, and the like. With regard to each configuration of the solid-state imaging device, paragraphs 0032 to 0036 of JP2011-233983A can be referred to, the content of which is incorporated herein by reference.

### EXAMPLES

Hereinafter, the present invention will be described in more detail based on examples. The materials, the amounts of materials to be used, the proportions, the treatment details, the treatment procedure, or the like shown in the examples below may be modified appropriately as long as the modifications do not depart from the spirit of the present invention. Therefore, the scope of the present invention should not be construed as being limited by the following examples.

[Production of Curable Composition]

In order to produce a curable composition used for test, first, a coloring material dispersion liquid and a silica particle dispersion liquid were prepared.

<Preparation of Coloring Material Dispersion Liquid>

Each component shown in Table 1 was mixed and stirred to obtain each coloring material dispersion liquid shown in Table 1. Among the respective components in Table 1, details of components represented by abbreviations or symbols are as follows.

(Solvent)

PGMEA: propylene glycol monomethyl ether acetate

(Resin)

B-1: weight-average molecular weight=11000, acid value=32 mgKOH/g, ethylenically unsaturated bond equivalent=1.42 mmol/g; see the formula below (in the formula, Me represents a methyl group)

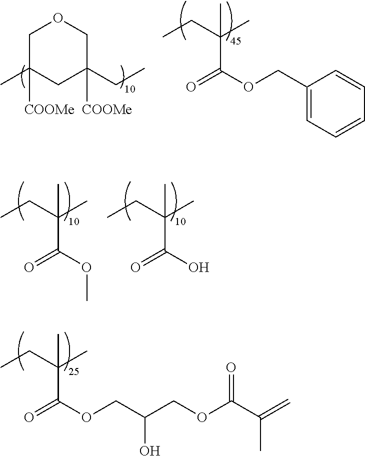

B-4: weight-average molecular weight=21000, acid value=36 mgKOH/g, ethylenically unsaturated bond equivalent=0 mmol/g; resin having a graft chain; see the formula below

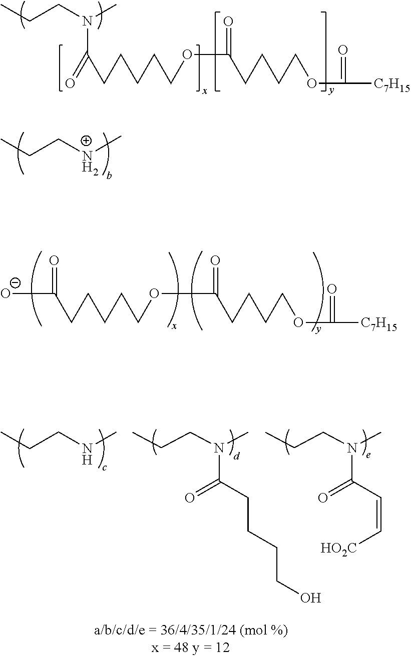

B-5: weight-average molecular weight=18000, acid value=67 mgKOH/g, ethylenically unsaturated bond equivalent=0.4 mmol/g; resin having a graft chain; see the formula below

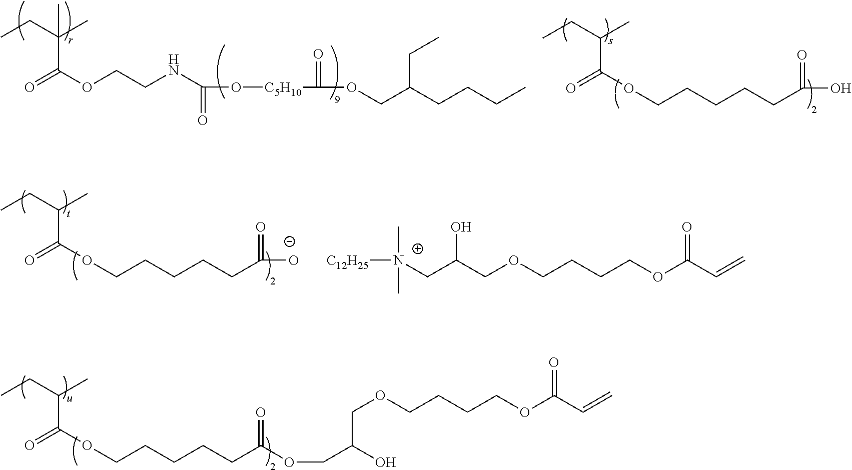

B-6: Solsperse 36000 manufactured by Lubrizol Corporation; weight-average molecular weight=36000, acid value=45 mgKOH/g, ethylenically unsaturated bond equivalent=0 mmol/g

(Pigment Derivative)

X-1: see the formula below

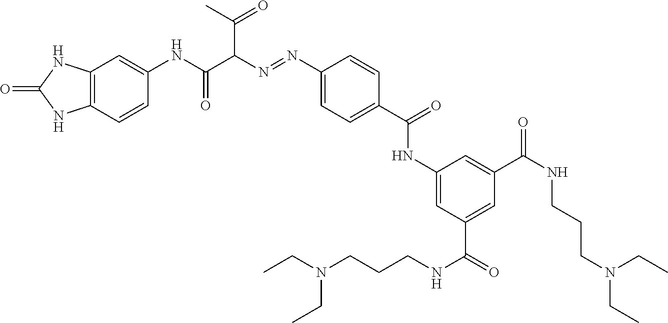 [SMILES: CCN(CC)CCCNC(=O)c1cc(NC(=O)c2ccc(/N=N/C(C(C)=O)C(=O)Nc3ccc4[nH]c(=O)[nH]c4c3)cc2)cc(C(=O)NCCCN(CC)CC)c1]

X-2: see the formula below (in the formula, Me represents a methyl group)

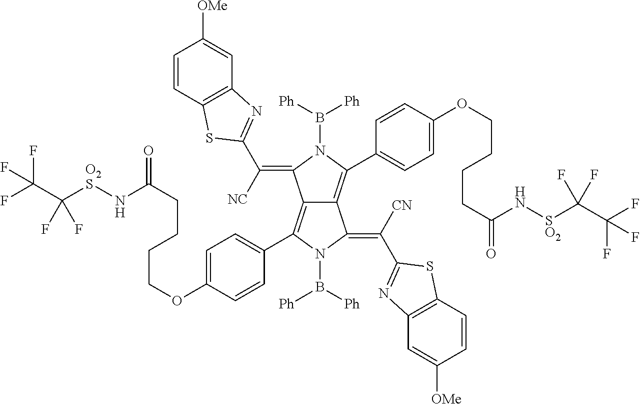 [SMILES: COc1ccc2sc(/C(C#N)=c3/c4c(-c5ccc(OCCCCC(=O)NS(=O)(=O)C(F)(F)C(F)(F)F)cc5)n(B(c5ccccc5)c5ccccc5)/c(=C(/C#N)c5nc6cc(OC)ccc6s5)c4c(-c4ccc(OCCCCC(=O)NS(=O)(=O)C(F)(F)C(F)(F)F)cc4)n3B(c3ccccc3)c3ccccc3)nc2c1]

(Coloring Material)

Pyrrolopyrrole compound: see the formula below (in the formula, Ph represents a phenyl group and Me represents a methyl group)

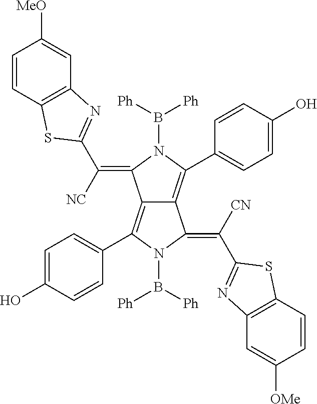 [SMILES: COc1ccc2sc(/C(C#N)=c3/c4c(-c5ccc(O)cc5)n(B(c5ccccc5)c5ccccc5)/c(=C(/C#N)c5nc6cc(OC)ccc6s5)c4c(-c4ccc(O)cc4)n3B(c3ccccc3)c3ccccc3)nc2c1]

Titanium black (coloring material): 13M-T manufactured by Mitsubishi Materials Corporation

Carbon black (coloring material): #2300 manufactured by Mitsubishi Chemical Corporation

TABLE 1

| | | | | | | Pigment | | |
|---|---|---|---|---|---|---|---|---|
| | | Solvent | | Coloring material | | derivative | Resin | |
| Green-1 | Type | PGMEA | | Pigment Green 36 | Pigment Yellow 150 | | B-4 | B-1 |
| | Content | 79.9 | | 8 | 6.5 | | 4.5 | 1.1 |
| Green-2 | Type | PGMEA | | Pigment Green 36 | | | B-4 | B-1 |
| | Content | 84.6 | | 9.8 | | | 4.5 | 1.1 |
| Red-1 | Type | PGMEA | | Pigment Red 254 | Pigment Yellow 139 | X-1 | B-5 | B-1 |
| | Content | 81.7 | | 8 | 3.3 | 1 | 1.6 | 4.4 |
| Blue-1 | Type | PGMEA | | Pigment Blue 15:6 | Pigment Violet 23 | | B-6 | B-1 |
| | Content | 82.5 | | 10.1 | 2.3 | | 2.1 | 3 |
| Cyan-1 | Type | PGMEA | | Pigment Blue 16 | | X-1 | B-4 | |
| | Content | 77.6 | | 14 | | 1.4 | 7 | |
| Magenta-1 | Type | PGMEA | | Pigment Red 122 | | X-1 | B-5 | |
| | Content | 69.6 | | 19 | | 1.9 | 9.5 | |
| Yellow-1 | Type | PGMEA | | Pigment Yellow 150 | | X-1 | B-4 | |
| | Content | 74.4 | | 16 | | 1.6 | 8 | |
| Black-1 | Type | PGMEA | Butyl acetate | Titanium black | | | B-5 | |
| | Content | 41.4 | 27 | 24.3 | | | 7.3 | |
| Black-2 | Type | PGMEA | Butyl acetate | Carbon black | | | B-5 | |
| | Content | 41.4 | 27 | 24.3 | | | 7.3 | |
| SIR-1 | Type | PGMEA | | Pyrrolopyrrole | | X-2 | B-4 | |
| | | | | compound | | | | |
| | Content | 86.39 | | 7 | | 0.54 | 6.07 | |

<Preparation of Dispersion Liquid of Silica Particles>

(Dispersion Liquid S-1 of Silica Particles 1) 4 g of KBM-503 (manufactured by Shin-Etsu Chemical Co., Ltd., 3-methacryloxypropyltrimethoxysilane), 0.5 g of 10 mass % formic acid aqueous solution, and 1 g of water were mixed in 100 g of THRULYA 4110 (manufactured by JGC C&C, solid content: 20 mass %, isopropyl alcohol solvent, hollow silica sol, average primary particle diameter: 60 nm) to obtain a mixed solution. The obtained mixed solution was stirred at 60° C. for 3 hours. In addition, using a rotary evaporator, the solvent in the mixed solution was replaced with 1-methoxy-2-propanol. By confirming concentration of solid contents of the mixed solution and further diluting the mixed solution with the required amount of 1-methoxy-2-propanol, a silica particle dispersion liquid PS-1 (dispersion liquid of hollow silica particles surface-modified with a methacrylic group) having a solid content of 20 mass % was obtained.

The silica particle dispersion liquid PS-1 (dispersion liquid having a solid content of 20 mass % produced in the above, 30.0 g), X-22-2404 (manufactured by Shin-Etsu Chemical Co., Ltd., silicone oil with methacrylic-modified one terminal, 1.8 g), and PGMEA (propylene glycol monomethyl ether acetate, 28.2 g) were charged into a three-necked flask, and the contents of the flask were heated to 80° C. under a nitrogen atmosphere. An initiator V-601 (manufactured by FUJIFILM Wako Pure Chemicals Corporation, 0.01 g) was added to the flask, and the mixture was stirred for 3 hours. Further, V-601 (0.02 g) was added to the flask, and the mixture was stirred for 2 hours. Thereafter, the contents of the flask were microfiltered, and 1-methoxy-2-propanol was added to the obtained filtrate so that the solid content was 20 mass %, thereby obtaining a dispersion liquid S-1 (31.3 g) of the silica particles 1.

(Dispersion Liquid S-2 of Silica Particles 2)

A dispersion liquid S-2 of silica particles 2 was prepared by the method described in Example 1 of WO2007/060884A.

(Dispersion Liquid S-3 of Silica Particles 3)

A dispersion liquid S-3 of silica particles 3 was prepared by the method described in Example 8 of WO2007/060884A.

(Dispersion Liquid S-4 of Silica Particles 4)

A dispersion liquid S-4 of silica particles 4 was prepared by the method described in Example 13 of WO2007/060884A.

(Dispersion Liquid S-5 of Silica Particles 5)

A dispersion liquid S-5 of silica particles 5 was prepared by the same method as described in Example 13 of WO2007/060884A, except that perfluorooctylethyltriethoxysilane was changed to KP-983 (manufactured by Shin-Etsu Silicone Co., Ltd., silicone oligomer-based silane coupling agent).

(Dispersion Liquid S-6 of Silica Particles 6)

A dispersion liquid S-6 of silica particles 6 was obtained in the same manner as in the dispersion liquid S-1 of the silica particles 1, except that, in the method for producing the dispersion liquid S-1 of the silica particles 1, the silica particle dispersion liquid PS-1 was changed to a PGM-AC-4130Y dispersion liquid (described later).

The PGM-AC-4130Y dispersion liquid was a dispersion liquid obtained by adding 1-methoxy-2-propanol to PGM-AC-4130Y (manufactured by Nissan Chemical Corporation, solid content: 32 mass %, 1-methoxy-2-propanol solvent, dispersion liquid of solid silica surface-modified with a methacrylic group) so that the solid content was 20 mass %.

(Dispersion Liquid S-7 of Silica Particles 7)

A dispersion liquid S-7 of silica particles 7 was prepared by the method described in Example 1 of JP2007-039323A.

(Dispersion Liquid S-8 of Silica Particles 8)

A dispersion liquid S-8 of silica particles 8 was prepared by the method described in Example 2 of JP2007-039323A.

(Dispersion Liquid S-9 of Silica Particles 9)

A dispersion liquid S-9 of silica particles 9 was prepared by the method described in Example 5 of JP2000-43319A (JP-H11-43319A).

(Dispersion Liquid S-10 of Silica Particles 10)

A dispersion liquid S-10 of silica particles 10 was prepared by the method described in Example 1 of WO2012/161157A.

(Dispersion Liquid S-11 of Silica Particles 11)

A dispersion liquid S-11 of silica particles 11 was prepared by the method described in Example 5 of W02012/161157A.

(Dispersion Liquid S-12 of Silica Particles 12)

A dispersion liquid S-12 of silica particles 12 was prepared by the same method as described in Example 1 of WO2012/161157A, except that 3-glycidoxypropyltrimethoxysilane was changed to KP-983 (manufactured by Shin-Etsu Silicone Co., Ltd., silicone oligomer-based silane coupling agent).

(Dispersion Liquid S-13 of Silica Particles 13)

A dispersion liquid S-13 of silica particles 13 was prepared by the same method as described in Example 1 of WO2012/161157A, except that methanol-dispersed silica sol (MT-ST manufactured by Nissan Chemical Corporation) was changed to isopropyl alcohol-dispersed silica sol (IPA-ST-L manufactured by Nissan Chemical Corporation), and 3-glycidoxypropyltrimethoxysilane was changed to KP-983 (manufactured by Shin-Etsu Silicone Co., Ltd., silicone oligomer-based silane coupling agent).

(Dispersion liquid S-14 of silica particles 14)

A dispersion liquid S-14 of silica particles 14 was prepared by the method described in Example 1 of WO2016/181997A.

(Dispersion Liquid S-15 of Silica Particles 15)

THRULYA 4110 (manufactured by JGC C&C, solid content: 20 mass %, isopropyl alcohol solvent, hollow silica sol, average primary particle diameter: 60 nm) was used as a dispersion liquid S-15 of silica particles 15.

TABLE 2

| Dispersion liquid | Silica | Solid/hollow | | Solid | Average particle |
|---|---|---|---|---|---|
| of silica particles | particles | (mass%) | Group having coating layer | content | diameter |
| S-1 | 1 | Hollow | Group including silicon atom | 20 | 48 nm |
| S-2 | 2 | Hollow | Methacryloyl group | 20 | 47 nm |
| S-3 | 3 | Hollow | Trifluoromethyl group | 20 | 47 nm |
| | | | (Group including fluorine atom) | | |
| S-4 | 4 | Hollow | Perfluorooctylethyl group | 20 | 60 nm |
| | | | (Group including fluorine atom) | | |
| S-5 | 5 | Hollow | Group including silicon atom | 20 | 60 nm |
| S-6 | 6 | Solid | Group including silicon atom | 20 | 47 nm |
| S-7 | 7 | Solid | Methyl group | 20 | 67 nm |
| S-8 | 8 | Solid | Methyl group | 20 | 152 nm |
| S-9 | 9 | Solid | n-Butyl group, methyl group | 20 | 40 nm |
| S-10 | 10 | Solid | Glycidoxy group | 20 | 20 nm |
| S-11 | 11 | Solid | Methacryloyl group | 20 | 19 nm |
| S-12 | 12 | Solid | Group including silicon atom | 20 | 20 nm |
| S-13 | 13 | Solid | Group including silicon atom | 20 | 47 nm |
| S-14 | 14 | Solid | Amino group | 20 | 20 nm |
| S-15 | 15 | Hollow | No coating layer | 20 | 60 nm |

In Table 2, the column “Average particle diameter” shows the particle size (average primary particle diameter, nm) of the silica particles contained in the dispersion liquid of silica particles.

The column “Solid/hollow” shows whether the silica particles contained in the dispersion liquid of silica particles were hollow particles or solid particles.

The column “Group having coating layer” shows the group contained in the coating layer of the silica particles.

“Solid content (mass %)” shows the content of the silica particles in the dispersion liquid of silica particles.

Further, among the other components used in the production of the curable composition, details of the components indicated by abbreviations are shown below.

(Resin)
B1: same as B1 used in the coloring material dispersion liquid
B2: weight-average molecular weight=30000, acid value=112 mgKOH/g, ethylenically unsaturated bond equivalent=0 mmol/g; see the formula below

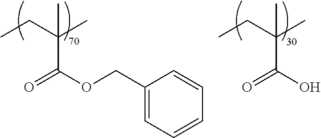

B3: CYCLOMER P manufactured by DAICEL-ALLNEX LTD., weight-average molecular weight=14000, acid value=29.6 mgKOH/g, ethylenically unsaturated bond equivalent=2.1 mmol/g
E-1: EHPE-3150 (epoxy resin) manufactured by Daicel Corporation

(Polymerizable Compound)
M-1: NK ESTER A-TMMT manufactured by Shin-Nakamura Chemical Co., Ltd.
M-2: KAYARAD DPCA-20 manufactured by Nippon Kayaku Co., Ltd.
M-3: NK ESTER A-DPH-12E manufactured by Shin-Nakamura Chemical Co., Ltd.
M-4: KAYARAD DPHA manufactured by Nippon Kayaku Co., Ltd.

(Polymerization Initiator)
Ini-1: IRGACURE-OXE01 manufactured by BASF
Ini-2: IRGACURE-OXE02 manufactured by BASF
Ini-3: IRGACURE-OXE03 manufactured by BASF

(Ultraviolet (UV) absorber)
U-1: see the following formula

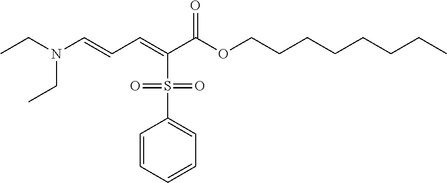 [SMILES: CCCCCCCCOC(=O)/C(=C/C=C/N(CC)CC)S(=O)(=O)c1ccccc1]

(Adhesive)
M-5: see the formula below

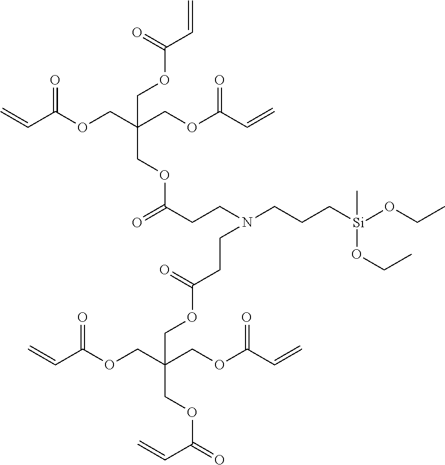 [SMILES: C=CC(=O)OCC(COC(=O)C=C)(COC(=O)C=C)COC(=O)CCN(CCC[Si](C)(OCC)OCC)CCC(=O)OCC(COC(=O)C=C)(COC(=O)C=C)COC(=O)C=C]

(Polymerization Inhibitor)
A-1: p-methoxyphenol

(Surfactant)
W-1: see the formula below (weight-average molecular weight: 15000)

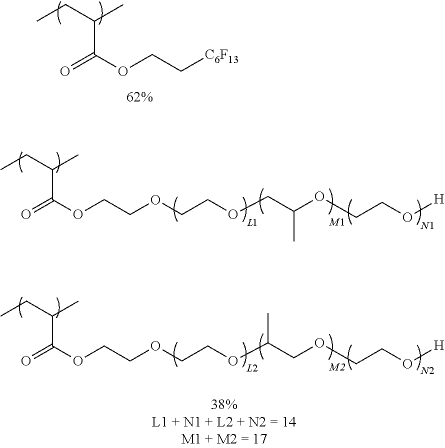

CW-1: Pionin D6112 W (manufactured by TAKEMOTO OIL & FAT Co., Ltd.)

<Preparation>

Curable compositions of Examples and Comparative Examples were obtained by mixing and stirring each component so that the content of each component was the value shown in Tables 3 to 8. The unit of numerical values in Tables 3 to 8 is mass %.

In the tables, the content of the column “Dispersion liquid of silica particles” means the content of the dispersion liquid of silica particles, and the content of the column “Coloring material dispersion liquid” means the content of the coloring material dispersion liquid.

TABLE 3

| | | Example | Example | Example | Example | Example | Example | Example | Example | Example | Example | Example | Example | Example | Example | Example | Example |
|---|---|---|---|---|---|---|---|---|---|---|---|---|---|---|---|---|---|
| | | G1 | G2 | G3 | G4 | G5 | G6 | G7 | G8 | G9 | G10 | G11 | G12 | G13 | G14 | G15 | G15A |
| Solvent | PGMEA | 12.14 | 10.44 | 10.44 | 10.44 | 10.44 | 10.44 | 10.44 | 10.44 | 10.44 | 10.44 | 10.44 | 10.44 | 10.44 | 10.44 | 10.44 | 10.44 |
| Resin | B-1 | 0.13 | 0.09 | 0.09 | 0.09 | 0.09 | 0.09 | 0.09 | 0.09 | 0.09 | 0.09 | 0.09 | 0.09 | 0.09 | 0.09 | 0.09 | 0.09 |
| | B-2 | | | | | | | | | | | | | | | | |
| | B-3 | | | | | | | | | | | | | | | | |
| | E-1 | | | | | | | | | | | | | | | | |
| Polymerizable | M-1 | 2.75 | 2.00 | 2.00 | 2.00 | 2.00 | 2.00 | 2.00 | 2.00 | 2.00 | 2.00 | 2.00 | 2.00 | 2.00 | 2.00 | 2.00 | 2.00 |
| compound | M-2 | | | | | | | | | | | | | | | | |
| | M-3 | | | | | | | | | | | | | | | | |
| | M-4 | | | | | | | | | | | | | | | | |
| Polymerization | Ini-1 | 1.04 | 0.76 | 0.76 | 0.76 | 0.76 | 0.76 | 0.76 | 0.76 | 0.76 | 0.76 | 0.76 | 0.76 | 0.76 | 0.76 | 0.76 | 0.76 |
| initiator | Ini-2 | | | | | | | | | | | | | | | | |
| | Ini-3 | | | | | | | | | | | | | | | | |
| UV absorber | U-1 | 0.60 | 0.59 | 0.59 | 0.59 | 0.59 | 0.59 | 0.59 | 0.59 | 0.59 | 0.59 | 0.59 | 0.59 | 0.59 | 0.59 | 0.59 | 0.59 |
| Adhesive | M-5 | | | | | | | | | | | | | | | | |
| Polymerization | A-1 | 0.002 | 0.002 | 0.002 | 0.002 | 0.002 | 0.002 | 0.002 | 0.002 | 0.002 | 0.002 | 0.002 | 0.002 | 0.002 | 0.002 | 0.002 | 0.002 |
| inhibitor | | | | | | | | | | | | | | | | | |
| Surfactant | W-1 | 0.04 | 0.04 | 0.04 | 0.04 | 0.04 | 0.04 | 0.04 | 0.04 | 0.04 | 0.04 | 0.04 | 0.04 | 0.04 | 0.04 | 0.04 | 0.04 |
| Dispersion | Silica particles 1 | 5.00 | 9.75 | | | | | | | | | | | | | | |
| liquid of silica | Silica particles 2 | | | 9.75 | | | | | | | | | | | | | |
| particles | Silica particles 3 | | | | 9.75 | | | | | | | | | | | | |
| | Silica particles 4 | | | | | 9.75 | | | | | | | | | | | |
| | Silica particles 5 | | | | | | 9.75 | | | | | | | | | | |
| | Silica particles 6 | | | | | | | 9.75 | | | | | | | | | |
| | Silica particles 7 | | | | | | | | 9.75 | | | | | | | | |
| | Silica particles 8 | | | | | | | | | 9.75 | | | | | | | |
| | Silica particles 9 | | | | | | | | | | 9.75 | | | | | | |
| | Silica particles 10 | | | | | | | | | | | 9.75 | | | | | |
| | Silica particles 11 | | | | | | | | | | | | 9.75 | | | | |
| | Silica particles 12 | | | | | | | | | | | | | 9.75 | | | |
| | Silica particles 13 | | | | | | | | | | | | | | 9.75 | | |
| | Silica particles 14 | | | | | | | | | | | | | | | 9.75 | |
| | Silica particles 15 | | | | | | | | | | | | | | | | 9.75 |
| Coloring | Green-1 | 49.60 | 48.36 | 48.36 | 48.36 | 48.36 | 48.36 | 48.36 | 48.36 | 48.36 | 48.36 | 48.36 | 48.36 | 48.36 | 48.36 | 48.36 | 48.36 |
| material | Green-2 | 28.69 | 27.97 | 27.97 | 27.97 | 27.97 | 27.97 | 27.97 | 27.97 | 27.97 | 27.97 | 27.97 | 27.97 | 27.97 | 27.97 | 27.97 | 27.97 |
| dispersion | | | | | | | | | | | | | | | | | |
| liquid | | | | | | | | | | | | | | | | | |

| | | | | | | | | | | | | | | | | |
|---|---|---|---|---|---|---|---|---|---|---|---|---|---|---|---|---|
| Content of coloring material with respect | 50 | 50 | 50 | 50 | 50 | 50 | 50 | 50 | 50 | 50 | 50 | 50 | 50 | 50 | 50 | 50 |
| to total solid content of curable compound (mass %) | | | | | | | | | | | | | | | | |
| Content of silica particles with respect to total | 5 | 10 | 10 | 10 | 10 | 10 | 10 | 10 | 10 | 10 | 10 | 10 | 10 | 10 | 10 | 10 |
| solid content of curable compound (mass %) | | | | | | | | | | | | | | | | |
| Mass ratio of content of coloring material to | 10.0 | 5.0 | 5.0 | 5.0 | 5.0 | 5.0 | 5.0 | 5.0 | 5.0 | 5.0 | 5.0 | 5.0 | 5.0 | 5.0 | 5.0 | 5.0 |
| content of silica particles | | | | | | | | | | | | | | | | |

TABLE 4

| | | Example | Example | Example | Example | Example | Example | Example | Example | Example | Example | Example | Example | Example | Example | Example | Example |
|---|---|---|---|---|---|---|---|---|---|---|---|---|---|---|---|---|---|
| | | G16 | G17 | G18 | G19 | G20 | G21 | G22 | G23 | G24 | G25 | G26 | G27 | G28 | G29 | G30 | G31 |
| Solvent | PGMEA | 10.44 | 10.44 | 10.44 | 10.44 | 10.44 | 10.53 | 10.53 | 10.44 | 35.33 | 22.88 | 24.60 | 18.98 | 15.08 | 11.18 | 10.44 | 10.44 |
| Resin | B-1 | | | 0.09 | 0.09 | 0.09 | | | 0.05 | 4.24 | 2.17 | 0.06 | 1.57 | 0.96 | 0.36 | 0.09 | 0.09 |
| | B-2 | 0.09 | | | | | | | | | | | | | | | |
| | B-3 | | 0.09 | | | | | | 0.04 | | | | | | | | |
| | E-1 | | | | | | | | | | | | | | | 0.20 | |
| Polymerizable | M-1 | 2.00 | 2.00 | | | | 2.00 | 2.00 | 1.00 | 3.08 | 2.54 | 1.40 | 2.27 | 2.00 | 1.73 | 1.86 | 1.86 |
| compound | M-2 | | | 2.00 | | | | | | | | | | | | | |
| | M-3 | | | | 2.00 | | | | | | | | | | | | |
| | M-4 | | | | | 2.00 | | | 1.00 | | | | | | | | |
| Polymerization | Ini-1 | 0.76 | 0.76 | 0.76 | 0.76 | 0.76 | | | 0.30 | 1.17 | 0.96 | 0.53 | 0.86 | 0.76 | 0.66 | 0.71 | 0.71 |
| initiator | Ini-2 | | | | | | 0.76 | | 0.46 | | | | | | | | |
| | Ini-3 | | | | | | | 0.76 | | | | | | | | | |
| UV absorber | U-1 | 0.59 | 0.59 | 0.59 | 0.59 | 0.59 | 0.59 | 0.59 | 0.59 | 0.59 | 0.59 | 0.48 | 0.59 | 0.59 | 0.59 | 0.59 | 0.59 |
| Adhesive | M-5 | | | | | | | | | | | | | | | | 0.20 |
| Polymerization | A-1 | 0.002 | 0.002 | 0.002 | 0.002 | 0.002 | 0.002 | 0.002 | 0.002 | 0.002 | 0.002 | 0.002 | 0.002 | 0.002 | 0.002 | 0.002 | 0.002 |
| inhibitor | | | | | | | | | | | | | | | | | |
| Surfactant | W-1 | 0.04 | 0.04 | 0.04 | 0.04 | 0.04 | 0.04 | 0.04 | 0.04 | 0.04 | 0.04 | 0.04 | 0.04 | 0.04 | 0.04 | 0.04 | 0.04 |
| Dispersion | Silica particles 1 | 9.75 | 9.75 | 9.75 | 9.75 | 9.75 | 9.75 | 9.75 | 9.75 | 9.75 | 9.75 | 4.00 | 14.63 | 19.50 | 24.38 | 9.75 | 9.75 |
| liquid of silica | Silica particles 2 | | | | | | | | | | | | | | | | |
| particles | Silica particles 3 | | | | | | | | | | | | | | | | |
| | Silica particles 4 | | | | | | | | | | | | | | | | |
| | Silica particles 5 | | | | | | | | | | | | | | | | |
| | Silica particles 6 | | | | | | | | | | | | | | | | |
| | Silica particles 7 | | | | | | | | | | | | | | | | |
| | Silica particles 8 | | | | | | | | | | | | | | | | |
| | Silica particles 9 | | | | | | | | | | | | | | | | |
| | Silica particles 10 | | | | | | | | | | | | | | | | |
| | Silica particles 11 | | | | | | | | | | | | | | | | |
| | Silica particles 12 | | | | | | | | | | | | | | | | |
| | Silica particles 13 | | | | | | | | | | | | | | | | |
| | Silica particles 14 | | | | | | | | | | | | | | | | |
| | Silica particles 15 | | | | | | | | | | | | | | | | |
| Coloring | Green-1 | 48.36 | 48.36 | 48.36 | 48.36 | 48.36 | 48.36 | 48.36 | 48.36 | 29.02 | 38.69 | 43.65 | 38.69 | 38.69 | 38.69 | 48.36 | 48.36 |
| material | Green-2 | 27.97 | 27.97 | 27.97 | 27.97 | 27.97 | 27.97 | 27.97 | 27.97 | 16.78 | 22.38 | 25.24 | 22.38 | 22.38 | 22.38 | 27.97 | 27.97 |
| dispersion | | | | | | | | | | | | | | | | | |
| liquid | | | | | | | | | | | | | | | | | |

| | | | | | | | | | | | | | | | | |
|---|---|---|---|---|---|---|---|---|---|---|---|---|---|---|---|---|
| Content of coloring material with respect | 50 | 50 | 50 | 50 | 50 | 50 | 50 | 50 | 30 | 40 | 55 | 40 | 40 | 40 | 50 | 50 |
| to total solid content of curable compound (mass %) | | | | | | | | | | | | | | | | |
| Content of silica particles with respect to total | 10 | 10 | 10 | 10 | 10 | 10 | 10 | 10 | 10 | 10 | 5 | 15 | 20 | 25 | 10 | 10 |
| solid content of curable compound (mass %) | | | | | | | | | | | | | | | | |
| Mass ratio of content of coloring material to | 5.0 | 5.0 | 5.0 | 5.0 | 5.0 | 5.0 | 5.0 | 5.0 | 3.0 | 4.0 | 11.0 | 2.7 | 2.0 | 1.6 | 5.0 | 5.0 |
| content of silica particles | | | | | | | | | | | | | | | | |

TABLE 5

| | | Comparative | Comparative | Comparative | Comparative | Comparative | Comparative | Comparative |
|---|---|---|---|---|---|---|---|---|
| | | example | example | example | example | example | example | example |
| | | G1 | G2 | G3 | G4 | G5 | G6 | G6A |
| Solvent | PGMEA | 16.16 | 43.10 | 30.65 | 27.76 | 12.91 | 40.32 | 48.60 |
| Resin | B-1 | 0.67 | 5.47 | 3.41 | 0.64 | 0.28 | 4.57 | 6.52 |
| | B-2 | | | | | | | |
| | B-3 | | | | | | | |
| | E-1 | | | | | | | |
| Polymerizable | M-1 | 3.08 | 3.63 | 3.08 | 1.58 | 2.82 | 4.07 | 3.90 |
| compound | M-2 | | | | | | | |
| | M-3 | | | | | | | |
| | M-4 | | | | | | | |
| Polymerization | Ini-1 | 1.17 | 1.38 | 1.17 | 0.60 | 1.07 | 1.54 | 1.48 |
| initiator | Ini-2 | | | | | | | |
| | Ini-3 | | | | | | | |
| UV absorber | U-1 | 0.59 | 0.59 | 0.59 | 0.48 | 0.59 | 0.59 | 0.59 |
| Adhesive | M-5 | | | | | | | |
| Polymerization | A-1 | 0.002 | 0.002 | 0.002 | 0.002 | 0.002 | 0.002 | 0.002 |
| inhibitor | | | | | | | | |
| Surfactant | W-1 | 0.04 | 0.04 | 0.04 | 0.04 | 0.04 | 0.04 | 0.04 |
| Dispersion | Silica particles 1 | 0.00 | 0.00 | 0.00 | 0.00 | 4.00 | 10.00 | |
| liquid of silica | Silica particles 2 | | | | | | | |
| particles | Silica particles 3 | | | | | | | |
| | Silica particles 4 | | | | | | | |
| | Silica particles 5 | | | | | | | |
| | Silica particles 6 | | | | | | | |
| | Silica particles 7 | | | | | | | |
| | Silica particles 8 | | | | | | | |
| | Silica particles 9 | | | | | | | |
| | Silica particles 10 | | | | | | | |
| | Silica particles 11 | | | | | | | |
| | Silica particles 12 | | | | | | | |
| | Silica particles 13 | | | | | | | |
| | Silica particles 14 | | | | | | | |
| | Silica particles 15 | | | | | | | |
| Coloring | Green-1 | 49.60 | 29.02 | 38.69 | 43.65 | 49.60 | 24.46 | 24.46 |
| material | Green-2 | 28.69 | 16.78 | 22.38 | 25.24 | 28.69 | 14.40 | 14.40 |
| dispersion | | | | | | | | |
| liquid | | | | | | | | |

| | | | | | | | |
|---|---|---|---|---|---|---|---|
| Content of coloring material with | 50 | 30 | 40 | 55 | 50 | 25 | 25 |
| respect to total solid content of curable | | | | | | | |
| compound (mass %) | | | | | | | |
| Content of silica particles with respect to | 0 | 0 | 0 | 0 | 4 | 10 | 0 |
| total solid content of curable compound | | | | | | | |
| (mass %) | | | | | | | |
| Mass ratio of content of coloring | — | — | — | — | 12.5 | 2.5 | — |
| material to content of silica particles | | | | | | | |

TABLE 6

| | | Ex- | Ex- | Ex- | Ex- | Ex- | Ex- | Ex- | Ex- | Ex- | Ex- |
|---|---|---|---|---|---|---|---|---|---|---|---|
| | | ample | ample | ample | ample | ample | ample | ample | ample | ample | ample |
| | | B1 | B2 | B3 | B4 | B5 | B6 | R1 | R2 | C1 | C2 |
| Solvent | PGMEA | 58.62 | 56.12 | 53.62 | 51.12 | 48.62 | 41.31 | 17.61 | 13.90 | 50.35 | 47.19 |
| | Cycloheptanone | | | | | | | | | | |
| Post-addition | B-1 | 1.35 | 1.09 | 0.82 | 0.56 | 0.29 | 0.03 | 0.58 | 0.07 | 0.57 | 0.21 |
| resin | B-2 | | | | | | | | | | |
| | B-3 | | | | | | | | | | |
| Polymerizable | M-1 | 3.31 | 3.02 | 2.73 | 2.44 | 2.15 | 1.31 | | | | |
| compound | M-2 | | | | | | | 2.14 | 1.79 | | |
| | M-3 | | | | | | | | | | |
| | M-4 | | | | | | | | | 3.35 | 3.04 |
| Polymerization | Ini-1 | 0.79 | 0.72 | 0.66 | 0.59 | 0.52 | 0.31 | 0.41 | 0.34 | | |
| initiator | Ini-2 | | | | | | | | | 1.28 | 1.17 |
| | Ini-3 | | | | | | | | | | |
| UV absorber | U-1 | | | | | | | | | 0.95 | 0.95 |
| Epoxy compound | E-1 | 0.63 | 0.63 | 0.63 | 0.63 | 0.63 | 0.63 | 0.93 | 0.93 | | |
| Adhesive | M-5 | | | | | | | | | | |
| Polymerization | A-1 | 0.002 | 0.002 | 0.002 | 0.002 | 0.002 | 0.002 | 0.002 | 0.002 | 0.002 | 0.002 |
| inhibitor | | | | | | | | | | | |
| Surfactant | W-1 | 0.04 | 0.04 | 0.04 | 0.04 | 0.04 | 0.04 | 0.04 | 0.04 | 0.04 | 0.04 |
| | CW-1 | 0.13 | 0.13 | 0.13 | 0.13 | 0.13 | 0.13 | | | | |
| Dispersion | Silica particles 1 | 3.13 | 6.25 | 9.38 | 12.50 | 15.63 | 6.25 | 4.63 | 9.25 | 3.95 | 7.90 |
| liquid of silica | | | | | | | | | | | |
| particles | | | | | | | | | | | |
| Coloring material | Blue-1 | 32.00 | 32.00 | 32.00 | 32.00 | 32.00 | 50.00 | | | | |
| dispersion liquid | Red-1 | | | | | | | 73.67 | 73.67 | | |
| | Cyan-1 | | | | | | | | | 39.50 | 39.50 |
| | Magenta-1 | | | | | | | | | | |
| | Yellow-1 | | | | | | | | | | |
| | Black-1 | | | | | | | | | | |
| | Black-2 | | | | | | | | | | |
| | SIR-1 | | | | | | | | | | |

| | | | | | | | | | | |
|---|---|---|---|---|---|---|---|---|---|---|
| Content of coloring material | 32 | 32 | 32 | 32 | 32 | 50 | 45 | 45 | 35 | 35 |
| with respect to total solid content | | | | | | | | | | |
| of curable compound (mass %) | | | | | | | | | | |
| Content of silica particles with | 5 | 10 | 15 | 20 | 25 | 10 | 5 | 10 | 5 | 10 |
| respect to total solid content | | | | | | | | | | |
| of curable compound (mass %) | | | | | | | | | | |
| Mass ratio of content of | 6.3 | 3.2 | 2.1 | 1.6 | 1.3 | 5.0 | 9.0 | 4.5 | 7.0 | 3.5 |
| coloring material to | | | | | | | | | | |

TABLE 7

| | | Ex- | Ex- | Ex- | Ex- | Ex- | Ex- | Ex- | Ex- | Ex- | Ex- |
|---|---|---|---|---|---|---|---|---|---|---|---|
| | | ample | ample | ample | ample | ample | ample | ample | ample | ample | ample |
| | | M1 | M2 | Y1 | Y2 | BK1 | BK2 | BK3 | BK4 | S1 | S2 |
| Solvent | PGMEA | 60.38 | 57.48 | 54.37 | 51.39 | 40.30 | 36.80 | 54.33 | 50.83 | 11.74 | 8.13 |
| | Cycloheptanone | | | | | 14.03 | 14.03 | | | | |
| Post-addition | B-1 | | | | | | | | | | |
| resin | B-2 | 1.34 | 0.87 | | | | | | | 0.22 | 0.05 |
| | B-3 | | | 1.74 | 1.22 | 1.12 | 0.68 | 1.12 | 0.68 | | |
| Polymerizable | M-1 | 2.43 | 2.20 | | | | | | | | |
| compound | M-2 | 0.41 | 0.37 | | | | | | | | |
| | M-3 | | | 1.86 | 1.68 | | | | | 2.12 | 1.80 |
| | M-4 | | | | | 2.99 | 2.64 | 2.99 | 2.64 | 2.12 | 1.80 |
| Polymerization | Ini-1 | | | | | | | | | 0.50 | 0.42 |
| initiator | Ini-2 | 0.41 | 0.37 | 0.49 | 0.44 | | | | | | |
| | Ini-3 | | | | | 0.70 | 0.62 | 0.70 | 0.62 | | |
| UV absorber | U-1 | 0.37 | 0.37 | 0.52 | 0.52 | 0.44 | 0.44 | 0.44 | 0.44 | 1.62 | 1.62 |
| Epoxy compound | E-1 | | | | | | | | | | |
| Adhesive | M-5 | | | | | | | | | | |
| Polymerization | A-1 | 0.002 | 0.002 | 0.002 | 0.002 | 0.002 | 0.002 | 0.002 | 0.002 | 0.002 | 0.002 |
| inhibitor | | | | | | | | | | | |
| Surfactant | W-1 | 0.04 | 0.04 | 0.04 | 0.04 | 0.04 | 0.04 | 0.04 | 0.04 | 0.04 | 0.04 |
| | CW-1 | | | | | | | | | | |
| Dispersion | Silica particles 1 | 3.68 | 7.35 | 3.73 | 7.45 | 4.38 | 8.75 | 4.38 | 8.75 | 4.50 | 9.00 |
| liquid of silica | | | | | | | | | | | |
| particles | | | | | | | | | | | |
| Coloring material | Blue-1 | | | | | | | | | | |
| dispersion liquid | Red-1 | | | | | | | | | | |
| | Cyan-1 | | | | | | | | | | |
| | Magenta-1 | 30.95 | 30.95 | | | | | | | | |
| | Yellow-1 | | | 37.25 | 37.25 | | | | | | |
| | Black-1 | | | | | 36.01 | 36.01 | | | | |
| | Black-2 | | | | | | | 36.01 | 36.01 | | |
| | SIR-1 | | | | | | | | | 77.14 | 77.14 |

| | | | | | | | | | | |
|---|---|---|---|---|---|---|---|---|---|---|
| Content of coloring material | 39 | 39 | 40 | 40 | 50 | 50 | 50 | 50 | 30 | 30 |
| with respect to total solid content | | | | | | | | | | |
| of curable compound (mass %) | | | | | | | | | | |
| Content of silica particles with | 5 | 10 | 5 | 10 | 5 | 10 | 5 | 10 | 5 | 10 |
| respect to total solid content | | | | | | | | | | |
| of curable compound (mass %) | | | | | | | | | | |
| Mass ratio of content of | 8.0 | 4.0 | 8.0 | 4.0 | 10.0 | 5.0 | 10.0 | 5.0 | 6.0 | 3.0 |
| coloring material to | | | | | | | | | | |

TABLE 8

| | | Compar- | Compar- | Compar- | Compar- | Compar- | Compar- | Compar- | Compar- | Compar- |
|---|---|---|---|---|---|---|---|---|---|---|
| | | ative | ative | ative | ative | ative | ative | ative | ative | ative |
| | | example | example | example | example | example | example | example | example | example |
| | | B1 | B2 | R1 | C1 | M1 | Y1 | BK1 | BK2 | S1 |
| Solvent | PGMEA | 45.90 | 61.14 | 21.31 | 53.51 | 63.73 | 57.87 | 57.83 | 57.83 | 15.19 |
| | Cyclo- | | | | | | | 14.03 | | |
| | heptanone | | | | | | | | | |
| Post-addition | B-1 | 0.81 | 1.61 | 1.23 | 0.93 | | | | | |
| resin | B-2 | | | | | 1.80 | | | | 0.69 |
| | B-3 | | | | | | 2.25 | 1.56 | 1.56 | |
| Polymerizable | M-1 | 1.69 | 3.60 | | | 2.67 | | | | |
| compound | M-2 | | | 2.37 | | | | | | |
| | M-3 | | | | | | 2.04 | | | 2.31 |
| | M-4 | | | | 3.66 | | | 3.34 | 3.34 | 2.31 |
| Polymerization | Ini-1 | 0.41 | 0.86 | 0.46 | | | | | | 0.54 |
| initiator | Ini-2 | | | | 1.40 | 0.45 | 0.54 | | | |
| | Ini-3 | | | | | | | 0.79 | 0.79 | |
| UV absorber | U-1 | | | | 0.95 | 0.37 | | 0.44 | 0.44 | 1.62 |
| Epoxy compound | E-1 | 0.63 | 0.63 | 0.93 | | | | | | 0.20 |
| Adhesive | M-5 | | | | | | | | | |
| Polymerization | A-1 | 0.002 | 0.002 | 0.002 | 0.002 | 0.002 | 0.002 | 0.002 | 0.002 | |
| inhibitor | | | | | | | | | | |
| Surfactant | W-1 | 0.04 | 0.04 | 0.04 | 0.04 | 0.04 | 0.04 | 0.04 | 0.04 | |
| | CW-1 | 0.13 | 0.13 | | | | | | | |
| Dispersion | Silica | 0.00 | 0.00 | 0.00 | 0.00 | 0.00 | 0.00 | 0.00 | 0.00 | 0.00 |
| liquid of silica | particles 1 | | | | | | | | | |
| particles | | | | | | | | | | |
| Coloring material | Blue-1 | 50.40 | 32.00 | | | | | | | |
| dispersion liquid | Red-1 | | | 73.67 | | | | | | |
| | Cyan-1 | | | | 39.50 | | | | | |
| | Magenta-1 | | | | | 30.95 | | | | |
| | Yellow-1 | | | | | | 37.25 | | | |
| | Black-1 | | | | | | | 36.01 | | |
| | Black-2 | | | | | | | | 36.01 | |
| | SIR-1 | | | | | | | | | 77.14 |

| | | | | | | | | | |
|---|---|---|---|---|---|---|---|---|---|
| Content of coloring material | 50 | 32 | 45 | 35 | 40 | 41 | 50 | 50 | 30 |
| with respect to total solid content | | | | | | | | | |
| of curable compound (mass %) | | | | | | | | | |
| Content of silica particles with | — | — | — | — | — | — | — | — | — |
| respect to total solid content | | | | | | | | | |
| of curable compound (mass %) | | | | | | | | | |
| Mass ratio of content of | — | — | — | — | — | — | — | — | — |
| coloring material to | | | | | | | | | |

[Evaluation]

<Evaluation of Transmittance Improvement Range>

The curable composition obtained above was applied to an 8-inch glass wafer with an undercoat layer (CT-4000L manufactured by Fujifilm Electronic Materials Co., Ltd., film thickness: 0.1 μm) using a spin coater such that the thickness after drying was 0.8 μm. Thereafter, the curable composition was heat-treated (pre-baked) using a hot plate at 90° C. for 120 minutes.

Next, using an i-ray stepper exposure device FPA-3000 i5+(manufactured by Canon Inc.), the coating film was exposed with light having a wavelength of 365 nm through a mask having a 2 cm×2 cm pattern at an exposure amount of 1000 mJ/cm².

Thereafter, the glass wafer on which the exposed coating film had been formed was placed on a horizontal rotary table of a spin-shower developing machine (DW-30 Type, manufactured by Chemitronics Co., Ltd.), and was subjected to a puddle development at 23° C. for 60 seconds using a 0.3% tetramethylammonium hydroxide (TMAH) aqueous solution to form a color filter pattern on the glass wafer.

The glass wafer on which the color filter pattern had been formed was fixed on the above-described horizontal rotary table by a vacuum chuck method, a rinse treatment was performed by supplying pure water from an ejection nozzle from above a rotation center in shower-like while rotating the glass wafer at a rotation speed of 50 rpm by a rotation device, and then the glass wafer was spray-dried. Thereafter, heating treatment (post-baking; 220° C./5 minutes) was performed for 5 minutes using a hot plate at 200° C. to obtain a color filter.

The transmittance of the obtained color filter at a wavelength of 400 to 1100 nm was measured at 5 nm intervals using MCPD-9800 (manufactured by OTSUKA ELECTRONICS Co., LTD.), and the integrated value thereof was defined as T(example). In addition, the integrated value of the transmittance of the comparative example was also measured by the same method and defined as T(comparative example).

An improvement range (I) of the transmittance was defined by the following expression, and evaluated according to the following standard. It is judged that evaluations A to D have no problem in practical use.

I(%)=100×T(example)/T(comparative example)

(Evaluation Standard)

A: I was 6% or more.

B: I was 4% or more and less than 6%.

C: I was 2% or more and less than 4%.

D: I was 1% or more and less than 2%.

E: I was 0% or more and less than 1%.

<Evaluation of Color Separation>

The transmittance of the obtained color filter at a wavelength of 400 to 750 nm obtained in the “Evaluation of transmittance improvement range” described above was measured at 5 nm intervals using MCPD-9800 (manufactured by OTSUKA ELECTRONICS Co., LTD.), and the minimum transmittance was defined as T(min) [unit: %] and evaluated according to the following standard. As the minimum transmittance T is closer to 0%, color separation is more excellent. It is judged that evaluations A and B have no problem in practical use.

(Evaluation standard)

A: T(min) was more than 0% and less than 5%.

B: T(min) was 5% or more and less than 10%.

C: T(min) was 10% or more.

<Evaluation of Pattern Shape Accuracy>

A silicon oxide layer was formed on a silicon wafer by a plasma chemical vapor deposition (CVD) method. Next, the silicon oxide layer was patterned by a dry etching method to form partition walls (width: 100 nm, thickness: 500 nm) formed of silicon oxide in a lattice form at intervals of 1.0 μm. The dimensions of the opening of the partition walls on the silicon wafer (area partitioned by the partition walls on the silicon wafer) were 1.0 μm in length and 1.0 μm in width.

Next, the curable compositions of Examples and Comparative Examples were applied to the silicon wafer produced above by a spin coating method so that the film thickness after film formation was 0.8 μm, and the curable composition was heated using a hot plate at 90° C. for 2 minutes. Next, using an i-ray stepper exposure device FPA-3000 i5+(manufactured by Canon Inc.), the coating film was exposed through a mask having a 1.0 μm island pattern at an exposure amount of 50 to 2000 mJ/cm². Next, puddle development was performed at 23° C. for 60 seconds using a 0.3% tetramethylammonium hydroxide (TMAH) aqueous solution. Thereafter, the coating film was rinsed with a spin shower, washed with pure water, and heated using a hot plate at 220° C. for 5 minutes to form a color filter in the area partitioned by the partition walls.

In the island pattern of the color filter embedded in the partition walls obtained above, using a focused ion beam (FIB), a cross-sectional sample of the part where the color filter was embedded in the partition walls was produced and observed with a scanning electron microscope (SEM) (S-4800H manufactured by Hitachi High-Tech Corporation.) to measure a taper angle of the color filter cross section, and pattern shape accuracy was evaluated according to the following standard. As the taper angle of the color filter cross section is closer to 90 degrees, the pattern shape accuracy is higher. It is judged that evaluations A to D have no problem in practical use.

(Evaluation Standard)

A: taper angle of the color filter cross section was 88 degrees or more and 90 degrees or less.

B: taper angle of the color filter cross section was 85 degrees or more and less than 88 degrees.

C: taper angle of the color filter cross section was 80 degrees or more and less than 85 degrees.

D: taper angle of the color filter cross section was 75 degrees or more and less than 80 degrees.

E: taper angle of the color filter cross section was less than 75 degrees.

<Evaluation of Residue>

In the island pattern of the color filter obtained in the “Evaluation of pattern shape accuracy” described above, the residue of the pattern (non-image area) where the color filter was not embedded in the partition walls was evaluated by observation with a scanning electron microscope (SEM) (S-4800H manufactured by Hitachi High-Tech Corporation.). The evaluation standard is as follows. It is judged that evaluations A to D have no problem in practical use.

(Evaluation Standard)

A: no residue was observed in the non-image area.

B: residue of less than 0.01 μm was observed in the non-image area.

C: residue of 0.01 μm or more and less than 0.05 μm was observed in the non-image area.

D: residue of 0.05 μm or more and less than 0.10 μm was observed in the non-image area.

E: residue of 0.10 μm or more was observed in the non-image area.

<Evaluation of Peeling after Humidity Test>

Using a constant temperature and humidity chamber (EHS-221M) manufactured by Yamato Scientific co., ltd., a humidity test was performed by allowing the color filter obtained in the “Evaluation of pattern shape accuracy” described above to stand in an atmosphere having a temperature of 85° C. and a relative humidity of 85% for 500 hours, 750 hours, 1000 hours, and 1500 hours. After the test, using a focused ion beam (FIB), a cross-sectional sample of the part where the color filter was embedded in the partition walls was produced and observed with a scanning electron microscope (SEM) (S-4800H manufactured by Hitachi High-Tech Corporation.). The evaluation standard is as follows. It is judged that evaluations A to D have no problem in practical use.

(Evaluation standard)

A: no peeling was observed after 1500 hours of the humidity test.

B: peeling was observed after 1500 hours of the humidity test.

C: peeling was observed after 1000 hours of the humidity test.

D: peeling was observed after 750 hours of the humidity test.

E: peeling was observed after 500 hours of the humidity test.

<Evaluation of Defects>

Each of the curable compositions of Examples and Comparative Examples was applied to an 8-inch glass wafer using a spin coater such that the film thickness after drying was 0.8 μm, and a heating treatment (pre-baking) was performed for 120 seconds using a hot plate at 90° C.

Using a defect evaluation device COMPLUS (manufactured by Applied Materials, Inc.), foreign matters having a size of 1.0 μm or more were counted on the substrate on which the curable composition layer (cured film) had been formed.

This evaluation was carried out immediately after the preparation of the curable composition layer and after being allowed to stand at 45° C. for 2 weeks, and a rate of increase in foreign matter was evaluated according to the following determination standard.

The rate of increase in foreign matter was calculated by (Number of foreign matters after being allowed to stand at 45° C. for 2 weeks/Number of foreign matters immediately after preparation). The evaluation standard is as follows. It is judged that evaluations A to D have no problem in practical use.

(Evaluation standard)

A: rate of increase in foreign matter was less than 1.1.

B: rate of increase in foreign matter was 1.1 or more and less than 1.3.

C: rate of increase in foreign matter was 1.3 or more and less than 1.5.

D: rate of increase in foreign matter was 1.5 or more and less than 3.0.

E: rate of increase in foreign matter was 3.0 or more.

The results of the above-described evaluation tests are shown in Tables 9 to 11.

TABLE 9

| | Evaluation result | | | | | | |
|---|---|---|---|---|---|---|---|
| | Transmittance | | | | | Peeling | |
| | improvement range | | | Pattern | | after | |
| | Improvement | | Color | shape | | humidity | |
| | range | Comparison | separation | accuracy | Residue | test | Defects |
| Example G1 | C | Comparative | A | C | C | C | A |
| | | example-G1 | | | | | |
| Example G2 | B | Comparative | A | B | B | C | A |
| | | example-G1 | | | | | |
| Example G3 | C | Comparative | A | B | D | C | A |
| | | example-G1 | | | | | |
| Example G4 | C | Comparative | A | B | B | C | A |
| | | example-G1 | | | | | |
| Example G5 | B | Comparative | A | B | B | C | B |
| | | example-G1 | | | | | |
| Example G6 | A | Comparative | A | B | B | C | B |
| | | example-G1 | | | | | |
| Example G7 | B | Comparative | A | B | B | C | A |
| | | example-G1 | | | | | |
| Example G8 | C | Comparative | A | B | A | C | C |
| | | example-G1 | | | | | |
| Example G9 | C | Comparative | A | B | A | C | D |
| | | example-G1 | | | | | |
| Example G10 | B | Comparative | A | B | B | C | A |
| | | example-G1 | | | | | |
| Example G11 | C | Comparative | A | B | C | C | A |
| | | example-G1 | | | | | |
| Example G12 | C | Comparative | A | B | C | C | A |
| | | example-G1 | | | | | |
| Example G13 | A | Comparative | A | B | A | C | A |
| | | example-G1 | | | | | |
| Example G14 | A | Comparative | A | A | A | C | A |
| | | example-G1 | | | | | |
| Example G15 | C | Comparative | A | B | C | C | A |
| | | example-G1 | | | | | |
| Example G15A | D | Comparative | A | B | B | C | C |
| | | example-G1 | | | | | |
| Example G16 | B | Comparative | A | B | B | D | A |
| | | example-G1 | | | | | |
| Example G17 | B | Comparative | A | B | A | C | A |
| | | example-G1 | | | | | |
| Example G18 | B | Comparative | A | B | B | B | A |
| | | example-G1 | | | | | |
| Example G19 | B | Comparative | A | B | A | B | A |
| | | example-G1 | | | | | |
| Example G20 | B | Comparative | A | A | B | B | A |
| | | example-G1 | | | | | |
| Example G21 | B | Comparative | A | B | B | B | A |
| | | example-G1 | | | | | |
| Example G22 | B | Comparative | A | A | B | A | A |
| | | example-G1 | | | | | |
| Example G23 | B | Comparative | A | B | B | C | A |
| | | example-G1 | | | | | |
| Example G24 | C | Comparative | B | B | B | C | A |
| | | example-G2 | | | | | |
| Example G25 | B | Comparative | A | B | B | C | A |
| | | example-G3 | | | | | |
| Example G26 | C | Comparative | A | C | C | C | A |
| | | example-G4 | | | | | |
| Example G27 | A | Comparative | A | B | B | C | A |
| | | example-G3 | | | | | |
| Example G28 | A | Comparative | A | B | B | C | B |
| | | example-G3 | | | | | |
| Example G29 | A | Comparative | A | B | B | D | C |
| | | example-G3 | | | | | |
| Example G30 | B | Comparative | A | B | B | B | A |
| | | example-G1 | | | | | |
| Example G31 | B | Comparative | A | B | B | A | A |
| | | example-G1 | | | | | |

TABLE 10

| | Evaluation result | | | | | | |
|---|---|---|---|---|---|---|---|
| | Transmittance | | | | | Peeling | |
| | improvement range | | | Pattern | | after | |
| | Improvement | | Color | shape | | humidity | |
| | range | Comparison | separation | accuracy | Residue | test | Defects |
| Example B1 | C | Comparative | B | C | B | B | A |
| | | example-B2 | | | | | |
| Example B2 | B | Comparative | B | B | B | B | A |
| | | example-B2 | | | | | |
| Example B3 | A | Comparative | B | B | B | B | A |
| | | example-B2 | | | | | |
| Example B4 | A | Comparative | B | B | B | C | A |
| | | example-B2 | | | | | |
| Example B5 | A | Comparative | B | B | B | C | A |
| | | example-B2 | | | | | |
| Example B6 | A | Comparative | A | B | B | B | A |
| | | example-B1 | | | | | |
| Example R1 | C | Comparative | A | B | B | B | A |
| | | example-R1 | | | | | |
| Example R2 | B | Comparative | A | A | A | B | A |
| | | example-R1 | | | | | |
| Example C1 | C | Comparative | B | B | C | C | A |
| | | example-C1 | | | | | |
| Example C2 | B | Comparative | B | A | B | C | A |
| | | example-C1 | | | | | |
| Example M1 | C | Comparative | A | B | C | C | A |
| | | example-M1 | | | | | |
| Example M2 | B | Comparative | A | A | B | C | A |
| | | example-M1 | | | | | |
| Example Y1 | C | Comparative | A | B | B | C | A |
| | | example-Y1 | | | | | |
| Example Y2 | B | Comparative | A | A | A | C | A |
| | | example-Y1 | | | | | |
| Example BK1 | C | Comparative | A | C | C | C | A |
| | | example-BK1 | | | | | |
| Example BK2 | B | Comparative | A | B | B | C | A |
| | | example-BK1 | | | | | |
| Example BK3 | C | Comparative | A | C | C | C | A |
| | | example-BK2 | | | | | |
| Example BK4 | B | Comparative | A | B | B | C | A |
| | | example-BK2 | | | | | |
| Example S1 | C | Comparative | B | C | C | B | A |
| | | example-S1 | | | | | |
| Example S2 | B | Comparative | B | B | B | B | A |
| | | example-S1 | | | | | |

TABLE 11
Evaluation result

| | Transmittance | | | | | Peeling | |
|---|---|---|---|---|---|---|---|
| | improvement range | | | Pattern | | after | |
| | Improvement | | Color | shape | | humidity | |
| | range | Comparison | separation | accuracy | Residue | test | Defects |
| Comparative | — | — | A | D | D | C | A |
| example G1 | | | | | | | |
| Comparative | — | — | B | D | D | C | A |
| example G2 | | | | | | | |
| Comparative | — | — | A | D | D | C | A |
| example G3 | | | | | | | |
| Comparative | — | — | A | D | D | C | A |
| example G4 | | | | | | | |
| Comparative | E | Comparative | A | D | D | C | A |
| example G5 | | example-G1 | | | | | |
| Comparative | — | — | C | D | D | E | A |
| example G6A | | | | | | | |
| Comparative | D | Comparative | C | D | D | E | A |
| example G6 | | example-G6A | | | | | |
| Comparative | — | — | A | D | D | C | A |
| example B1 | | | | | | | |
| Comparative | — | — | B | D | D | C | A |
| example B2 | | | | | | | |
| Comparative | — | — | A | D | D | C | A |
| example R1 | | | | | | | |
| Comparative | — | — | B | D | D | C | A |
| example C1 | | | | | | | |
| Comparative | — | — | A | D | D | C | A |
| example M1 | | | | | | | |
| Comparative | — | — | A | D | D | C | A |
| example Y1 | | | | | | | |
| Comparative | — | — | A | E | E | C | A |
| example BK1 | | | | | | | |
| Comparative | — | — | A | E | E | C | A |
| example BK2 | | | | | | | |
| Comparative | — | — | A | D | D | C | A |
| example S1 | | | | | | | |

As shown in Tables 9 to 11, it was found that, by using a curable composition in which the content of the coloring material is 30 to 80 mass % with respect to the total solid content of the curable composition and the content of the silica particles is 5 to 30 mass % with respect to the total solid content of the curable composition, a cured film having excellent color separation, pattern shape accuracy, and transmittance could be manufactured (Examples).

From the comparison of Examples G2 to G15 and G15A, it is shown that, in a case where silica particles (surface-modified silica particles) containing a coating layer coating the silica were used (Examples G2 to G15), the evaluation result of the transmittance improvement range was more excellent.

From the comparison of Examples G2 to G15, it is shown that, in a case where the surface-modified silica particles were used and a case where the surface-modified silica particles, in which the coating layer contained at least one group selected from the group consisting of a group including a silicon atom, a group including a fluorine atom, an alkyl group which may have a substituent, and an aryl group which may have a substituent, were used (Examples G2, G4 to G10, G13, and G14), the evaluation of the residue was more excellent.

From the comparison of Examples G2, G16, and G17, it is shown that, in a case where a resin (hereinafter, also referred to as a “specific resin”) having an acid value of 10 to 100 mgKOH/g and an ethylenically unsaturated bond equivalent of 0.4 to 2.5 mmol/g was used and the content of the specific resin was 20 to 100 mass % with respect to the total mass of resins included in the curable composition (Examples G2 and G17), the evaluation of peeling after the humidity test was more excellent.

From the comparison of Examples G26 to G29, it is shown that, in a case where a curable composition in which the content of the silica particles was 5 mass % or more and less than 20 mass % with respect to the total solid content of the curable composition (Examples G26 and G27), the evaluation of peeling after the humidity test was more excellent.

From the comparison of Examples G2, G24, and G25, it is shown that, in a case where a curable composition in which the content of the coloring material was 40 mass % or more and less than 70 mass % with respect to the total solid content of the curable composition (Examples G2 and G25), the evaluation of color separation was more excellent.

In a case where the above-described various evaluations were carried out using the same curable composition as in Example G1, except that the UV absorber was not added, the same results as in Example G1 were obtained.

In a case where the above-described various evaluations were carried out using the same curable composition as in Example G1, except that the polymerization inhibitor was not added, the same results as in Example G1 were obtained.

In a case where the above-described various evaluations were carried out using the same curable composition as in Example G1, except that the surfactant was not added, the same results as in Example G1 were obtained.

A dispersion liquid S-16 of silica particles 16 was obtained by a polymerization in the same manner as in the dispersion liquid S-6 of the silica particles 6, except that a mixture of X-22-2404 (1.5 g) and methacrylic acid (0.3 g, manufactured by FUJIFILM Wako Pure Chemicals Corporation) was used instead of X-22-2404 (1.8 g). In Example G7, the same evaluations were carried out using the dispersion liquid 5-16 of the silica particles 16 instead of the dispersion liquid S-6 of the silica particles 6, and the same results were obtained.

With regard to the evaluation results of Examples B1 to B6, R1 and R2, C1 and C2, M1 and M2, BK1 to BK4, and S1 and S2, it is shown that the tendency was similar to that of Examples G1 to G31.

The reflectivity of the cured film in each of Examples was 5% or less.

On the other hand, as shown in Tables 9 to 11, in a case where at least one of the content of the coloring material or the content of the silica particles was out of the above-described range, it was found that at least one of color separation, pattern shape accuracy, or transmittance was deteriorated (Comparative Examples).

### EXPLANATION OF REFERENCES

100: solid-state imaging device
101: solid-state imaging element
102: imaging unit
103: cover glass
104: spacer
105: laminated substrate
106: chip board
107: circuit board
108: electrode pad
109: external connection terminal
110: through-electrode
111: lens layer
112: lens material
113: support
114, 115: light shielding film
201: light receiving element
202: color filter
203: microlens
204: substrate
205b: blue pixel
205r: red pixel
205g: green pixel
205bm: black matrix
206: p-well layer
207: readout gate portion
208: vertical electric charge transfer path
209: element separation region
210: gate insulating film
211: vertical electric charge transfer electrode
212: light shielding film
213, 214: insulating film
215: planarizing film
300: infrared sensor
310: solid-state imaging element
311: infrared absorbing filter
312: color filter
313: infrared transmitting filter
314: resin film
315: microlens
316: planarizing film

What is claimed is:

1. A curable composition comprising:
a coloring material;
a resin;
a polymerizable compound;
a polymerization initiator; and
silica particles,
wherein a content of the coloring material is 30 to 80 mass % with respect to a total solid content of the curable composition, and
a content of the silica particles is 5 to 30 mass % with respect to the total solid content of the curable composition.

2. The curable composition according to claim 1,
wherein the silica particles are modified silica particles containing silica and a coating layer coating the silica.

3. The curable composition according to claim 2,
wherein the coating layer contains at least one group selected from the group consisting of a group including a silicon atom, a group including a fluorine atom, an alkyl group which may have a substituent, and an aryl group which may have a substituent.

4. The curable composition according to claim 1,
wherein the resin contains a resin having a repeating unit having a graft chain.

5. The curable composition according to claim 1,
wherein the resin contains a resin having an acid value of 10 to 100 mgKOH/g and having an ethylenically unsaturated bond equivalent of 0.4 to 2.5 mmol/g.

6. The curable composition according to claim 1,
wherein the content of the silica particles is 5 mass % or more and less than 20 mass % with respect to the total solid content of the curable composition.

7. The curable composition according to claim 1,
wherein the content of the coloring material is 40 mass % or more and less than 70 mass % with respect to the total solid content of the curable composition.

8. The curable composition according to claim 1,
wherein a mass ratio of the content of the coloring material to the content of the silica particles is 2 to 14.

9. The curable composition according to claim 1,
wherein the coloring material contains at least one selected from the group consisting of Color Index Pigment Red 122, Color Index Pigment Red 177, Color Index Pigment Red 179, Color Index Pigment Red 254, Color Index Pigment Red 264, Color Index Pigment Red 269, Color Index Pigment Red 272, Color Index Pigment Green 7, Color Index Pigment Green 36, Color Index Pigment Green 58, Color Index Pigment Green 59, Color Index Pigment Green 63, Color Index Pigment Blue 15:4, Color Index Pigment Blue 15:6, Color Index Pigment Blue 16, Color Index Pigment Yellow 138, Color Index Pigment Yellow 139, Color Index Pigment Yellow 150, Color Index Pigment Yellow 185, Color Index Pigment Violet 23, carbon black, titanium black, a squarylium compound, and a pyrrolopyrrole compound.

10. A cured film formed of the curable composition according to claim 1.

11. The cured film according to claim 10,
wherein a reflectivity is 5% or less.

12. The cured film according to claim 10,
wherein the cured film has a patterned shape, and
a size of one side of the pattern is 3 μm or less.

13. A color filter comprising:
the cured film according to claim 10.

14. A solid-state imaging element comprising:
the cured film according to claim 10.

15. An image display device comprising:
the cured film according to claim 10.

16. The curable composition according to claim 2,
wherein the resin contains a resin having a repeating unit having a graft chain.

17. The curable composition according to claim 2,
wherein the resin contains a resin having an acid value of 10 to 100 mgKOH/g and having an ethylenically unsaturated bond equivalent of 0.4 to 2.5 mmol/g.

18. The curable composition according to claim 2,
wherein the content of the silica particles is 5 mass % or more and less than 20 mass % with respect to the total solid content of the curable composition.

19. The curable composition according to claim 2,
wherein the content of the coloring material is 40 mass % or more and less than 70 mass % with respect to the total solid content of the curable composition.

20. The curable composition according to claim 2,
wherein a mass ratio of the content of the coloring material to the content of the silica particles is 2 to 14.
